(19) United States
(12) Patent Application Publication
(10) Pub. No.: US 2025/0282127 A1
(43) Pub. Date: Sep. 11, 2025

(54) METHOD FOR PROCESSING A LAYER ELEMENT

(71) Applicant: SOLAR MATERIALS GMBH, Magdeburg (DE)

(72) Inventors: Jan BARGEL, Magdeburg (DE); Fridolin FRANKE, Magdeburg (DE); Jan-Philipp MAI, Magdeburg (DE)

(21) Appl. No.: 18/862,795

(22) PCT Filed: May 5, 2023
(86) PCT No.: PCT/EP2023/062061

§ 371 Date: Nov. 4, 2024

(30) Foreign Application Priority Data
May 17, 2022 (DE) 10 2022 112 295.6
Jul. 6, 2022 (DE) 10 2022 116 809.3

(51) Int. Cl. B32B 37/08; B32B 37/06; B32B 41/00

(52) U.S. Cl. CPC B32B 37/08; B32B 37/06; B32B 41/00; B32B 2457/12

(57) ABSTRACT

The invention relates to a method for processing a layer element, wherein the layer element has at least one base body with a lower side and an upper side opposite the lower side, a cover layer that is at least partially transparent to visible light, and at least one adhesive layer arranged between the cover layer and the upper side, wherein, during the method, the adhesive layer is heated to an adhesive layer temperature and the lower side of the base body is cooled to a lower side temperature.

The invention relates to a method for processing a layer element, wherein the layer element has at least one base body with a lower side and an upper side opposite the lower side, a cover layer that is at least partially transparent to visible light, and at least one adhesive layer arranged between the cover layer and the upper side. The invention also relates to a device for conducting such a method.

In the context of the present invention, a layer element is, for example, a solar module comprising said layers. Other components and elements comprising said layers are likewise to be understood under the term layer element. Solar modules of the type mentioned above are being used in increasing numbers to generate electricity from sunlight. For example, said solar modules may be placed in small numbers on roofs of private buildings, such as residential buildings, in order to at least partially meet the electricity demand of the house on which the solar modules are mounted. This use of this kind of decentralized energy supply is increasing, for example to charge electric vehicles decentrally. However, solar modules of the type mentioned above are also used in large installations on otherwise agricultural land to generate commercial electricity and feed it into the public grid.

The disadvantage is that the solar modules only have a limited service life. Expensive raw materials are used during production of the solar modules. For example, the conductor tracks are manufactured from a large number of modules made of silver. For this reason alone, the prior art describes methods that can recycle said raw materials and make them available for reprocessing. For solar modules which contain metal components arranged on a glass substrate, JP 2014/054593 A, for example, proposes a method in which the components are mechanically removed. For solar modules with a silicon substrate, the previously non-published DE 10 2021 129 301 discloses a method in which the adhesive layer arranged between the cover layer and the conductor tracks is heated so as to enable the cover layer to be removed from the rest of the solar module.

The disadvantage is that this method also cannot be used for all solar modules with a silicon base body. The invention is therefore based on the task of improving the method in such a way that it can be applied for a wider range of different solar modules.

The invention solves the addressed task by way of a method according to the preamble of claim 1, characterized in that, during the method, the adhesive layer is heated to an adhesive layer temperature and the lower side of the base body is cooled to a lower side temperature. Heating the adhesive layer makes it possible to remove the cover layer from the rest of the layer element. The cover layer is preferably a glass layer which, particularly preferably, is designed to be completely transparent for visible light. By heating the adhesive layer, the adhesive force of the adhesive layer decreases and the cover layer can be removed. The heat introduced into the adhesive layer spreads inside the layer element and gradually heats other layers and elements of the layer element. A plastic layer, for example of polyvinyl fluoride (PVF), is often arranged on the lower side of the base body. The material of this plastic layer is usually less heat-resistant than the base body, the cover layer and especially the adhesive layer. The heat introduced to heat the adhesive layer also heats the plastic layer and can cause it to disintegrate, which can release gases that are harmful and pose a health hazard. According to the invention, this is prevented by cooling the lower side of the base body to a lower side temperature.

Within the context of the present invention, processing a layer element comprises, for example, at least partially dismantling the layer element. In one preferred embodiment, this is achieved by either completely or partially removing the cover layer from the base body. This is preferably done without damaging or destroying the cover layer in the process. However, this is not necessarily the case. Even if the cover layer is damaged or destroyed during complete or partial removal from the base body and/or prior to complete or partial removal from the base body, it still constitutes “processing” within the context of the present invention.

This does not mean that the lower side is cooled during the method to a temperature below room temperature, for example. Prior to starting the method, the lower side of the base body of the layer element is at a temperature that is significantly lower than the lower side temperature that is aimed for during the method. All it means is that heat is dissipated from the lower side of the base body in order to achieve and preferably maintain the lower side temperature. The lower side temperature is lower than the adhesive layer temperature.

In order to cool the lower side of the base body to a lower side temperature, a cooling device is provided to dissipate heat from the lower side of the base body.

One difficulty that is eliminated by the method according to the invention is that the conductor tracks of the layer elements, for example of solar modules, which are produced from the valuable raw material, are not accessible from the outside. They are located on the upper side of the base body, but are covered by the cover layer, which is fixed by the at least one adhesive layer. Heating the adhesive layer reduces its adhesive effect so that the cover layer and base body can be removed from each other afterwards. The conductor tracks arranged on the upper side of the base body are then accessible. They are now removed from the base body by mechanical removal and the removed material is collected.

The layer element preferably refers to a solar module, wherein the layer element preferably comprises metallic conductor tracks which, particularly preferably, are arranged on the upper side of the base body and are covered by the cover layer.

Preferably, the adhesive layer temperature is at least 180° C., preferably at least 200° C., especially preferably at least 230° C., and at most 400° C., preferably at most 350° C., especially preferably at most 280° C. This is particularly advantageous if the adhesive layer is a layer made of or with ethylene-vinyl acetate (EVA). The adhesive layer temperature is preferably selected in such a way that pyrolysis of the adhesive layer does not occur, which can release partially poisonous and environmentally harmful gases. This is prevented by a temperature below 400° C. At a temperature of more than 180° C., preferably more than 200° C., acetic acid in an EVA adhesive layer is released, which creates a lubricating film between the layers connected by the adhesive layer. This causes forces of adhesion, which are applied by the adhesive layer, to decrease and the two connected elements can be separated from each other. Preferably, therefore, at least one EVA film is also used as an adhesive layer.

The lower side temperature is preferably at most 150° C., preferably at most 110° C., especially preferably at most 100° C. The lower this temperature, the smaller the effects of the heat on layers arranged on the lower side of the base body.

The base body preferably has a structure composed of multiple layers arranged next to each other. The lower side of the base body constitutes the lower side of the cover element that is processed using the method described here. For example, the base body has a substrate, which is preferably produced from silicon, particularly preferably made of silicon, and a charge-doped zone and a hole-doped zone. The metallic conductor tracks are arranged on the upper side of this substrate, which forms the upper side of the base body. The lower side of the substrate does not necessarily have to form the lower side of the layer element. Further layers, such as the previously mentioned plastic layer, can be arranged on the lower side of the substrate. The lower side of the base body preferably forms the lower side of the layer element.

In one preferred embodiment, the adhesive layer is heated by means of infrared radiation and/or magnetic induction and/or microwave radiation. In particular, it is advantageous when using infrared radiation or microwave radiation to apply the radiation through the cover layer, which is at least partially transparent, but preferably completely transparent, to the respective type of radiation. Infrared radiation used to heat the adhesive layer preferably has a wavelength between 1000 and 4000 nm, preferably from 1000 to 2000 nm.

If microwave radiation is used, it preferably has a frequency of between 2.4 GHz and 2.5 Ghz, preferably 2.45 GHz. Alternatively, the microwave radiation has a frequency of 5.8 GHz.

During heating by means of magnetic induction, alternating magnetic fields are used which preferably have a frequency of between 1 kHz and 500 kHz. A suitable frequency range is referred to as a low frequency range and encompasses frequencies between 1 kHz and 7 kHz. A different frequency range is referred to as a medium frequency range and contains frequencies between 8 kHz and 40 KHz. The high frequency range contains frequencies between 60 kHz and 500 kHz. The frequency used is preferably between 25 kHz and 300 kHz, especially preferably between 25 kHz and 100 KHz.

The invention also solves the addressed task by way of a device for carrying out one of the methods described here, characterized in that the device comprises a heating device for heating the adhesive layer of a layer element to the adhesive layer temperature and a cooling device for cooling the lower side of the base body of the layer element to the lower side temperature.

Preferably, the device has a holding device with which the layer element processed using the device is held. The device preferably has a workbench for supporting the layer element, the cooling device preferably being arranged within the workbench. In a particularly preferred embodiment, the workbench has a contact surface on which the layer element rests while the method is conducted. This contact surface can preferably be cooled by the cooling device. The holding device with which the layer element is held is, for example, a traction device for exerting a tensile force. It may comprise, for example, a negative pressure element, such as a suction element. The layer element is positioned, for example, on openings within the contact surface, which are sealed by the layer element. By applying a negative pressure or a suction force to the sealed openings, a suction force and therefore a tensile force is exerted on the layer element that holds it on the contact surface.

Alternatively or additionally, the holding device has a pressure device for exerting a compressive force. This compressive force causes the layer element to be pressed onto the contact surface. The pressure device preferably comprises at least one, preferably multiple, hold-down clamps. They can preferably be moved relative to the contact surface. The hold-down clamps are preferably removed from the contact surface in order to arrange a layer element to be processed on the contact surface. The hold-down clamps are then lowered until they come into contact with the layer element and are able to apply a compressive force to the layer element.

Preferably, the cooling device has at least one fluid channel, through which a coolant can be directed. The coolant is, for example, a cooling liquid such as water. The cooling device preferably has a pump, by means of which the coolant can be moved through the fluid channel. If the fluid channel is situated within the workbench, it is advantageous for said workbench to be made of a material with high thermal conductivity, for example a metal, such as aluminium or steel.

The at least one cooling channel is preferably located as close to the actual contact surface of the workbench as possible, for example at most 15 cm, preferably at most 10 cm, especially preferably at most 5 cm, away from the contact surface. The material of the workbench, at least the material of the workbench between the at least one cooling channel and the contact surface, preferably has a high thermal conductivity. The material is preferably a metal, such as aluminium or steel.

Alternatively or additionally, the cooling device has at least one fan through which the air can be directed onto the lower side of the layer element. The fan may be designed, for example, in the form of one or multiple ventilators, which are arranged and aligned such that they move air towards the lower side of the layer element.

Alternatively or additionally, the cooling device has at least one device for discharging compressed air. This device is configured such that the compressed air, which comes from a compressed air source that is preferably part of the cooling device, but is at least part of the device, is directed onto the lower side of the layer element. In the methods described here, the lower side of the layer element is preferably cooled via the fan and/or the device for discharging compressed air.

The device preferably has a first temperature sensor for detecting the adhesive layer temperature and/or a second temperature sensor for detecting the lower side temperature. Preferably, the first temperature sensor and/or the second temperature sensor have/has a pyrometer by means of which the temperatures that occur can be detected, preferably in a contactless manner.

The device preferably has an electronic control unit, especially preferably an electronic data processing device, which is configured to control the heating device and/or the cooling device depending on the detected adhesive layer temperature and/or the detected lower side temperature. To this end, the respective detected temperature is compared with a target temperature stored in an electronic memory. The target temperature may also be a temperature range, within which the detected temperature should lie. The electrical control unit is configured in such a way that it increases the power of the heating device and/or increases the duration of heating if the detected adhesive layer temperature is considered too low after comparison with a stored target temperature. Alternatively or additionally, the electrical control unit is preferably configured in such a way that it increases the power of the cooling device and/or increases the duration of cooling if the detected lower side temperature is considered too high after comparison with a stored target temperature.

In the following, a number of embodiment examples of the invention will be explained in more detail with the aid of the accompanying drawings. They show:

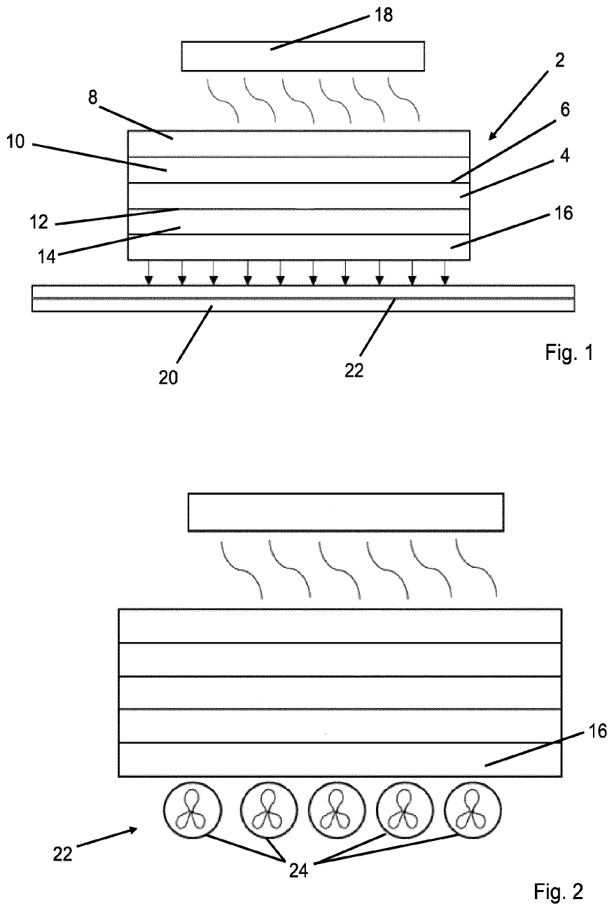

FIGS. 1 and 6—schematic views of a layer element in the method.

FIG. 1 depicts a layer element 2, which is designed as a solar module. It has a base body 4, on the upper side 6 of which conductor tracks are located, the latter not being depicted in the figures. The layer element 2 also has a cover layer 8 made, for example, of glass. The cover layer 8 is arranged on the base body 4 by means of an adhesive layer 10. A reverse side 16 is arranged on the lower side 12 of the base body 4, which is opposite the upper side 6, by means of a further adhesive layer 14. During the method, the layer element 2 should be processed, for example, by recycling it. To this end, the cover layer 8 must first be removed. To achieve this, the adhesive layer 10 is heated. In the embodiment example in FIG. 1, a heating unit 18 is used for this purpose. The upper side of the layer element 2 is heated via schematically depicted thermal radiation. Given that the cover layer 8 is at least partially, but preferably completely transparent for the radiation, which may also be visible light, such as laser radiation, the adhesive layer 10 is heated by the thermal radiation and thus loses at least part of its adhesive effect.

The reverse side 16 of the layer element 2 comes into contact with a workbench 20, in which a cooling device 22 is located. The latter is schematically represented as a solid line and may, for example, comprise cooling ducts through which a cooling medium is directed.

The only difference between FIG. 1 and FIG. 2 is a modified cooling device 22. In FIG. 2, it is designed in the form of multiple fans 24, by which air is directed to the reverse side 16 of the layer element. This can be achieved, for example, by way of openings in the workbench.

FIG. 2 depicts the layer element 2 as well as the heating unit 18. To be able to determine the temperature of the cover layer 8 and the reverse side 16, two temperature sensors 26 are provided. They can be used to measure the corresponding temperatures and transmit the measurement data to an electric control unit, not depicted, which controls the heating device and/or the cooling device.

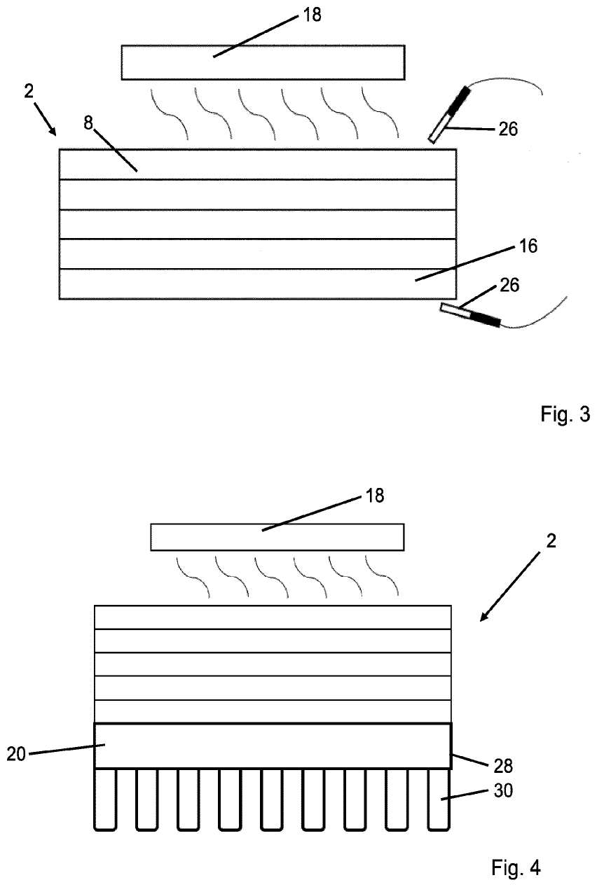

In the embodiment shown in FIG. 4, the layer element 2 rests on the workbench 20, which is designed as a cooling plate 28. Said cooling plate 28 forms part of the cooling device 22. In the embodiment example shown, the cooling device 22 also has cooling fins 30, which are arranged on the side of the workbench 20 facing away from the layer element 2. As a result, heat that is transferred from the layer element 2 to the workbench 20 and the cooling plate 28 can be discharged. The heat is preferably transferred to the surrounding air. To this end, the cooling fins 30 are preferably cooled by at least one, but preferably multiple fans, which are not shown in FIG. 4.

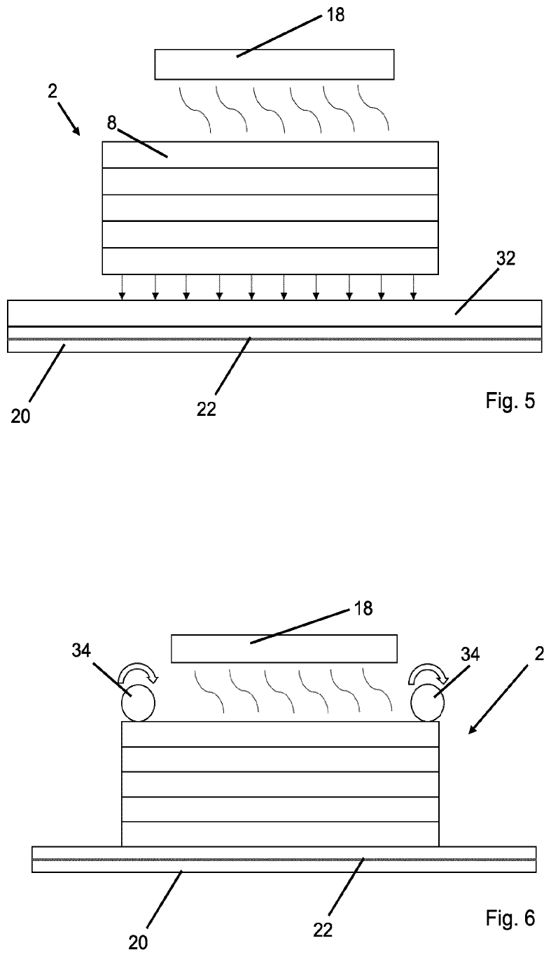

FIG. 5 shows a further embodiment. The layer element 2 is positioned on the workbench 20 in which the cooling device 22 is located, as in FIG. 1. In the embodiment example shown, a vacuum plate 32 is arranged between the layer element 2 and the part of the workbench 20 containing the cooling device, said vacuum plate applying a suction force to the layer element 2 and thereby firmly holding it on the workbench 20, of which the vacuum plate 32 is preferably a part.

FIG. 5 largely corresponds to FIG. 1. Conversely to this, in FIG. 6 the workbench 20 is not equipped with a holding device, such as a suction device. As such, the layer element 2 can be moved on the upper side of the workbench 20, for example to change the point heated by the heating unit 18. Rollers 34 are used for this purpose, which are depicted on the upper side of the layer element 2. The rollers can be rotated in two directions, one of which is illustrated by the arrow shown in FIG. 6.

### REFERENCE LIST

2 layer element
4 base body
6 upper side
8 cover layer
10 adhesive layer
12 lower side
14 adhesive layer
16 reverse side
18 heating unit
20 workbench
22 cooling device
24 fan
26 temperature sensor
28 cooling plate
30 cooling fin
32 vacuum plate
34 roller

1. A method for processing a layer element comprising
at least one base body with a lower side and an upper side opposite the lower side,
a cover layer that is at least partially transparent to visible light, and at least one adhesive layer arranged between the cover layer and the upper side, t
the method comprising
heating the adhesive layer to an adhesive layer temperature; and
cooling the lower side of the at least one base body to a lower side temperature.

2. The method according to claim 1, wherein the layer element is a solar module.

3. The method according to claim 1, wherein the adhesive layer temperature is at least 180° C.

4. The method according to claim 1 wherein the lower side temperature is at most 150° C.

5. The method according to claim 1 wherein the adhesive layer is heated by infrared radiation and/or magnetic induction and/or microwave radiation.

6. A device for carrying out a method according to claim 1, comprising:
at least one heating device for heating the adhesive layer of the layer element to the adhesive layer temperature; and
a cooling device for cooling the lower side of the base body of the layer element to the a lower side temperature.

7. The device according to claim 6, further comprising a workbench for supporting the layer element, wherein the cooling device is arranged in the workbench.

8. The device according to claim 6 wherein the cooling device comprises at least one fluid channel through which a cooling medium is directable.

9. The device according to claim 6 wherein the cooling device has at least one fan through which air is directable onto the lower side of the layer element.

10. The device according to claim 6 further comprising a first temperature sensor for detecting the adhesive layer temperature and/or a second temperature sensor for detecting the lower side temperature.

11. The device according to claim 10, further comprising an electric control unit configured to control the heating device and/or the cooling device depending on a detected adhesive layer temperature and/or a detected lower side temperature.

12. The method of claim 2 wherein the solar module metallic conductor tracks which are arranged on the upper side of the base body and are covered by the cover layer.

13. The method of claim 3 wherein the adhesive layer temperature ranges from 200° C. to 400° C.

14. The device according to claim 11 wherein the electric control unit is an electronic data processing device


SEQUENCE LISTING (69 sequences)

SEQ ID NO: 1 - DNA, 1293 bp, Streptomyces coelicolor
  source 1..1293: mol_type = genomic DNA
ttgaccgcgcttgctgacaccacggaaccgacctacgacttcgtgggcatcgggctgggcccgttcaacctggggctggcctgcctgaccgagcccgtcgacgaactcgccggggtcttcctggagtccaagccggacttcgcgtggcacgcggggatgttcctcgacggcgcgcacctgcagacgccgttcatgtcggacctggtcaccctcgccgacccgacctccccctactccttcctcaactacctgaaggagaagggccggctgtactcgttctacatccgggagaacttctacccgctgcgcgtcgagtacgacgactactgccgctgggccgccgcacagctgagcagcatccgcttcggcaccaccgtcaccgaggtcacgtgggacgagacggccgaggtgtacgtggtggccacctccaccggtacgacctaccgcggccggcacctggtgctcggcaccggcaccgtgccgttcgtgcccgaggcgtgccgggggctggagggcgacctcttccacaacgcgcagtacatgcggcgcaaggcggagctgctggagaagaagtcggtcacggtcgtgggcagcgggcagtccgccgccgagatctactacgagctgctctccgggatcgacgcccacggctatcagctgaactgggtcacccgctccccgcggttcttcccgctggagtacaccaagctgaccctggagatgacgtccccggactacatcgactacttccgcgcgctgcccgaggacacccgctaccgcctggagaagcagcagaagggcctgttcaagggcatcaactcggacctgatcgacgcgatcttcgacctgctgtaccagaagaacgtggagagcggcggccgcggcgtgcccacccggctgctcaccaactcctcgctcaccaccgcccggtaccaggacggcacctacacgctcggcttccgccaggacgagcagggcaaggacttcgagatcgccaccgagggcctggtgctggccaccggctaccactacgagcagcccgccttcctggagccggtgcgtgaccggctgcgcttcgacggccacggccggttcgacgtcgcccgcaactacgcgatcgacgtcaccgggcgcggcgtgttcctgcagaacgcgggcgtgcacacgcacagcatcaccagccccgacctgggcatgggcgcctaccgcaacgcctcgatcatccgcgagctgctgggcaccgagtactacccggtcgagaagagcatcgccttccaggagttcgccgtatga

SEQ ID NO: 2 - DNA, 543 bp, Streptomyces coelicolor
  source 1..543: mol_type = genomic DNA
atgagcaccatcggtacgttcacgatccgcccgctcgacccggagaaggacgcggagctgctgcaccgctgggtgacgcatcccaaggcggcgttctggatgatgcaggacgcgaggctcgaggacgtcgagcgcgagtacatgcgcatcgccgcccacgagcaccaccacgcctacctgggcctgcacgacggcgagcccgccttcctgatggagaagtacgacccccggcacgtcgaactcgtcgggctctacgagcccgagcccggtgacgtcggcatgcacttcctggtcgcccccaccgaccgccccgtccacggcttcacccgcgccgtcatcaccgccgtgatggaggagctgttcgccgacccggccacccgccgggtcgtggtggagccggacgtcggcaacaaggccgtgcacgccctgaacgaggccgtgggttttgaacccgagcgcgagatcgacaagccggagaagcgcgcgctgctgagcttctgcacgcgtgaacagttcgaggccgcccgaggagcttccgcatga

SEQ ID NO: 3 - DNA, 1773 bp, Streptomyces coelicolor
  source 1..1773: mol_type = genomic DNA
atgaccctgtccgacgccgtggcgcacctgtccccccaccgctgggcgcgggccaaccgtctgctgatccgcaaggcgctcgccgagttcgcgcacgagcggctcgtcacgccggagccggccggcgacggccggtacgtcgtccgcagcgacgacggcgagacccgctacacgttcaccgcgaagctgcgcggcctggaccactggcagatcgacgccggctcgatcacccgtcatcgcgacggcgtcgaactcgagctcgccgcgctggacttcttcatcgagctgcagaagtccctggggctgagcgacgagatcctgccggtgtacctggaggagatctcctccaccctctccggcacctgctacaagctgaccaagccggaggtcacctcggccgagctggtcgacgccgggttccaggcgatcgagaccggcatgaccgagggccacccctgcttcgtcgccaacaacgggcggctcggcttcggcgtccacgagtaccggtggtacgccccggaggccgcgaacccggtgcggctggtgtggctggccgcccaccactcgcgggccgcgttcaccgcgggtgcgggcatcgagtacgagtcgttcgtccgccaggagctgggcgaggagaccgtcgaccggttccacgacgtcctgcgcgcgcaggacctggaccccgccgactacctgctggtccccgtccacccctggcagtggtggaacaagctgtccgtcaccttcgccgccgaggtcgcccgccggcacctggtgttgctgggcgagggcgacgacgagtacctggcgcagcagtccatacgtaccttcttcaaccgctcccatccggagaagcactatgtgaagacggcgctgtccgtcctcaacatgggcttcatgaggggcctgtcggccgcctacatggaggccactccggccatcaacgactggctggcccgcctgatcgacaacgacccggtgctgcggtccacgggactgtcgatcatccgggagcgcgccgccgtggggtaccggcacctggagtacgagcaggccaccgaccgctactcgccgtaccgcaagatgctggcggcgctgtggcgggagagcccggtggcgtccctggaggacggcgagtcgctcgccaccatggcgtccctggtccacgtcgaccacgagggccggtccttcgccgccgccctgatcgagcgctccgggctcaccccggccgagtggctgcggcgctacctgcgggcctactacgtcccgctgctgcacagcttctacgcctacgacctggtgtacatgccccacggcgagaacgtcatcctggtgctggaggacggcgccgtgaagcgcgcggtctacaaggacatcgccgaggagatcgcggtgatggacccggacgcggtactgccgccggaggtgtcccggatccgcgtcgaggtccccgacgacaccaagctgctgtccatcttcacggacgtcttcgactgcttcttccgcttcctcgcggcgaacctcgccgaggagggcgttctcgacgaggacggcttctggcggacggtcgcggaggtcacccgcgagtaccaggcgtcggtgccggagctgacggacaagttcgcccggtacgacctgttcgccccggagttcgcgctgtcctgcctgaaccgcctccagttgcgcaacaacaagcagatggtcgacctggcggacccctcgggcgccctccagctcgtgggcaccctgaggaaccccctggcggccttctga

SEQ ID NO: 4 - protein, 430 aa, Streptomyces coelicolor
LTALADTTEPTYDFVGIGLGPFNLGLACLTEPVDELAGVFLESKPDFAWHAGMFLDGAHLQTPFMSDLVTLADPTSPYSFLNYLKEKGRLYSFYIRENFYPLRVEYDDYCRWAAAQLSSIRFGTTVTEVTWDETAEVYVVATSTGTTYRGRHLVLGTGTVPFVPEACRGLEGDLFHNAQYMRRKAELLEKKSVTVVGSGQSAAEIYYELLSGIDAHGYQLNWVTRSPRFFPLEYTKLTLEMTSPDYIDYFRALPEDTRYRLEKQQKGLFKGINSDLIDAIFDLLYQKNVESGGRGVPTRLLTNSSLTTARYQDGTYTLGFRQDEQGKDFEIATEGLVLATGYHYEQPAFLEPVRDRLRFDGHGRFDVARNYAIDVTGRGVFLQNAGVHTHSITSPDLGMGAYRNASIIRELLGTEYYPVEKSIAFQEFAV

SEQ ID NO: 5 - protein, 180 aa, Streptomyces coelicolor
MSTIGTFTIRPLDPEKDAELLHRWVTHPKAAFWMMQDARLEDVEREYMRIAAHEHHHAYLGLHDGEPAFLMEKYDPRHVELVGLYEPEPGDVGMHFLVAPTDRPVHGFTRAVITAVMEELFADPATRRVVVEPDVGNKAVHALNEAVGFEPEREIDKPEKRALLSFCTREQFEAARGASA

SEQ ID NO: 6 - protein, 590 aa, Streptomyces coelicolor
MTLSDAVAHLSPHRWARANRLLIRKALAEFAHERLVTPEPAGDGRYVVRSDDGETRYTFTAKLRGLDHWQIDAGSITRHRDGVELELAALDFFIELQKSLGLSDEILPVYLEEISSTLSGTCYKLTKPEVTSAELVDAGFQAIETGMTEGHPCFVANNGRLGFGVHEYRWYAPEAANPVRLVWLAAHHSRAAFTAGAGIEYESFVRQELGEETVDRFHDVLRAQDLDPADYLLVPVHPWQWWNKLSVTFAAEVARRHLVLLGEGDDEYLAQQSIRTFFNRSHPEKHYVKTALSVLNMGFMRGLSAAYMEATPAINDWLARLIDNDPVLRSTGLSIIRERAAVGYRHLEYEQATDRYSPYRKMLAALWRESPVASLEDGESLATMASLVHVDHEGRSFAAALIERSGLTPAEWLRRYLRAYYVPLLHSFYAYDLVYMPHGENVILVLEDGAVKRAVYKDIAEEIAVMDPDAVLPPEVSRIRVEVPDDTKLLSIFTDVFDCFFRFLAANLAEEGVLDEDGFWRTVAEVTREYQASVPELTDKFARYDLFAPEFALSCLNRLQLRNNKQMVDLADPSGALQLVGTLRNPLAAF

SEQ ID NO: 7 - DNA, 3732 bp, synthetic construct
  misc_feature 1..3732: note = vector construct
  source 1..3732: mol_type = other DNA
aagcttccgtcctcgacctgatcgccggccacgccgagcagtacctgggagagtcccttgaccgcgcttgctgacaccacggaaccgacctacgacttcgtgggcatcgggctgggcccgttcaacctggggctggcctgcctgaccgagcccgtcgacgaactcgccggggtcttcctggagtccaagccggacttcgcgtggcacgcggggatgttcctcgacggcgcgcacctgcagacgccgttcatgtcggacctggtcaccctcgccgacccgacctccccctactccttcctcaactacctgaaggagaagggccggctgtactcgttctacatccgggagaacttctacccgctgcgcgtcgagtacgacgactactgccgctgggccgccgcacagctgagcagcatccgcttcggcaccaccgtcaccgaggtcacgtgggacgagacggccgaggtgtacgtggtggccacctccaccggtacgacctaccgcggccggcacctggtgctcggcaccggcaccgtgccgttcgtgcccgaggcgtgccgggggctggagggcgacctcttccacaacgcgcagtacatgcggcgcaaggcggagctgctggagaagaagtcggtcacggtcgtgggcagcgggcagtccgccgccgagatctactacgagctgctctccgggatcgacgcccacggctatcagctgaactgggtcacccgctccccgcggttcttcccgctggagtacaccaagctgaccctggagatgacgtccccggactacatcgactacttccgcgcgctgcccgaggacacccgctaccgcctggagaagcagcagaagggcctgttcaagggcatcaactcggacctgatcgacgcgatcttcgacctgctgtaccagaagaacgtggagagcggcggccgcggcgtgcccacccggctgctcaccaactcctcgctcaccaccgcccggtaccaggacggcacctacacgctcggcttccgccaggacgagcagggcaaggacttcgagatcgccaccgagggcctggtgctggccaccggctaccactacgagcagcccgccttcctggagccggtgcgtgaccggctgcgcttcgacggccacggccggttcgacgtcgcccgcaactacgcgatcgacgtcaccgggcgcggcgtgttcctgcagaacgcgggcgtgcacacgcacagcatcaccagccccgacctgggcatgggcgcctaccgcaacgcctcgatcatccgcgagctgctgggcaccgagtactacccggtcgagaagagcatcgccttccaggagttcgccgtatgagcaccatcggtacgttcacgatccgcccgctcgacccggagaaggacgcggagctgctgcaccgctgggtgacgcatcccaaggcggcgttctggatgatgcaggacgcgaggctcgaggacgtcgagcgcgagtacatgcgcatcgccgcccacgagcaccaccacgcctacctgggcctgcacgacggcgagcccgccttcctgatggagaagtacgacccccggcacgtcgaactcgtcgggctctacgagcccgagcccggtgacgtcggcatgcacttcctggtcgcccccaccgaccgccccgtccacggcttcacccgcgccgtcatcaccgccgtgatggaggagctgttcgccgacccggccacccgccgggtcgtggtggagccggacgtcggcaacaaggccgtgcacgccctgaacgaggccgtgggttttgaacccgagcgcgagatcgacaagccggagaagcgcgcgctgctgagcttctgcacgcgtgaacagttcgaggccgcccgaggagcttccgcatgaccctgtccgacgccgtggcgcacctgtccccccaccgctgggcgcgggccaaccgtctgctgatccgcaaggcgctcgccgagttcgcgcacgagcggctcgtcacgccggagccggccggcgacggccggtacgtcgtccgcagcgacgacggcgagacccgctacacgttcaccgcgaagctgcgcggcctggaccactggcagatcgacgccggctcgatcacccgtcatcgcgacggcgtcgaactcgagctcgccgcgctggacttcttcatcgagctgcagaagtccctggggctgagcgacgagatcctgccggtgtacctggaggagatctcctccaccctctccggcacctgctacaagctgaccaagccggaggtcacctcggccgagctggtcgacgccgggttccaggcgatcgagaccggcatgaccgagggccacccctgcttcgtcgccaacaacgggcggctcggcttcggcgtccacgagtaccggtggtacgccccggaggccgcgaacccggtgcggctggtgtggctggccgcccaccactcgcgggccgcgttcaccgcgggtgcgggcatcgagtacgagtcgttcgtccgccaggagctgggcgaggagaccgtcgaccggttccacgacgtcctgcgcgcgcaggacctggaccccgccgactacctgctggtccccgtccacccctggcagtggtggaacaagctgtccgtcaccttcgccgccgaggtcgcccgccggcacctggtgttgctgggcgagggcgacgacgagtacctggcgcagcagtccatacgtaccttcttcaaccgctcccatccggagaagcactatgtgaagacggcgctgtccgtcctcaacatgggcttcatgaggggcctgtcggccgcctacatggaggccactccggccatcaacgactggctggcccgcctgatcgacaacgacccggtgctgcggtccacgggactgtcgatcatccgggagcgcgccgccgtggggtaccggcacctggagtacgagcaggccaccgaccgctactcgccgtaccgcaagatgctggcggcgctgtggcgggagagcccggtggcgtccctggaggacggcgagtcgctcgccaccatggcgtccctggtccacgtcgaccacgagggccggtccttcgccgccgccctgatcgagcgctccgggctcaccccggccgagtggctgcggcgctacctgcgggcctactacgtcccgctgctgcacagcttctacgcctacgacctggtgtacatgccccacggcgagaacgtcatcctggtgctggaggacggcgccgtgaagcgcgcggtctacaaggacatcgccgaggagatcgcggtgatggacccggacgcggtactgccgccggaggtgtcccggatccgcgtcgaggtccccgacgacaccaagctgctgtccatcttcacggacgtcttcgactgcttcttccgcttcctcgcggcgaacctcgccgaggagggcgttctcgacgaggacggcttctggcggacggtcgcggaggtcacccgcgagtaccaggcgtcggtgccggagctgacggacaagttcgcccggtacgacctgttcgccccggagttcgcgctgtcctgcctgaaccgcctccagttgcgcaacaacaagcagatggtcgacctggcggacccctcgggcgccctccagctcgtgggcaccctgaggaaccccctggcggccttctgaccgcatcggacggacgagcccccggagtacggtcctccgggggcttcgtcacaccctcaggcgcgacgaagctt

SEQ ID NO: 8 - DNA, 10317 bp, synthetic construct
  misc_feature 1..10317: note = Vector construct
  source 1..10317: mol_type = other DNA
aattaccgtcctcgacctgatcgccggccacgccgagcagtacctgggagagtcccttgaccgcgcttgctgacaccacggaaccgacctacgacttcgtgggcatcgggctgggcccgttcaacctggggctggcctgcctgaccgagcccgtcgacgaactcgccggggtcttcctggagtccaagccggacttcgcgtggcacgcggggatgttcctcgacggcgcgcacctgcagacgccgttcatgtcggacctggtcaccctcgccgacccgacctccccctactccttcctcaactacctgaaggagaagggccggctgtactcgttctacatccgggagaacttctacccgctgcgcgtcgagtacgacgactactgccgctgggccgccgcacagctgagcagcatccgcttcggcaccaccgtcaccgaggtcacgtgggacgagacggccgaggtgtacgtggtggccacctccaccggtacgacctaccgcggccggcacctggtgctcggcaccggcaccgtgccgttcgtgcccgaggcgtgccgggggctggagggcgacctcttccacaacgcgcagtacatgcggcgcaaggcggagctgctggagaagaagtcggtcacggtcgtgggcagcgggcagtccgccgccgagatctactacgagctgctctccgggatcgacgcccacggctatcagctgaactgggtcacccgctccccgcggttcttcccgctggagtacaccaagctgaccctggagatgacgtccccggactacatcgactacttccgcgcgctgcccgaggacacccgctaccgcctggagaagcagcagaagggcctgttcaagggcatcaactcggacctgatcgacgcgatcttcgacctgctgtaccagaagaacgtggagagcggcggccgcggcgtgcccacccggctgctcaccaactcctcgctcaccaccgcccggtaccaggacggcacctacacgctcggcttccgccaggacgagcagggcaaggacttcgagatcgccaccgagggcctggtgctggccaccggctaccactacgagcagcccgccttcctggagccggtgcgtgaccggctgcgcttcgacggccacggccggttcgacgtcgcccgcaactacgcgatcgacgtcaccgggcgcggcgtgttcctgcagaacgcgggcgtgcacacgcacagcatcaccagccccgacctgggcatgggcgcctaccgcaacgcctcgatcatccgcgagctgctgggcaccgagtactacccggtcgagaagagcatcgccttccaggagttcgccgtatgagcaccatcggtacgttcacgatccgcccgctcgacccggagaaggacgcggagctgctgcaccgctgggtgacgcatcccaaggcggcgttctggatgatgcaggacgcgaggctcgaggacgtcgagcgcgagtacatgcgcatcgccgcccacgagcaccaccacgcctacctgggcctgcacgacggcgagcccgccttcctgatggagaagtacgacccccggcacgtcgaactcgtcgggctctacgagcccgagcccggtgacgtcggcatgcacttcctggtcgcccccaccgaccgccccgtccacggcttcacccgcgccgtcatcaccgccgtgatggaggagctgttcgccgacccggccacccgccgggtcgtggtggagccggacgtcggcaacaaggccgtgcacgccctgaacgaggccgtgggttttgaacccgagcgcgagatcgacaagccggagaagcgcgcgctgctgagcttctgcacgcgtgaacagttcgaggccgcccgaggagcttccgcatgaccctgtccgacgccgtggcgcacctgtccccccaccgctgggcgcgggccaaccgtctgctgatccgcaaggcgctcgccgagttcgcgcacgagcggctcgtcacgccggagccggccggcgacggccggtacgtcgtccgcagcgacgacggcgagacccgctacacgttcaccgcgaagctgcgcggcctggaccactggcagatcgacgccggctcgatcacccgtcatcgcgacggcgtcgaactcgagctcgccgcgctggacttcttcatcgagctgcagaagtccctggggctgagcgacgagatcctgccggtgtacctggaggagatctcctccaccctctccggcacctgctacaagctgaccaagccggaggtcacctcggccgagctggtcgacgccgggttccaggcgatcgagaccggcatgaccgagggccacccctgcttcgtcgccaacaacgggcggctcggcttcggcgtccacgagtaccggtggtacgccccggaggccgcgaacccggtgcggctggtgtggctggccgcccaccactcgcgggccgcgttcaccgcgggtgcgggcatcgagtacgagtcgttcgtccgccaggagctgggcgaggagaccgtcgaccggttccacgacgtcctgcgcgcgcaggacctggaccccgccgactacctgctggtccccgtccacccctggcagtggtggaacaagctgtccgtcaccttcgccgccgaggtcgcccgccggcacctggtgttgctgggcgagggcgacgacgagtacctggcgcagcagtccatacgtaccttcttcaaccgctcccatccggagaagcactatgtgaagacggcgctgtccgtcctcaacatgggcttcatgaggggcctgtcggccgcctacatggaggccactccggccatcaacgactggctggcccgcctgatcgacaacgacccggtgctgcggtccacgggactgtcgatcatccgggagcgcgccgccgtggggtaccggcacctggagtacgagcaggccaccgaccgctactcgccgtaccgcaagatgctggcggcgctgtggcgggagagcccggtggcgtccctggaggacggcgagtcgctcgccaccatggcgtccctggtccacgtcgaccacgagggccggtccttcgccgccgccctgatcgagcgctccgggctcaccccggccgagtggctgcggcgctacctgcgggcctactacgtcccgctgctgcacagcttctacgcctacgacctggtgtacatgccccacggcgagaacgtcatcctggtgctggaggacggcgccgtgaagcgcgcggtctacaaggacatcgccgaggagatcgcggtgatggacccggacgcggtactgccgccggaggtgtcccggatccgcgtcgaggtccccgacgacaccaagctgctgtccatcttcacggacgtcttcgactgcttcttccgcttcctcgcggcgaacctcgccgaggagggcgttctcgacgaggacggcttctggcggacggtcgcggaggtcacccgcgagtaccaggcgtcggtgccggagctgacggacaagttcgcccggtacgacctgttcgccccggagttcgcgctgtcctgcctgaaccgcctccagttgcgcaacaacaagcagatggtcgacctggcggacccctcgggcgccctccagctcgtgggcaccctgaggaaccccctggcggccttctgaccgcatcggacggacgagcccccggagtacggtcctccgggggcttcgtcacaccctcaggcgcgacgtgcatgcctgcaggtcgactctagaggatccccgggtaccgagctcgaattcagcttggctgttttggcggatgagagaagattttcagcctgatacagattaaatcagaacgcagaagcggtctgataaaacagaatttgcctggcggcagtagcgcggtggtcccacctgaccccatgccgaactcagaagtgaaacgccgtagcgccgatggtagtgtggggtctccccatgcgagagtagggaactgccaggcatcaaataaaacgaaaggctcagtcgaaagactgggcctttcgttttatctgttgtttgtcggtgaacgctctcctgagtaggacaaatccgccgggagcggatttgaacgttgcgaagcaacggcccggagggtggcgggcaggacgcccgccataaactgccaggcatcaaattaagcagaaggccatcctgacggatggcctttttgcgtttctacaaactcttttgtttatttttctaaatacattcaaatatgtatccgctcatgagacaataaccctgataaatgcttcaataatattgaaaaaggaagagtatgagtattcaacatttccgtgtcgcccttattcccttttttgcggcattttgccttcctgtttttgctcacccagaaacgctggtgaaagtaaaagatgctgaagatcagttgggtgcacgagtgggttacatcgaactggatctcaacagcggtaagatccttgagagttttcgccccgaagaacgttttccaatgatgagcacttttgcttcctcgctcactgactcgctgcgctcggtcgttcggctgcggcgagcggtatcagctcactcaaaggcggtaatacggttatccacagaatcaggggataacgcaggaaagaacatgtgagcaaaaggccagcaaaaggccaggaaccgtaaaaaggccgcgttgctggcgtttttccataggctccgcccccctgacgagcatcacaaaaatcgacgctcaagtcagaggtggcgaaacccgacaggactataaagataccaggcgtttccccctggaagctccctcgtgcgctctcctgttccgaccctgccgcttaccggatacctgtccgcctttctcccttcgggaagcgtggcgctttctcaatgctcacgctgtaggtatctcagttcggtgtaggtcgttcgctccaagctgggctgtgtgcacgaaccccccgttcagcccgaccgctgcgccttatccggtaactatcgtcttgagtccaacccggtaagacacgacttatcgccactggcagcagccactggtaacaggattagcagagcgaggtatgtaggcggtgctacagagttcttgaagtggtggcctaactacggctacactagaaggacagtatttggtatctgcgctctgctgaagccagttaccttcggaaaaagagttggtagctcttgatccggcaaacaaaccaccgctggtagcggtggtttttttgtttgcaagcagcagattacgcgcagaaaaaaaggatctcaagaagatcctttgatcttttctacggggtctgacgctcagtggaacgaaaactcacgttaagggattttggtcatgagattatcaaaaaggatcttcacctagatccttttggggtgggcgaagaactccagcatgagatccccgcgctggaggatcatccagccattcggggtcgttcactggttcccctttctgatttctggcatagaagaacccccgtgaactgtgtggttccgggggttgctgatttttgcgagacttctcgcgcaattccctagcttaggtgaaaacaccatgaaacactagggaaacacccatgaaacacccattagggcagtagggcggcttcttcgtctagggcttgcatttgggcggtgatctggtctttagcgtgtgaaagtgtgtcgtaggtggcgtgctcaatgcactcgaacgtcacgtcatttaccgggtcacggtgggcaaagagaactagtgggttagacattgttttcctcgttgtcggtggtggtgagcttttctagccgctcggtaaacgcggcgatcatgaactcttggaggttttcaccgttctgcatgcctgcgcgcttcatgtcctcacgtagtgccaaaggaacgcgtgcggtgaccacgacgggcttagcctttgcctgcgcttctagtgcttcgatggtggcttgtgcctgcgcttgctgcgcctgtagtgcctgttgagcttcttgtagttgctgttctagctgtgccttggttgccatgctttaagactctagtagctttcctgcgatatgtcatgcgcatgcgtagcaaacattgtcctgcaactcattcattatgtgcagtgctcctgttactagtcgtacatactcatatttacctagtctgcatgcagtgcatgcacatgcagtcatgtcgtgctaatgtgtaaaacatgtacatgcagattgctgggggtgcagggggcggagccaccctgtccatgcggggtgtggggcttgccccgccggtacagacagtgagcaccggggcacctagtcgcggataccccccctaggtatcggacacgtaaccctcccatgtcgatgcaaatctttaacattgagtacgggtaagctggcacgcatagccaagctaggcggccaccaaacaccactaaaaattaatagtccctagacaagacaaacccccgtgcgagctaccaactcatatgcacgggggccacataacccgaaggggtttcaattgacaaccatagcactagctaagacaacgggcacaacacccgcacaaactcgcactgcgcaaccccgcacaacatcgggtctaggtaacactgagtaacactgaaatagaagtgaacacctctaaggaaccgcaggtcaatgagggttctaaggtcactcgcgctagggcgtggcgtaggcaaaacgtcatgtacaagatcaccaatagtaaggctctggcggggtgccataggtggcgcagggacgaagctgttgcggtgtcctggtcgtctaacggtgcttcgcagtttgagggtctgcaaaactctcactctcgctgggggtcacctctggctgaattggaagtcatgggcgaacgccgcattgagctggctattgctactaagaatcacttggcggcgggtggcgcgctcatgatgtttgtgggcactgttcgacacaaccgctcacagtcatttgcgcaggttgaagcgggtattaagactgcgtactcttcgatggtgaaaacatctcagtggaagaaagaacgtgcacggtacggggtggagcacacctatagtgactatgaggtcacagactcttgggcgaacggttggcacttgcaccgcaacatgctgttgttcttggatcgtccactgtctgacgatgaactcaaggcgtttgaggattccatgttttcccgctggtctgctggtgtggttaaggccggtatggacgcgccactgcgtgagcacggggtcaaacttgatcaggtgtctacctggggtggagacgctgcgaaaatggcaacctacctcgctaagggcatgtctcaggaactgactggctccgctactaaaaccgcgtctaaggggtcgtacacgccgtttcagatgttggatatgttggccgatcaaagcgacgccggcgaggatatggacgctgttttggtggctcggtggcgtgagtatgaggttggttctaaaaacctgcgttcgtcctggtcacgtggggctaagcgtgctttgggcattgattacatagacgctgatgtacgtcgtgaaatggaagaagaactgtacaagctcgccggtctggaagcaccggaacgggtcgaatcaacccgcgttgctgttgctttggtgaagcccgatgattggaaactgattcagtctgatttcgcggttaggcagtacgttctcgattgcgtggataaggctaaggacgtggccgctgcgcaacgtgtcgctaatgaggtgctggcaagtctgggtgtggattccaccccgtgcatgatcgttatggatgatgtggacttggacgcggttctgcctactcatggggacgctactaagcgtgatctgaatgcggcggtgttcgcgggtaatgagcagactattcttcgcacccactaaaagcggcataaaccccgttcgatattttgtgcgatgaatttatggtcaatgtcgcgggggcaaactatgatgggtcttgttgttggcgtcccggaaaacgattccgaagcccaacctttcatagaaggcggcggtggaatcgaaatctcgtgatggcaggttgggcgtcgcttggtcggtcatttcgaagggcaccaataactgccttaaaaaaattacgccccgccctgccactcatcgcagtactgttgtaattcattaagcattctgccgacatggaagccatcacagacggcatgatgaacctgaatcgccagcggcatcagcaccttgtcgccttgcgtataatatttgcccatggtgaaaacgggggcgaagaagttgtccatattggccacgtttaaatcaaaactggtgaaactcacccagggattggctgagacgaaaaacatattctcaataaaccctttagggaaataggccaggttttcaccgtaacacgccacatcttgcgaatatatgtgtagaaactgccggaaatcgtcgtggtattcactccagagcgatgaaaacgtttcagtttgctcatggaaaacggtgtaacaagggtgaacactatcccatatcaccagctcaccgtctttcattgccatacggaactccggatgagcattcatcaggcgggcaagaatgtgaataaaggccggataaaacttgtgcttatttttctttacggtctttaaaaaggccgtaatatccagctgaacggtctggttataggtacattgagcaactgactgaaatgcctcaaaatgttctttacgatgccattgggatatatcaacggtggtatatccagtgatttttttctccattttagcttccttagctcctgaaaatctcgtcgaagctcggcggatttgtcctactcaagctgatccgacaaaatccacacattatcccaggtgtccggatcggtcaaatacgctgccagctcatagaccgtatccaaagcatccggggctgatccccggcgccagggtggtttttcttttcaccagtgagacgggcaacagctgattgcccttcaccgcctggccctgagagagttgcagcaagcggtccacgtggtttgccccagcaggcgaaaatcctgtttgatggtggttaacggcgggatataacatgagctgtcttcggtatcgtcgtatcccactaccgagatatccgcaccaacgcgcagcccggactcggtaatggcgcgcattgcgcccagcgccatctgatcgttggcaaccagcatcgcagtgggaacgatgccctcattcagcatttgcatggtttgttgaaaaccggacatggcactccagtcgccttcccgttccgctatcggctgaatttgattgcgagtgagatatttatgccagccagccagacgcagacgcgccgagacagaacttaatgggcccgctaacagcgcgatttgctggtgacccaatgcgaccagatgctccacgcccagtcgcgtaccgtcttcatgggagaaaataatactgttgatgggtgtctggtcagagacatcaagaaataacgccggaacattagtgcaggcagcttccacagcaatggcatcctggtcatccagcggatagttaatgatcagcccactgacgcgttgcgcgagaagattgtgcaccgccgctttacaggcttcgacgccgcttcgttctaccatcgacaccaccacgctggcacccagttgatcggcgcgagatttaatcgccgcgacaatttgcgacggcgcgtgcagggccagactggaggtggcaacgccaatcagcaacgactgtttgcccgccagttgttgtgccacgcggttgggaatgtaattcagctccgccatcgccgcttccactttttcccgcgttttcgcagaaacgtggctggcctggttcaccacgcgggaaacggtctgataagagacaccggcatactctgcgacatcgtataacgttactggtttcacattcaccaccctgaattgactctcttccgggcgctatcatgccataccgcgaaaggttttgcaccattcgatggtgtcaacgtaaatgccgcttcgccttcgcgcgcgaattgcaagctgatccgggcttatcgactgcacggtgcaccaatgcttctggcgtcaggcagccatcggaagctgtggtatggctgtgcaggtcgtaaatcactgcataattcgtgtcgctcaaggcgcactcccgttctggataatgttttttgcgccgacatcataacggttctggcaaatattctgaaatgagctgttgacaattaatcatcggctcgtataatgtgtggaattgtgagcggataacaatttcacacaggaaacagaatt

SEQ ID NO: 9 - DNA, 3779 bp, synthetic construct
  misc_feature 1..3779: note = Vector construct
  source 1..3779: mol_type = other DNA
aagcttccgtcctcgacctgatcgccggccacgccgtgcaggaaggagatatagatatgaccgctcttgctgacaccaccgagccaacctacgacttcgtcggcatcggtcttggacctttcaacctgggtctggcatgtctcaccgagccagtcgacgagctagcaggtgttttcctggaatccaagccagacttcgcttggcacgcgggaatgttcctggacggcgcccacctgcagaccccattcatgtccgacctggtcaccctggctgaccctaccagcccttacagctttctgaactaccttaaggagaagggacgtctttacagcttctacatccgcgaaaacttttacccactgcgtgtggaatacgacgattactgccgttgggcagctgcacagttatcctccatccgcttcggtaccacagtcaccgaagtcacctgggatgaaaccgctgaagtgtacgtcgtcgcgaccagcaccggtaccacgtaccgcggtcgtcatctggttctgggaaccggcaccgtcccgttcgtccctgaggcatgccgcggattggaaggcgaccttttccacaacgcacagtacatgcgtcgcaaggcagaactcctcgagaagaagtcggttaccgttgttggctccggccagtccgctgctgaaatctactacgagctcctttccggtatcgacgcacacggctaccaactaaactgggtcacccgctccccccgcttcttccctctcgaatacaccaagctcaccctcgaaatgacctcccccgactacattgattactttcgcgctctgcctgaagacacccgctaccgcctggaaaagcaacagaagggcctgttcaagggcatcaattcagacctcatcgacgcaatcttcgacctcctgtaccagaagaacgtcgaatccggtggccgcggcgtccccactcgcctgctcaccaactcctccctgaccaccgcccgctaccaggacggcacctacacacttggcttccgccaagacgaacagggaaaggatttcgaaatcgctactgagggcctggtcctcgccaccggctaccactacgaacagccagccttcctagagccagtccgcgatcgcctccgcttcgacggtcacggccgttttgatgtagcacgcaactacgctatcgatgttacaggccgcggcgtgttcctccagaacgcaggcgttcacacccactccatcacctccccagacctcggcatgggcgcataccgcaatgccagcattatccgcgaactgctgggcaccgaatactacccagtcgagaaatccatcgcattccaagaattcgccgtctgatgcaggaaggagatatagatatgtccaccatcggtaccttcaccatccgccctcttgacccagagaaggacgcggagttgctgcaccgctgggtgacccacccaaaggccgcattctggatgatgcaggacgcacgcctagaagacgtagagcgcgaatacatgcgcatcgctgctcacgagcaccaccacgcctacctgggcctgcacgacggagagcctgctttcctcatggaaaaatacgacccacgccacgtcgaactggtgggcctgtacgaaccagaaccaggagacgttggcatgcacttcctcgtagcgccaaccgaccgcccagttcacggcttcacccgcgccgtcatcaccgccgttatggaagaactgttcgctgatcctgcgacccgccgcgtcgtcgttgagccagacgtcggcaacaaggctgtgcacgccctcaacgaagcagttggcttcgaacccgaacgcgaaatcgacaagccagagaagcgcgcactgctttccttctgcacccgcgaacagttcgaagcagctcgcggcgcctccgcctgatgcaggaaggagatatagatatgaccctgtccgacgccgtggctcacctgtccccacaccgctgggctcgcgcaaaccgtctgctcatccgcaaagctctggcagagttcgctcacgaacgtctcgttacccctgaacccgcaggcgacggtcgctacgttgttcgctccgacgacggcgagacccgctacactttcaccgctaagctccgcggcctagaccactggcagatcgacgcaggctccattacccgccaccgcgatggcgttgagctcgagctggctgcactggacttcttcatcgaactccagaaatccctcgggctctctgacgagatcctgccagtctatctggaggagatctcctcgaccctttctggtacctgctacaagctgaccaaacccgaagtcacctccgcagagctggtcgacgcaggcttccaggctatcgaaactggtatgaccgaaggtcacccctgcttcgttgcaaacaatggccgtctgggcttcggcgttcacgaataccgctggtacgctccagaggccgcaaacccagttcgtctagtttggctcgcagcccaccactcccgcgcagctttcaccgcaggcgctggaatcgagtacgaatccttcgttcgccaggagcttggcgaagagaccgtcgatcgtttccacgacgttctgcgcgcccaagacctcgaccctgctgattacctgctcgtcccagttcatccatggcaatggtggaacaagctgagcgtcacctttgcagcggaggtcgcccgtcgccacctcgtcctgctgggcgaaggtgatgacgaataccttgcacagcaaagcattcgcacctttttcaaccgttcccaccctgaaaagcactacgtcaagactgccctctcagtactcaatatgggcttcatgcgcggcctctccgcagcatacatggaggccaccccagcaatcaacgactggcttgctcgccttatcgataatgacccagttctccgttccaccggcctgtccattatccgcgaacgtgctgcagttggctaccggcaccttgaatacgaacaggcaaccgaccgctactccccataccgcaaaatgttggcagcactttggcgcgaatccccagtagcatccctcgaggacggcgagtccctggccaccatggcttcactcgttcacgtggaccacgaaggccgctccttcgctgctgctctgatcgagcgctctggtctcaccccagctgaatggctgcgccgctaccttcgtgcttactacgtgccattgctgcactcattctacgcatacgatctcgtctacatgccacacggcgagaacgtcatcttggtgctcgaggatggcgcggtgaagcgcgcagtctacaaggacatcgctgaagagatcgcagtgatggacccagacgcagttctgccacctgaggtttcccgcatccgcgtcgaagttccagacgacaccaagctcctgagcatcttcaccgatgtcttcgactgcttcttccgtttcctggctgctaatctcgcggaagaaggcgtcctcgatgaggacggtttctggcgtaccgtcgcagaggtgacacgcgaataccaagcatcagttccagagctcaccgacaagttcgcacgttacgatcttttcgcacccgaattcgctctgtcctgcctgaaccgcctccagctccgcaacaacaagcagatggttgatctcgcagacccttccggcgccctgcagctggttggaaccctccgcaaccctctcgcggcattctgaccgcatcggacggacgagcccccggagtacggtcctccgggggcttcgtcacaccctcaggcgcgacgaagctt

SEQ ID NO: 10 - DNA, 10414 bp, synthetic construct
  misc_feature 1..10414: note = vector construct
  source 1..10414: mol_type = other DNA
aattattcacacaggaaacagaattaattaccgtcctcgacctgatcgccggccacgccgtgcaggaaggagatatagatatgaccgctcttgctgacaccaccgagccaacctacgacttcgtcggcatcggtcttggacctttcaacctgggtctggcatgtctcaccgagccagtcgacgagctagcaggtgttttcctggaatccaagccagacttcgcttggcacgcgggaatgttcctggacggcgcccacctgcagaccccattcatgtccgacctggtcaccctggctgaccctaccagcccttacagctttctgaactaccttaaggagaagggacgtctttacagcttctacatccgcgaaaacttttacccactgcgtgtggaatacgacgattactgccgttgggcagctgcacagttatcctccatccgcttcggtaccacagtcaccgaagtcacctgggatgaaaccgctgaagtgtacgtcgtcgcgaccagcaccggtaccacgtaccgcggtcgtcatctggttctgggaaccggcaccgtcccgttcgtccctgaggcatgccgcggattggaaggcgaccttttccacaacgcacagtacatgcgtcgcaaggcagaactcctcgagaagaagtcggttaccgttgttggctccggccagtccgctgctgaaatctactacgagctcctttccggtatcgacgcacacggctaccaactaaactgggtcacccgctccccccgcttcttccctctcgaatacaccaagctcaccctcgaaatgacctcccccgactacattgattactttcgcgctctgcctgaagacacccgctaccgcctggaaaagcaacagaagggcctgttcaagggcatcaattcagacctcatcgacgcaatcttcgacctcctgtaccagaagaacgtcgaatccggtggccgcggcgtccccactcgcctgctcaccaactcctccctgaccaccgcccgctaccaggacggcacctacacacttggcttccgccaagacgaacagggaaaggatttcgaaatcgctactgagggcctggtcctcgccaccggctaccactacgaacagccagccttcctagagccagtccgcgatcgcctccgcttcgacggtcacggccgttttgatgtagcacgcaactacgctatcgatgttacaggccgcggcgtgttcctccagaacgcaggcgttcacacccactccatcacctccccagacctcggcatgggcgcataccgcaatgccagcattatccgcgaactgctgggcaccgaatactacccagtcgagaaatccatcgcattccaagaattcgccgtctgatgcaggaaggagatatagatatgtccaccatcggtaccttcaccatccgccctcttgacccagagaaggacgcggagttgctgcaccgctgggtgacccacccaaaggccgcattctggatgatgcaggacgcacgcctagaagacgtagagcgcgaatacatgcgcatcgctgctcacgagcaccaccacgcctacctgggcctgcacgacggagagcctgctttcctcatggaaaaatacgacccacgccacgtcgaactggtgggcctgtacgaaccagaaccaggagacgttggcatgcacttcctcgtagcgccaaccgaccgcccagttcacggcttcacccgcgccgtcatcaccgccgttatggaagaactgttcgctgatcctgcgacccgccgcgtcgtcgttgagccagacgtcggcaacaaggctgtgcacgccctcaacgaagcagttggcttcgaacccgaacgcgaaatcgacaagccagagaagcgcgcactgctttccttctgcacccgcgaacagttcgaagcagctcgcggcgcctccgcctgatgcaggaaggagatatagatatgaccctgtccgacgccgtggctcacctgtccccacaccgctgggctcgcgcaaaccgtctgctcatccgcaaagctctggcagagttcgctcacgaacgtctcgttacccctgaacccgcaggcgacggtcgctacgttgttcgctccgacgacggcgagacccgctacactttcaccgctaagctccgcggcctagaccactggcagatcgacgcaggctccattacccgccaccgcgatggcgttgagctcgagctggctgcactggacttcttcatcgaactccagaaatccctcgggctctctgacgagatcctgccagtctatctggaggagatctcctcgaccctttctggtacctgctacaagctgaccaaacccgaagtcacctccgcagagctggtcgacgcaggcttccaggctatcgaaactggtatgaccgaaggtcacccctgcttcgttgcaaacaatggccgtctgggcttcggcgttcacgaataccgctggtacgctccagaggccgcaaacccagttcgtctagtttggctcgcagcccaccactcccgcgcagctttcaccgcaggcgctggaatcgagtacgaatccttcgttcgccaggagcttggcgaagagaccgtcgatcgtttccacgacgttctgcgcgcccaagacctcgaccctgctgattacctgctcgtcccagttcatccatggcaatggtggaacaagctgagcgtcacctttgcagcggaggtcgcccgtcgccacctcgtcctgctgggcgaaggtgatgacgaataccttgcacagcaaagcattcgcacctttttcaaccgttcccaccctgaaaagcactacgtcaagactgccctctcagtactcaatatgggcttcatgcgcggcctctccgcagcatacatggaggccaccccagcaatcaacgactggcttgctcgccttatcgataatgacccagttctccgttccaccggcctgtccattatccgcgaacgtgctgcagttggctaccggcaccttgaatacgaacaggcaaccgaccgctactccccataccgcaaaatgttggcagcactttggcgcgaatccccagtagcatccctcgaggacggcgagtccctggccaccatggcttcactcgttcacgtggaccacgaaggccgctccttcgctgctgctctgatcgagcgctctggtctcaccccagctgaatggctgcgccgctaccttcgtgcttactacgtgccattgctgcactcattctacgcatacgatctcgtctacatgccacacggcgagaacgtcatcttggtgctcgaggatggcgcggtgaagcgcgcagtctacaaggacatcgctgaagagatcgcagtgatggacccagacgcagttctgccacctgaggtttcccgcatccgcgtcgaagttccagacgacaccaagctcctgagcatcttcaccgatgtcttcgactgcttcttccgtttcctggctgctaatctcgcggaagaaggcgtcctcgatgaggacggtttctggcgtaccgtcgcagaggtgacacgcgaataccaagcatcagttccagagctcaccgacaagttcgcacgttacgatcttttcgcacccgaattcgctctgtcctgcctgaaccgcctccagctccgcaacaacaagcagatggttgatctcgcagacccttccggcgccctgcagctggttggaaccctccgcaaccctctcgcggcattctgaccgcatcggacggacgagcccccggagtacggtcctccgggggcttcgtcacaccctcaggcgcgacgtgcatgcctgcaggtcgactctagatgcatgcctgcaggtcgactctagaggatccccgggtaccgagctcgaattcagcttggctgttttggcggatgagagaagattttcagcctgatacagattaaatcagaacgcagaagcggtctgataaaacagaatttgcctggcggcagtagcgcggtggtcccacctgaccccatgccgaactcagaagtgaaacgccgtagcgccgatggtagtgtggggtctccccatgcgagagtagggaactgccaggcatcaaataaaacgaaaggctcagtcgaaagactgggcctttcgttttatctgttgtttgtcggtgaacgctctcctgagtaggacaaatccgccgggagcggatttgaacgttgcgaagcaacggcccggagggtggcgggcaggacgcccgccataaactgccaggcatcaaattaagcagaaggccatcctgacggatggcctttttgcgtttctacaaactcttttgtttatttttctaaatacattcaaatatgtatccgctcatgagacaataaccctgataaatgcttcaataatattgaaaaaggaagagtatgagtattcaacatttccgtgtcgcccttattcccttttttgcggcattttgccttcctgtttttgctcacccagaaacgctggtgaaagtaaaagatgctgaagatcagttgggtgcacgagtgggttacatcgaactggatctcaacagcggtaagatccttgagagttttcgccccgaagaacgttttccaatgatgagcacttttgcttcctcgctcactgactcgctgcgctcggtcgttcggctgcggcgagcggtatcagctcactcaaaggcggtaatacggttatccacagaatcaggggataacgcaggaaagaacatgtgagcaaaaggccagcaaaaggccaggaaccgtaaaaaggccgcgttgctggcgtttttccataggctccgcccccctgacgagcatcacaaaaatcgacgctcaagtcagaggtggcgaaacccgacaggactataaagataccaggcgtttccccctggaagctccctcgtgcgctctcctgttccgaccctgccgcttaccggatacctgtccgcctttctcccttcgggaagcgtggcgctttctcaatgctcacgctgtaggtatctcagttcggtgtaggtcgttcgctccaagctgggctgtgtgcacgaaccccccgttcagcccgaccgctgcgccttatccggtaactatcgtcttgagtccaacccggtaagacacgacttatcgccactggcagcagccactggtaacaggattagcagagcgaggtatgtaggcggtgctacagagttcttgaagtggtggcctaactacggctacactagaaggacagtatttggtatctgcgctctgctgaagccagttaccttcggaaaaagagttggtagctcttgatccggcaaacaaaccaccgctggtagcggtggtttttttgtttgcaagcagcagattacgcgcagaaaaaaaggatctcaagaagatcctttgatcttttctacggggtctgacgctcagtggaacgaaaactcacgttaagggattttggtcatgagattatcaaaaaggatcttcacctagatccttttggggtgggcgaagaactccagcatgagatccccgcgctggaggatcatccagccattcggggtcgttcactggttcccctttctgatttctggcatagaagaacccccgtgaactgtgtggttccgggggttgctgatttttgcgagacttctcgcgcaattccctagcttaggtgaaaacaccatgaaacactagggaaacacccatgaaacacccattagggcagtagggcggcttcttcgtctagggcttgcatttgggcggtgatctggtctttagcgtgtgaaagtgtgtcgtaggtggcgtgctcaatgcactcgaacgtcacgtcatttaccgggtcacggtgggcaaagagaactagtgggttagacattgttttcctcgttgtcggtggtggtgagcttttctagccgctcggtaaacgcggcgatcatgaactcttggaggttttcaccgttctgcatgcctgcgcgcttcatgtcctcacgtagtgccaaaggaacgcgtgcggtgaccacgacgggcttagcctttgcctgcgcttctagtgcttcgatggtggcttgtgcctgcgcttgctgcgcctgtagtgcctgttgagcttcttgtagttgctgttctagctgtgccttggttgccatgctttaagactctagtagctttcctgcgatatgtcatgcgcatgcgtagcaaacattgtcctgcaactcattcattatgtgcagtgctcctgttactagtcgtacatactcatatttacctagtctgcatgcagtgcatgcacatgcagtcatgtcgtgctaatgtgtaaaacatgtacatgcagattgctgggggtgcagggggcggagccaccctgtccatgcggggtgtggggcttgccccgccggtacagacagtgagcaccggggcacctagtcgcggataccccccctaggtatcggacacgtaaccctcccatgtcgatgcaaatctttaacattgagtacgggtaagctggcacgcatagccaagctaggcggccaccaaacaccactaaaaattaatagtccctagacaagacaaacccccgtgcgagctaccaactcatatgcacgggggccacataacccgaaggggtttcaattgacaaccatagcactagctaagacaacgggcacaacacccgcacaaactcgcactgcgcaaccccgcacaacatcgggtctaggtaacactgagtaacactgaaatagaagtgaacacctctaaggaaccgcaggtcaatgagggttctaaggtcactcgcgctagggcgtggcgtaggcaaaacgtcatgtacaagatcaccaatagtaaggctctggcggggtgccataggtggcgcagggacgaagctgttgcggtgtcctggtcgtctaacggtgcttcgcagtttgagggtctgcaaaactctcactctcgctgggggtcacctctggctgaattggaagtcatgggcgaacgccgcattgagctggctattgctactaagaatcacttggcggcgggtggcgcgctcatgatgtttgtgggcactgttcgacacaaccgctcacagtcatttgcgcaggttgaagcgggtattaagactgcgtactcttcgatggtgaaaacatctcagtggaagaaagaacgtgcacggtacggggtggagcacacctatagtgactatgaggtcacagactcttgggcgaacggttggcacttgcaccgcaacatgctgttgttcttggatcgtccactgtctgacgatgaactcaaggcgtttgaggattccatgttttcccgctggtctgctggtgtggttaaggccggtatggacgcgccactgcgtgagcacggggtcaaacttgatcaggtgtctacctggggtggagacgctgcgaaaatggcaacctacctcgctaagggcatgtctcaggaactgactggctccgctactaaaaccgcgtctaaggggtcgtacacgccgtttcagatgttggatatgttggccgatcaaagcgacgccggcgaggatatggacgctgttttggtggctcggtggcgtgagtatgaggttggttctaaaaacctgcgttcgtcctggtcacgtggggctaagcgtgctttgggcattgattacatagacgctgatgtacgtcgtgaaatggaagaagaactgtacaagctcgccggtctggaagcaccggaacgggtcgaatcaacccgcgttgctgttgctttggtgaagcccgatgattggaaactgattcagtctgatttcgcggttaggcagtacgttctcgattgcgtggataaggctaaggacgtggccgctgcgcaacgtgtcgctaatgaggtgctggcaagtctgggtgtggattccaccccgtgcatgatcgttatggatgatgtggacttggacgcggttctgcctactcatggggacgctactaagcgtgatctgaatgcggcggtgttcgcgggtaatgagcagactattcttcgcacccactaaaagcggcataaaccccgttcgatattttgtgcgatgaatttatggtcaatgtcgcgggggcaaactatgatgggtcttgttgttggcgtcccggaaaacgattccgaagcccaacctttcatagaaggcggcggtggaatcgaaatctcgtgatggcaggttgggcgtcgcttggtcggtcatttcgaagggcaccaataactgccttaaaaaaattacgccccgccctgccactcatcgcagtactgttgtaattcattaagcattctgccgacatggaagccatcacagacggcatgatgaacctgaatcgccagcggcatcagcaccttgtcgccttgcgtataatatttgcccatggtgaaaacgggggcgaagaagttgtccatattggccacgtttaaatcaaaactggtgaaactcacccagggattggctgagacgaaaaacatattctcaataaaccctttagggaaataggccaggttttcaccgtaacacgccacatcttgcgaatatatgtgtagaaactgccggaaatcgtcgtggtattcactccagagcgatgaaaacgtttcagtttgctcatggaaaacggtgtaacaagggtgaacactatcccatatcaccagctcaccgtctttcattgccatacggaactccggatgagcattcatcaggcgggcaagaatgtgaataaaggccggataaaacttgtgcttatttttctttacggtctttaaaaaggccgtaatatccagctgaacggtctggttataggtacattgagcaactgactgaaatgcctcaaaatgttctttacgatgccattgggatatatcaacggtggtatatccagtgatttttttctccattttagcttccttagctcctgaaaatctcgtcgaagctcggcggatttgtcctactcaagctgatccgacaaaatccacacattatcccaggtgtccggatcggtcaaatacgctgccagctcatagaccgtatccaaagcatccggggctgatccccggcgccagggtggtttttcttttcaccagtgagacgggcaacagctgattgcccttcaccgcctggccctgagagagttgcagcaagcggtccacgtggtttgccccagcaggcgaaaatcctgtttgatggtggttaacggcgggatataacatgagctgtcttcggtatcgtcgtatcccactaccgagatatccgcaccaacgcgcagcccggactcggtaatggcgcgcattgcgcccagcgccatctgatcgttggcaaccagcatcgcagtgggaacgatgccctcattcagcatttgcatggtttgttgaaaaccggacatggcactccagtcgccttcccgttccgctatcggctgaatttgattgcgagtgagatatttatgccagccagccagacgcagacgcgccgagacagaacttaatgggcccgctaacagcgcgatttgctggtgacccaatgcgaccagatgctccacgcccagtcgcgtaccgtcttcatgggagaaaataatactgttgatgggtgtctggtcagagacatcaagaaataacgccggaacattagtgcaggcagcttccacagcaatggcatcctggtcatccagcggatagttaatgatcagcccactgacgcgttgcgcgagaagattgtgcaccgccgctttacaggcttcgacgccgcttcgttctaccatcgacaccaccacgctggcacccagttgatcggcgcgagatttaatcgccgcgacaatttgcgacggcgcgtgcagggccagactggaggtggcaacgccaatcagcaacgactgtttgcccgccagttgttgtgccacgcggttgggaatgtaattcagctccgccatcgccgcttccactttttcccgcgttttcgcagaaacgtggctggcctggttcaccacgcgggaaacggtctgataagagacaccggcatactctgcgacatcgtataacgttactggtttcacattcaccaccctgaattgactctcttccgggcgctatcatgccataccgcgaaaggttttgcaccattcgatggtgtcaacgtaaatgccgcttcgccttcgcgcgcgaattgcaagctgatccgggcttatcgactgcacggtgcaccaatgcttctggcgtcaggcagccatcggaagctgtggtatggctgtgcaggtcgtaaatcactgcataattcgtgtcgctcaaggcgcactcccgttctggataatgttttttgcgccgacatcataacggttctggcaaatattctgaaatgagctgttgacaattaatcatcggctcgtataatgtgtggaattgtgagcggataacaatttcacacaggaaacagaatt

SEQ ID NO: 11 - DNA, 1443 bp, Streptomyces violaceoruber
  source 1..1443: mol_type = genomic DNA
atgcgctcgcacctgctcaacgacaccaccgcggagcagtaccgccgttccgtgaccgaaggagtcgagcgggtggccgccaaactcgccaccaccgaccgcccgttcaccggcgtcacggtcgacgccctctccccccgcatcgacgcgatcgacctcgacgagccgctgcacgacaccgccgcggtcctcgacgagctggaggacgtctacctccgcgacgccgtctacttccaccacccccgctacctcgcccacctcaactgcccggtcgtcataccggcgctgctcggtgaagcggtcctgtccgccgtcaactcctccctggacacctgggaccagtcggccggcggcacgctcatcgagcggaagctgatcgactggacctgcgcccgcatcggcctcggcccggcggccgacggcgtgttcacctccggcggcacccagtccaacctccaggcgctgctcctcgcccgcgaggaggcgaaggccgaggacttcgccgacctgcggatcttcgcctccgaggccagccacttcagcgtcaggaagtccgcgaaactgctcggcctcggccccgacgccgtcgtgtcgatcccggtcgaccgcgacaagcggatgcagaccgtcgccctcgcccgcgagctggagcgctgcgcgcgggacggcctggtccccatggccgtcgtcgccaccggcggcaccaccgacttcggctcgatcgacccgctgccggagatcgccgggctgtgcgagcagtacggcgtgtggatgcacgtcgacgcggcctacggctgcgggctgctcgcctccctgaagtaccgggaccgcatcaccggcatcgagcgggccgactcggtcaccgtggactaccacaagtccttcttccagccggtgagttcgtcggccgtgctggtccgggacgcggccaccctgcgccacgccacctaccacgcggagtacctcaacccgcgccgcatggtgcaggaacgtatccccaaccaggtggacaagtccctccagaccacccgccgcttcgacgcgctcaagctgtggatgacgctgcgcgtgatgggcgccgacggcatcggcgtcctcttcgacgaggtgtgcgacctggccgccgagggctggaaactgctcgccgccgacccgcgcttcgacgtcgtggtccagccgtcgctgtccacgctggtcttccgccacatcccggcggacgtcaccgatcccgccgagatcgaccgcgccaacctgtacgcccgcaaggccctgttcgcgtccggcgacgccgtggtcgcgggcaccaaggtcgccggtcgccactacctgaagttcaccctgctcaaccccgagacgaccccggccgacatcgccgccgtcctcgacctgatcgccggccacgccgagcagtacctgggagactcccttgaccgcgcttcctga

SEQ ID NO: 12 - DNA, 1281 bp, Streptomyces violaceoruber
  source 1..1281: mol_type = genomic DNA
ttgaccgcgcttcctgaagccagcgccccgtacgacttcgtgggcatcggcctcggccccttcaacctcggcctcgcctgcctcaccgagcccgtcgccgagctgaacggcgtcttcctggagtccaagccggacttcgagtggcacgccgggatgttcctggacggcgcccacctccagaccccgttcatgtcggacctggtgacgctcgccgacccgacctcgccgtactccttcctcaactacctgaaggagcagggccggctgtactccttctacatccgggagaacttctacccgctgcgggtcgagtacgacgactactgccgctgggccgcgcgcaagctgagcagcgtccgcttctccaccacggtcaccgaggtcacgtacgacgagcgcgaggagctgtacgccgtcgccaccacgtccggcgacacctaccgcgcccgccgcctcgtcctcggcaccggcaccccgccgcacatcccggacgcctgccggggcctggccggcgacttcctccacaactcccggtacgtgcggcaccgggcggagctggtgaagaagaagtcgatcacgctggtcggcagcggccagtccgccgccgagatctaccaggacctgctgagcgagatcgacgtccacggctacgggctgaactgggtgacccgctccccgcggttcttcccgctcgaatacaccaagctcaccctggagatgacgtccccggagtacgtggactactaccacgcgctgcccgaggacacccgctaccgcctcacggccgagcagaagggcctgttcaagggcatcgacggcgacctgatcaacgagatcttcgacctgctctaccagaaacggctcggcggccccgtccccacccgcctgctcaccaactcggcgctgaccagcgcccggtatgcggacggcacctacacgctcgggttccgccaggaggagcagggcacggacttcgagatcgagaccgagggcctggtcctcgccaccggctaccggtacaccgagccggagttcctcaagcccgtccgggaccggctgcgctacgactcccgcggcaacttcgacatcggccgcaactacgccgtcgacgtcacgggaggcggcgtgttcctccagaacgcgggggtccacgcgcacagcgtcaccagccccgacctgggcatgggcgcctaccgcaacagctgcatcgtccgggagctgctcggacgcgagtactacccggtcgagcagtcgatcgcgttccaggagttcgccgtatga

SEQ ID NO: 13 - DNA, 555 bp, Streptomyces violaceoruber
  source 1..555: mol_type = genomic DNA
atgagccgcttgagcaccaccacccccgtcggggcactgaccctgcgccccgtcgacccgctgacggacgccgtactgctgcacggctggctcacccaccccaagtccgcgttctggatgatgcaggacgcccggctggtggacgtcgagcgggcctacatggagctggccgccgacgagcaccagcaggcccacctcggcctgcacgacggggtcccggccttcctgacggagcgctacgaccccgcccaccgcgaactggtcgggctgtacgagcccgagccgggcgacgtcggcatgcacttcctggtcgcgcccaccgaccggcccgtgcacggcttcacccgcgccgtgatcaccaccgtgatgacggagctgttcgccgacccggcgacccggcgggtcgtcgtcgaaccggacgtcaccaacaccgccgtgcacgccctgaacgcagccgtcggattcgtgcccgagcgcgagatccagaagccggagaagaaggccttgctgagcttctgcacccgcgagcagttcgcgaaggcggtgtccgcatga

SEQ ID NO: 14 - DNA, 1788 bp, Streptomyces violaceoruber
  source 1..1788: mol_type = genomic DNA
atgagcctcgccgacgccgtcgcccacctgacccccgaacgctgggaggaggccaaccgcctcctggtccgcaaggcgctggccgagttcacccacgagcggctgctgacccccgagcgggagccggacgacgggggcgggcagacgtacgtcgtccgcagcgacgacggccagaccgcgtaccgcttcaccgccaccgtccgcgccctggaccactggcaggtggacgccgcctccgtcacccgccaccgcgacggcgcggaactcccgctcgccgcgctggacttcttcatcgagctgaagcagaccctgggcctgagcgacgagatcctcccggtctacctggaggagatctcctccaccctctccggcacctgctacaaactgaccaagccgcagctcagctccgccgagctggcccggagcggagacttccaggccgtcgagacgggcatgaccgagggccacccgtgcttcgtcgccaacaacgggcgcctcggcttcggcatccacgagtacctgtcgtacgcccccgagaccgcgagcccggtccggctggtgtggctggccgcgcaccgctcgcgggcggcgttcacggcgggcgtgggcatcgagtacgagtccttcgtccgggacgagctgggcgcggccaccgtcgaccgcttccacggcgtgctgcgcgggcgcggcctggacccggccgactacctgctcatcccggtccacccctggcagtggtggaacaagctcaccgtcaccttcgccgccgaggtcgcccgcgggcacctggtgtgcctgggcgagggcgacgacgagtacctggcccagcagtccatccgcaccttcttcaacgcctcgcaccccgggaagcactacgtgaagactgccctgtccgtcctcaacatgggcttcatgcgcggtctgtcggcggcgtacatggaggccactccggccatcaacgactggctcgcccggctgatcgagggcgacccggtgctgaaggagacggggctgagcatcatccgggagcgggcggccgtcggctaccggcacctggagtacgagcaggccaccgaccgctactcgccctaccgcaagatgctggcggcgctgtggcgggagagcccggtgccgtccatccgggagggcgagacgctcgccaccatggcctccctggtccaccaggaccacgagggcgcctccttcgcgggcgcgctgatcgagcggtccggactcacgcccaccgagtggctgcggcactacctgcgggcctactacgtcccgctgctgcacagcttctacgcctacgacctggtgtacatgccgcacggcgagaacgtgatcctggtgctggcggacggggtggtgcggcgggcggtctacaaggacatcgccgaggagatcgcggtgatggacccggacgcggtgctgccgccggaggtctcccgcatcgcggtggacgtgccggacgacaagaagctcctgtcgatcttcacggacgtcttcgactgcttcttccgcttcctggccgcgaacctggcggaggaggggatcgtcacggaggacgccttctggcggacggtcgcggaggtcacccgggagtaccaggagtcggtgccggagctggccgacaagttcgagcggtacgacatgttcgcgcccgagttcgccctgtcctgcctcaaccggctccagctgcgcgacaaccggcagatggtggacctggccgacccgtccggcgcgctccagctcgtcggcaccctgaagaaccccctggcaggccggtag

SEQ ID NO: 15 - protein, 480 aa, Streptomyces violaceoruber
MRSHLLNDTTAEQYRRSVTEGVERVAAKLATTDRPFTGVTVDALSPRIDAIDLDEPLHDTAAVLDELEDVYLRDAVYFHHPRYLAHLNCPVVIPALLGEAVLSAVNSSLDTWDQSAGGTLIERKLIDWTCARIGLGPAADGVFTSGGTQSNLQALLLAREEAKAEDFADLRIFASEASHFSVRKSAKLLGLGPDAVVSIPVDRDKRMQTVALARELERCARDGLVPMAVVATGGTTDFGSIDPLPEIAGLCEQYGVWMHVDAAYGCGLLASLKYRDRITGIERADSVTVDYHKSFFQPVSSSAVLVRDAATLRHATYHAEYLNPRRMVQERIPNQVDKSLQTTRRFDALKLWMTLRVMGADGIGVLFDEVCDLAAEGWKLLAADPRFDVVVQPSLSTLVFRHIPADVTDPAEIDRANLYARKALFASGDAVVAGTKVAGRHYLKFTLLNPETTPADIAAVLDLIAGHAEQYLGDSLDRAS

SEQ ID NO: 16 - protein, 420 aa, Streptomyces violaceoruber
LTALPEASAPYDFVGIGLGPFNLGLACLTEPVAELNGVFLESKPDFEWHAGMFLDGAHLQTPFMSDLVTLADPTSPYSFLNYLKEQGRLYSFYIRENFYPLRVEYDDYCRWAARKLSSVRFSTTVTEVTYDEREELYAVATTSGDTYRARRLVLGTGTPPHIPDACRGLAGDFLHNSRYVRHRAELVKKKSITLVGSGQSAAEIYQDLLSEIDVHGYGLNWVTRSPRFFPLEYTKLTLEMTSPEYVDYYHALPEDTRYRLTAEQKGLFKGIDGDLINEIFDLLYQKRLGGPVPTRLLTNSALTSARYADGTYTLGFRQEEQGTDFEIETEGLVLATGYRYTEPEFLKPVRDRLRYDSRGNFDIGRNYAVDVTGGGVFLQNAGVHAHSVTSPDLGMGAYRNSCIVRELLGREYYPVEQSIA

SEQ ID NO: 17 - protein, 184 aa, Streptomyces violaceoruber
MSRLSTTTPVGALTLRPVDPLTDAVLLHGWLTHPKSAFWMMQDARLVDVERAYMELAADEHQQAHLGLHDGVPAFLTERYDPAHRELVGLYEPEPGDVGMHFLVAPTDRPVHGFTRAVITTVMTELFADPATRRVVVEPDVTNTAVHALNAAVGFVPEREIQKPEKKALLSFCTREQFAKAVSA

SEQ ID NO: 18 - protein, 595 aa, Streptomyces violaceoruber
MSLADAVAHLTPERWEEANRLLVRKALAEFTHERLLTPEREPDDGGGQTYVVRSDDGQTAYRFTATVRALDHWQVDAASVTRHRDGAELPLAALDFFIELKQTLGLSDEILPVYLEEISSTLSGTCYKLTKPQLSSAELARSGDFQAVETGMTEGHPCFVANNGRLGFGIHEYLSYAPETASPVRLVWLAAHRSRAAFTAGVGIEYESFVRDELGAATVDRFHGVLRGRGLDPADYLLIPVHPWQWWNKLTVTFAAEVARGHLVCLGEGDDEYLAQQSIRTFFNASHPGKHYVKTALSVLNMGFMRGLSAAYMEATPAINDWLARLIEGDPVLKETGLSIIRERAAVGYRHLEYEQATDRYSPYRKMLAALWRESPVPSIREGETLATMASLVHQDHEGASFAGALIERSGLTPTEWLRHYLRAYYVPLLHSFYAYDLVYMPHGENVILVLADGVVRRAVYKDIAEEIAVMDPDAVLPPEVSRIAVDVPDDKKLLSIFTDVFDCFFRFLAANLAEEGIVTEDAFWRTVAEVTREYQESVPELADKFERYDMFAPEFALSCLNRLQLRDNRQMVDLADPSGALQLVGTLKNPLAGR

SEQ ID NO: 19 - DNA, 5120 bp, synthetic construct
  misc_feature 1..5120: note = Vector Construct
  source 1..5120: mol_type = other DNA
acaggaaacagaattaattaagcttccccaccggaggacccccccatgcgctcgcacctgctcaacgacaccaccgcggagcagtaccgccgttccgtgaccgaaggagtcgagcgggtggccgccaaactcgccaccaccgaccgcccgttcaccggcgtcacggtcgacgccctctccccccgcatcgacgcgatcgacctcgacgagccgctgcacgacaccgccgcggtcctcgacgagctggaggacgtctacctccgcgacgccgtctacttccaccacccccgctacctcgcccacctcaactgcccggtcgtcataccggcgctgctcggtgaagcggtcctgtccgccgtcaactcctccctggacacctgggaccagtcggccggcggcacgctcatcgagcggaagctgatcgactggacctgcgcccgcatcggcctcggcccggcggccgacggcgtgttcacctccggcggcacccagtccaacctccaggcgctgctcctcgcccgcgaggaggcgaaggccgaggacttcgccgacctgcggatcttcgcctccgaggccagccacttcagcgtcaggaagtccgcgaaactgctcggcctcggccccgacgccgtcgtgtcgatcccggtcgaccgcgacaagcggatgcagaccgtcgccctcgcccgcgagctggagcgctgcgcgcgggacggcctggtccccatggccgtcgtcgccaccggcggcaccaccgacttcggctcgatcgacccgctgccggagatcgccgggctgtgcgagcagtacggcgtgtggatgcacgtcgacgcggcctacggctgcgggctgctcgcctccctgaagtaccgggaccgcatcaccggcatcgagcgggccgactcggtcaccgtggactaccacaagtccttcttccagccggtgagttcgtcggccgtgctggtccgggacgcggccaccctgcgccacgccacctaccacgcggagtacctcaacccgcgccgcatggtgcaggaacgtatccccaaccaggtggacaagtccctccagaccacccgccgcttcgacgcgctcaagctgtggatgacgctgcgcgtgatgggcgccgacggcatcggcgtcctcttcgacgaggtgtgcgacctggccgccgagggctggaaactgctcgccgccgacccgcgcttcgacgtcgtggtccagccgtcgctgtccacgctggtcttccgccacatcccggcggacgtcaccgatcccgccgagatcgaccgcgccaacctgtacgcccgcaaggccctgttcgcgtccggcgacgccgtggtcgcgggcaccaaggtcgccggtcgccactacctgaagttcaccctgctcaaccccgagacgaccccggccgacatcgccgccgtcctcgacctgatcgccggccacgccgagcagtacctgggagactcccttgaccgcgcttcctgaagccagcgccccgtacgacttcgtgggcatcggcctcggccccttcaacctcggcctcgcctgcctcaccgagcccgtcgccgagctgaacggcgtcttcctggagtccaagccggacttcgagtggcacgccgggatgttcctggacggcgcccacctccagaccccgttcatgtcggacctggtgacgctcgccgacccgacctcgccgtactccttcctcaactacctgaaggagcagggccggctgtactccttctacatccgggagaacttctacccgctgcgggtcgagtacgacgactactgccgctgggccgcgcgcaagctgagcagcgtccgcttctccaccacggtcaccgaggtcacgtacgacgagcgcgaggagctgtacgccgtcgccaccacgtccggcgacacctaccgcgcccgccgcctcgtcctcggcaccggcaccccgccgcacatcccggacgcctgccggggcctggccggcgacttcctccacaactcccggtacgtgcggcaccgggcggagctggtgaagaagaagtcgatcacgctggtcggcagcggccagtccgccgccgagatctaccaggacctgctgagcgagatcgacgtccacggctacgggctgaactgggtgacccgctccccgcggttcttcccgctcgaatacaccaagctcaccctggagatgacgtccccggagtacgtggactactaccacgcgctgcccgaggacacccgctaccgcctcacggccgagcagaagggcctgttcaagggcatcgacggcgacctgatcaacgagatcttcgacctgctctaccagaaacggctcggcggccccgtccccacccgcctgctcaccaactcggcgctgaccagcgcccggtatgcggacggcacctacacgctcgggttccgccaggaggagcagggcacggacttcgagatcgagaccgagggcctggtcctcgccaccggctaccggtacaccgagccggagttcctcaagcccgtccgggaccggctgcgctacgactcccgcggcaacttcgacatcggccgcaactacgccgtcgacgtcacgggaggcggcgtgttcctccagaacgcgggggtccacgcgcacagcgtcaccagccccgacctgggcatgggcgcctaccgcaacagctgcatcgtccgggagctgctcggacgcgagtactacccggtcgagcagtcgatcgcgttccaggagttcgccgtatgagccgcttgagcaccaccacccccgtcggggcactgaccctgcgccccgtcgacccgctgacggacgccgtactgctgcacggctggctcacccaccccaagtccgcgttctggatgatgcaggacgcccggctggtggacgtcgagcgggcctacatggagctggccgccgacgagcaccagcaggcccacctcggcctgcacgacggggtcccggccttcctgacggagcgctacgaccccgcccaccgcgaactggtcgggctgtacgagcccgagccgggcgacgtcggcatgcacttcctggtcgcgcccaccgaccggcccgtgcacggcttcacccgcgccgtgatcaccaccgtgatgacggagctgttcgccgacccggcgacccggcgggtcgtcgtcgaaccggacgtcaccaacaccgccgtgcacgccctgaacgcagccgtcggattcgtgcccgagcgcgagatccagaagccggagaagaaggccttgctgagcttctgcacccgcgagcagttcgcgaaggcggtgtccgcatgagcctcgccgacgccgtcgcccacctgacccccgaacgctgggaggaggccaaccgcctcctggtccgcaaggcgctggccgagttcacccacgagcggctgctgacccccgagcgggagccggacgacgggggcgggcagacgtacgtcgtccgcagcgacgacggccagaccgcgtaccgcttcaccgccaccgtccgcgccctggaccactggcaggtggacgccgcctccgtcacccgccaccgcgacggcgcggaactcccgctcgccgcgctggacttcttcatcgagctgaagcagaccctgggcctgagcgacgagatcctcccggtctacctggaggagatctcctccaccctctccggcacctgctacaaactgaccaagccgcagctcagctccgccgagctggcccggagcggagacttccaggccgtcgagacgggcatgaccgagggccacccgtgcttcgtcgccaacaacgggcgcctcggcttcggcatccacgagtacctgtcgtacgcccccgagaccgcgagcccggtccggctggtgtggctggccgcgcaccgctcgcgggcggcgttcacggcgggcgtgggcatcgagtacgagtccttcgtccgggacgagctgggcgcggccaccgtcgaccgcttccacggcgtgctgcgcgggcgcggcctggacccggccgactacctgctcatcccggtccacccctggcagtggtggaacaagctcaccgtcaccttcgccgccgaggtcgcccgcgggcacctggtgtgcctgggcgagggcgacgacgagtacctggcccagcagtccatccgcaccttcttcaacgcctcgcaccccgggaagcactacgtgaagactgccctgtccgtcctcaacatgggcttcatgcgcggtctgtcggcggcgtacatggaggccactccggccatcaacgactggctcgcccggctgatcgagggcgacccggtgctgaaggagacggggctgagcatcatccgggagcgggcggccgtcggctaccggcacctggagtacgagcaggccaccgaccgctactcgccctaccgcaagatgctggcggcgctgtggcgggagagcccggtgccgtccatccgggagggcgagacgctcgccaccatggcctccctggtccaccaggaccacgagggcgcctccttcgcgggcgcgctgatcgagcggtccggactcacgcccaccgagtggctgcggcactacctgcgggcctactacgtcccgctgctgcacagcttctacgcctacgacctggtgtacatgccgcacggcgagaacgtgatcctggtgctggcggacggggtggtgcggcgggcggtctacaaggacatcgccgaggagatcgcggtgatggacccggacgcggtgctgccgccggaggtctcccgcatcgcggtggacgtgccggacgacaagaagctcctgtcgatcttcacggacgtcttcgactgcttcttccgcttcctggccgcgaacctggcggaggaggggatcgtcacggaggacgccttctggcggacggtcgcggaggtcacccgggagtaccaggagtcggtgccggagctggccgacaagttcgagcggtacgacatgttcgcgcccgagttcgccctgtcctgcctcaaccggctccagctgcgcgacaaccggcagatggtggacctggccgacccgtccggcgcgctccagctcgtcggcaccctgaagaaccccctggcaggccggtagccaaccggaagcttgcatgcctgcaggtcgact

SEQ ID NO: 20 - DNA, 11677 bp, synthetic construct
  misc_feature 1..11677: note = Vector Construct
  source 1..11677: mol_type = other DNA
aattaagcttccccaccggaggacccccccatgcgctcgcacctgctcaacgacaccaccgcggagcagtaccgccgttccgtgaccgaaggagtcgagcgggtggccgccaaactcgccaccaccgaccgcccgttcaccggcgtcacggtcgacgccctctccccccgcatcgacgcgatcgacctcgacgagccgctgcacgacaccgccgcggtcctcgacgagctggaggacgtctacctccgcgacgccgtctacttccaccacccccgctacctcgcccacctcaactgcccggtcgtcataccggcgctgctcggtgaagcggtcctgtccgccgtcaactcctccctggacacctgggaccagtcggccggcggcacgctcatcgagcggaagctgatcgactggacctgcgcccgcatcggcctcggcccggcggccgacggcgtgttcacctccggcggcacccagtccaacctccaggcgctgctcctcgcccgcgaggaggcgaaggccgaggacttcgccgacctgcggatcttcgcctccgaggccagccacttcagcgtcaggaagtccgcgaaactgctcggcctcggccccgacgccgtcgtgtcgatcccggtcgaccgcgacaagcggatgcagaccgtcgccctcgcccgcgagctggagcgctgcgcgcgggacggcctggtccccatggccgtcgtcgccaccggcggcaccaccgacttcggctcgatcgacccgctgccggagatcgccgggctgtgcgagcagtacggcgtgtggatgcacgtcgacgcggcctacggctgcgggctgctcgcctccctgaagtaccgggaccgcatcaccggcatcgagcgggccgactcggtcaccgtggactaccacaagtccttcttccagccggtgagttcgtcggccgtgctggtccgggacgcggccaccctgcgccacgccacctaccacgcggagtacctcaacccgcgccgcatggtgcaggaacgtatccccaaccaggtggacaagtccctccagaccacccgccgcttcgacgcgctcaagctgtggatgacgctgcgcgtgatgggcgccgacggcatcggcgtcctcttcgacgaggtgtgcgacctggccgccgagggctggaaactgctcgccgccgacccgcgcttcgacgtcgtggtccagccgtcgctgtccacgctggtcttccgccacatcccggcggacgtcaccgatcccgccgagatcgaccgcgccaacctgtacgcccgcaaggccctgttcgcgtccggcgacgccgtggtcgcgggcaccaaggtcgccggtcgccactacctgaagttcaccctgctcaaccccgagacgaccccggccgacatcgccgccgtcctcgacctgatcgccggccacgccgagcagtacctgggagactcccttgaccgcgcttcctgaagccagcgccccgtacgacttcgtgggcatcggcctcggccccttcaacctcggcctcgcctgcctcaccgagcccgtcgccgagctgaacggcgtcttcctggagtccaagccggacttcgagtggcacgccgggatgttcctggacggcgcccacctccagaccccgttcatgtcggacctggtgacgctcgccgacccgacctcgccgtactccttcctcaactacctgaaggagcagggccggctgtactccttctacatccgggagaacttctacccgctgcgggtcgagtacgacgactactgccgctgggccgcgcgcaagctgagcagcgtccgcttctccaccacggtcaccgaggtcacgtacgacgagcgcgaggagctgtacgccgtcgccaccacgtccggcgacacctaccgcgcccgccgcctcgtcctcggcaccggcaccccgccgcacatcccggacgcctgccggggcctggccggcgacttcctccacaactcccggtacgtgcggcaccgggcggagctggtgaagaagaagtcgatcacgctggtcggcagcggccagtccgccgccgagatctaccaggacctgctgagcgagatcgacgtccacggctacgggctgaactgggtgacccgctccccgcggttcttcccgctcgaatacaccaagctcaccctggagatgacgtccccggagtacgtggactactaccacgcgctgcccgaggacacccgctaccgcctcacggccgagcagaagggcctgttcaagggcatcgacggcgacctgatcaacgagatcttcgacctgctctaccagaaacggctcggcggccccgtccccacccgcctgctcaccaactcggcgctgaccagcgcccggtatgcggacggcacctacacgctcgggttccgccaggaggagcagggcacggacttcgagatcgagaccgagggcctggtcctcgccaccggctaccggtacaccgagccggagttcctcaagcccgtccgggaccggctgcgctacgactcccgcggcaacttcgacatcggccgcaactacgccgtcgacgtcacgggaggcggcgtgttcctccagaacgcgggggtccacgcgcacagcgtcaccagccccgacctgggcatgggcgcctaccgcaacagctgcatcgtccgggagctgctcggacgcgagtactacccggtcgagcagtcgatcgcgttccaggagttcgccgtatgagccgcttgagcaccaccacccccgtcggggcactgaccctgcgccccgtcgacccgctgacggacgccgtactgctgcacggctggctcacccaccccaagtccgcgttctggatgatgcaggacgcccggctggtggacgtcgagcgggcctacatggagctggccgccgacgagcaccagcaggcccacctcggcctgcacgacggggtcccggccttcctgacggagcgctacgaccccgcccaccgcgaactggtcgggctgtacgagcccgagccgggcgacgtcggcatgcacttcctggtcgcgcccaccgaccggcccgtgcacggcttcacccgcgccgtgatcaccaccgtgatgacggagctgttcgccgacccggcgacccggcgggtcgtcgtcgaaccggacgtcaccaacaccgccgtgcacgccctgaacgcagccgtcggattcgtgcccgagcgcgagatccagaagccggagaagaaggccttgctgagcttctgcacccgcgagcagttcgcgaaggcggtgtccgcatgagcctcgccgacgccgtcgcccacctgacccccgaacgctgggaggaggccaaccgcctcctggtccgcaaggcgctggccgagttcacccacgagcggctgctgacccccgagcgggagccggacgacgggggcgggcagacgtacgtcgtccgcagcgacgacggccagaccgcgtaccgcttcaccgccaccgtccgcgccctggaccactggcaggtggacgccgcctccgtcacccgccaccgcgacggcgcggaactcccgctcgccgcgctggacttcttcatcgagctgaagcagaccctgggcctgagcgacgagatcctcccggtctacctggaggagatctcctccaccctctccggcacctgctacaaactgaccaagccgcagctcagctccgccgagctggcccggagcggagacttccaggccgtcgagacgggcatgaccgagggccacccgtgcttcgtcgccaacaacgggcgcctcggcttcggcatccacgagtacctgtcgtacgcccccgagaccgcgagcccggtccggctggtgtggctggccgcgcaccgctcgcgggcggcgttcacggcgggcgtgggcatcgagtacgagtccttcgtccgggacgagctgggcgcggccaccgtcgaccgcttccacggcgtgctgcgcgggcgcggcctggacccggccgactacctgctcatcccggtccacccctggcagtggtggaacaagctcaccgtcaccttcgccgccgaggtcgcccgcgggcacctggtgtgcctgggcgagggcgacgacgagtacctggcccagcagtccatccgcaccttcttcaacgcctcgcaccccgggaagcactacgtgaagactgccctgtccgtcctcaacatgggcttcatgcgcggtctgtcggcggcgtacatggaggccactccggccatcaacgactggctcgcccggctgatcgagggcgacccggtgctgaaggagacggggctgagcatcatccgggagcgggcggccgtcggctaccggcacctggagtacgagcaggccaccgaccgctactcgccctaccgcaagatgctggcggcgctgtggcgggagagcccggtgccgtccatccgggagggcgagacgctcgccaccatggcctccctggtccaccaggaccacgagggcgcctccttcgcgggcgcgctgatcgagcggtccggactcacgcccaccgagtggctgcggcactacctgcgggcctactacgtcccgctgctgcacagcttctacgcctacgacctggtgtacatgccgcacggcgagaacgtgatcctggtgctggcggacggggtggtgcggcgggcggtctacaaggacatcgccgaggagatcgcggtgatggacccggacgcggtgctgccgccggaggtctcccgcatcgcggtggacgtgccggacgacaagaagctcctgtcgatcttcacggacgtcttcgactgcttcttccgcttcctggccgcgaacctggcggaggaggggatcgtcacggaggacgccttctggcggacggtcgcggaggtcacccgggagtaccaggagtcggtgccggagctggccgacaagttcgagcggtacgacatgttcgcgcccgagttcgccctgtcctgcctcaaccggctccagctgcgcgacaaccggcagatggtggacctggccgacccgtccggcgcgctccagctcgtcggcaccctgaagaaccccctggcaggccggtagccaaccggaagcttgcatgcctgcaggtcgactctagaggatccccgggtaccgagctcgaattcagcttggctgttttggcggatgagagaagattttcagcctgatacagattaaatcagaacgcagaagcggtctgataaaacagaatttgcctggcggcagtagcgcggtggtcccacctgaccccatgccgaactcagaagtgaaacgccgtagcgccgatggtagtgtggggtctccccatgcgagagtagggaactgccaggcatcaaataaaacgaaaggctcagtcgaaagactgggcctttcgttttatctgttgtttgtcggtgaacgctctcctgagtaggacaaatccgccgggagcggatttgaacgttgcgaagcaacggcccggagggtggcgggcaggacgcccgccataaactgccaggcatcaaattaagcagaaggccatcctgacggatggcctttttgcgtttctacaaactcttttgtttatttttctaaatacattcaaatatgtatccgctcatgagacaataaccctgataaatgcttcaataatattgaaaaaggaagagtatgagtattcaacatttccgtgtcgcccttattcccttttttgcggcattttgccttcctgtttttgctcacccagaaacgctggtgaaagtaaaagatgctgaagatcagttgggtgcacgagtgggttacatcgaactggatctcaacagcggtaagatccttgagagttttcgccccgaagaacgttttccaatgatgagcacttttgcttcctcgctcactgactcgctgcgctcggtcgttcggctgcggcgagcggtatcagctcactcaaaggcggtaatacggttatccacagaatcaggggataacgcaggaaagaacatgtgagcaaaaggccagcaaaaggccaggaaccgtaaaaaggccgcgttgctggcgtttttccataggctccgcccccctgacgagcatcacaaaaatcgacgctcaagtcagaggtggcgaaacccgacaggactataaagataccaggcgtttccccctggaagctccctcgtgcgctctcctgttccgaccctgccgcttaccggatacctgtccgcctttctcccttcgggaagcgtggcgctttctcaatgctcacgctgtaggtatctcagttcggtgtaggtcgttcgctccaagctgggctgtgtgcacgaaccccccgttcagcccgaccgctgcgccttatccggtaactatcgtcttgagtccaacccggtaagacacgacttatcgccactggcagcagccactggtaacaggattagcagagcgaggtatgtaggcggtgctacagagttcttgaagtggtggcctaactacggctacactagaaggacagtatttggtatctgcgctctgctgaagccagttaccttcggaaaaagagttggtagctcttgatccggcaaacaaaccaccgctggtagcggtggtttttttgtttgcaagcagcagattacgcgcagaaaaaaaggatctcaagaagatcctttgatcttttctacggggtctgacgctcagtggaacgaaaactcacgttaagggattttggtcatgagattatcaaaaaggatcttcacctagatccttttggggtgggcgaagaactccagcatgagatccccgcgctggaggatcatccagccattcggggtcgttcactggttcccctttctgatttctggcatagaagaacccccgtgaactgtgtggttccgggggttgctgatttttgcgagacttctcgcgcaattccctagcttaggtgaaaacaccatgaaacactagggaaacacccatgaaacacccattagggcagtagggcggcttcttcgtctagggcttgcatttgggcggtgatctggtctttagcgtgtgaaagtgtgtcgtaggtggcgtgctcaatgcactcgaacgtcacgtcatttaccgggtcacggtgggcaaagagaactagtgggttagacattgttttcctcgttgtcggtggtggtgagcttttctagccgctcggtaaacgcggcgatcatgaactcttggaggttttcaccgttctgcatgcctgcgcgcttcatgtcctcacgtagtgccaaaggaacgcgtgcggtgaccacgacgggcttagcctttgcctgcgcttctagtgcttcgatggtggcttgtgcctgcgcttgctgcgcctgtagtgcctgttgagcttcttgtagttgctgttctagctgtgccttggttgccatgctttaagactctagtagctttcctgcgatatgtcatgcgcatgcgtagcaaacattgtcctgcaactcattcattatgtgcagtgctcctgttactagtcgtacatactcatatttacctagtctgcatgcagtgcatgcacatgcagtcatgtcgtgctaatgtgtaaaacatgtacatgcagattgctgggggtgcagggggcggagccaccctgtccatgcggggtgtggggcttgccccgccggtacagacagtgagcaccggggcacctagtcgcggataccccccctaggtatcggacacgtaaccctcccatgtcgatgcaaatctttaacattgagtacgggtaagctggcacgcatagccaagctaggcggccaccaaacaccactaaaaattaatagtccctagacaagacaaacccccgtgcgagctaccaactcatatgcacgggggccacataacccgaaggggtttcaattgacaaccatagcactagctaagacaacgggcacaacacccgcacaaactcgcactgcgcaaccccgcacaacatcgggtctaggtaacactgagtaacactgaaatagaagtgaacacctctaaggaaccgcaggtcaatgagggttctaaggtcactcgcgctagggcgtggcgtaggcaaaacgtcatgtacaagatcaccaatagtaaggctctggcggggtgccataggtggcgcagggacgaagctgttgcggtgtcctggtcgtctaacggtgcttcgcagtttgagggtctgcaaaactctcactctcgctgggggtcacctctggctgaattggaagtcatgggcgaacgccgcattgagctggctattgctactaagaatcacttggcggcgggtggcgcgctcatgatgtttgtgggcactgttcgacacaaccgctcacagtcatttgcgcaggttgaagcgggtattaagactgcgtactcttcgatggtgaaaacatctcagtggaagaaagaacgtgcacggtacggggtggagcacacctatagtgactatgaggtcacagactcttgggcgaacggttggcacttgcaccgcaacatgctgttgttcttggatcgtccactgtctgacgatgaactcaaggcgtttgaggattccatgttttcccgctggtctgctggtgtggttaaggccggtatggacgcgccactgcgtgagcacggggtcaaacttgatcaggtgtctacctggggtggagacgctgcgaaaatggcaacctacctcgctaagggcatgtctcaggaactgactggctccgctactaaaaccgcgtctaaggggtcgtacacgccgtttcagatgttggatatgttggccgatcaaagcgacgccggcgaggatatggacgctgttttggtggctcggtggcgtgagtatgaggttggttctaaaaacctgcgttcgtcctggtcacgtggggctaagcgtgctttgggcattgattacatagacgctgatgtacgtcgtgaaatggaagaagaactgtacaagctcgccggtctggaagcaccggaacgggtcgaatcaacccgcgttgctgttgctttggtgaagcccgatgattggaaactgattcagtctgatttcgcggttaggcagtacgttctcgattgcgtggataaggctaaggacgtggccgctgcgcaacgtgtcgctaatgaggtgctggcaagtctgggtgtggattccaccccgtgcatgatcgttatggatgatgtggacttggacgcggttctgcctactcatggggacgctactaagcgtgatctgaatgcggcggtgttcgcgggtaatgagcagactattcttcgcacccactaaaagcggcataaaccccgttcgatattttgtgcgatgaatttatggtcaatgtcgcgggggcaaactatgatgggtcttgttgttggcgtcccggaaaacgattccgaagcccaacctttcatagaaggcggcggtggaatcgaaatctcgtgatggcaggttgggcgtcgcttggtcggtcatttcgaagggcaccaataactgccttaaaaaaattacgccccgccctgccactcatcgcagtactgttgtaattcattaagcattctgccgacatggaagccatcacagacggcatgatgaacctgaatcgccagcggcatcagcaccttgtcgccttgcgtataatatttgcccatggtgaaaacgggggcgaagaagttgtccatattggccacgtttaaatcaaaactggtgaaactcacccagggattggctgagacgaaaaacatattctcaataaaccctttagggaaataggccaggttttcaccgtaacacgccacatcttgcgaatatatgtgtagaaactgccggaaatcgtcgtggtattcactccagagcgatgaaaacgtttcagtttgctcatggaaaacggtgtaacaagggtgaacactatcccatatcaccagctcaccgtctttcattgccatacggaactccggatgagcattcatcaggcgggcaagaatgtgaataaaggccggataaaacttgtgcttatttttctttacggtctttaaaaaggccgtaatatccagctgaacggtctggttataggtacattgagcaactgactgaaatgcctcaaaatgttctttacgatgccattgggatatatcaacggtggtatatccagtgatttttttctccattttagcttccttagctcctgaaaatctcgtcgaagctcggcggatttgtcctactcaagctgatccgacaaaatccacacattatcccaggtgtccggatcggtcaaatacgctgccagctcatagaccgtatccaaagcatccggggctgatccccggcgccagggtggtttttcttttcaccagtgagacgggcaacagctgattgcccttcaccgcctggccctgagagagttgcagcaagcggtccacgtggtttgccccagcaggcgaaaatcctgtttgatggtggttaacggcgggatataacatgagctgtcttcggtatcgtcgtatcccactaccgagatatccgcaccaacgcgcagcccggactcggtaatggcgcgcattgcgcccagcgccatctgatcgttggcaaccagcatcgcagtgggaacgatgccctcattcagcatttgcatggtttgttgaaaaccggacatggcactccagtcgccttcccgttccgctatcggctgaatttgattgcgagtgagatatttatgccagccagccagacgcagacgcgccgagacagaacttaatgggcccgctaacagcgcgatttgctggtgacccaatgcgaccagatgctccacgcccagtcgcgtaccgtcttcatgggagaaaataatactgttgatgggtgtctggtcagagacatcaagaaataacgccggaacattagtgcaggcagcttccacagcaatggcatcctggtcatccagcggatagttaatgatcagcccactgacgcgttgcgcgagaagattgtgcaccgccgctttacaggcttcgacgccgcttcgttctaccatcgacaccaccacgctggcacccagttgatcggcgcgagatttaatcgccgcgacaatttgcgacggcgcgtgcagggccagactggaggtggcaacgccaatcagcaacgactgtttgcccgccagttgttgtgccacgcggttgggaatgtaattcagctccgccatcgccgcttccactttttcccgcgttttcgcagaaacgtggctggcctggttcaccacgcgggaaacggtctgataagagacaccggcatactctgcgacatcgtataacgttactggtttcacattcaccaccctgaattgactctcttccgggcgctatcatgccataccgcgaaaggttttgcaccattcgatggtgtcaacgtaaatgccgcttcgccttcgcgcgcgaattgcaagctgatccgggcttatcgactgcacggtgcaccaatgcttctggcgtcaggcagccatcggaagctgtggtatggctgtgcaggtcgtaaatcactgcataattcgtgtcgctcaaggcgcactcccgttctggataatgttttttgcgccgacatcataacggttctggcaaatattctgaaatgagctgttgacaattaatcatcggctcgtataatgtgtggaattgtgagcggataacaatttcacacaggaaacagaatt

SEQ ID NO: 21 - DNA, 1443 bp, Streptomyces pilosus
  source 1..1443: mol_type = genomic DNA
atgcgctcgcacctgctcaacgacaccaccgcggagcactaccgccgctccgtgaccgagggagtcgagcgggtggcggccaaactcgccaccacagcccggccgttcaccggcgtcacggtcgacgccctcgcgccccgcatcgacgcgatcgacctcgaccggcccctgcacgacaccaccgcggtactggacgaactggaggacgtctacctccgggacgcgatctacttccaccacccgcgctacctcgcccacctcaactgcccggtcgtcatcccggccctgctcggcgaggcggtgctctccgccgtcaactcctccctggacacctgggaccagtcggcgggcggcaccctcatcgagcgcaagctcatcgactggacgaccgcccgcatcggcctcggccccgccgccgacggcgtgttcacctccggcggcacccagtccaacctccaggcgctgctgctcgcccgcgaggaggccaagaccggtgacctggcgaaactgcgcgtcttcgcctccgaggtcagccacttcagcgtgaagaagtccgcgaaactgctcggcctcgggcccgacgccgtgatctcgatcccagtcgaccacgacaagcggctgcagaccgtcgccctcgcccgcgagctggagcggtgcgtcgaggcgggcctcgtccccatggccgtcgtcgccaccgccggcaccaccgacttcggctccatcgacccgctgcccgggatcgccgaactgtgcgggcggtacggcgcctggatgcacgtcgacgccgcctacggctgcggtctgctcgcctcactgaagtaccgcgaccgcatcgccggcatcgagcacgccgactccgtcaccgtcgactaccacaagtccttcttccagcccgtcagttcgtcggccgtactggtccgcgacaccgccacgctgcggcacgccacctaccacgccgagtacctcaacccgcgccgcatggtgatcgagcgcatccccaaccaggtcgacaagtccctgcagaccacccgccgcttcgacgccctgaaactgtggatgacgctgcgcgtgatgggtgccgacggcatcggcggcctcttcgacgaggtgtgcgacctggccgcggagggctggaagctgctcgccgccgacccgcgcttcgacgtcgtggtcgcgcccagcctctccaccctcgtcttccgctacatcccggcggccgtcaccgaccccgccgagatcgaccgcgccaacctctacgcccgcaaggccctcttcgcctccggcgacgcggtcgtcgccggcaccaaggtggccgggcgccactacctgaagttcaccctgctgaaccccgagaccacgacggacgacatctccgccgtcctcgatctgatcgccggccacgccgagcagtacctgggagagtcccttgaccgcgcttgctga

SEQ ID NO: 22 - DNA, 1293 bp, Streptomyces pilosus
  source 1..1293: mol_type = genomic DNA
ttgaccgcgcttgctgaagccccggaaaccacctacgacttcgtgggcgtcgggctgggccccttcaacctcggcctcgcctgcctcaccgagccgatatccgaactgaacggcgtcttcctggagtccaagccggacttcgcctggcacgccgggatgttcctcgacggcgcccacctccagacccccttcatgtcggacctggtcaccctcgccgaccccacctccccctactccttcctcaactacctgaaggagaagggccggctgtactcgttctacatacgcgagaacttctacccgctgcgggtcgagtacgacgactactgccgctgggccgccgccaagctgagcagcatccgcttcggcacgacggtcaccgaggtgacctacgacgaggccgccgagctgtacgcggtcgcgacggcggccggtgagacgtaccgcgcccggcacctggtgctcggcaccggcaccgtgccgttcctcccggagccgtgccgcgggctggacggcggcctcttccacaacgcgcagtacatgcagcgcaaggcggaactgctggagaagaagtcggtcacggtcgtcggcagcggtcagagcgccgccgagatctactacgagctgctctccgagatcgacgtccacggctaccagctcaactgggtcacgcgttcgccgcggttcttcccgctggagtacaccaagctgaccctggagatgacctccccggactacatcgactacttccgcgccctgcccgaggagacccgctaccggctggagaagcagcagaagggcctgttcaagggcatcaactcggagctgatcgacgccatcttcgacctgctctaccagaagaacgtcgagagcggggaccgtccggtacccacccggctgctcaccaactccagcctcaccggcgcgcggtaccaggacggcgcgtacacgctcggcttccaccaggacgagcagggcaaggacttcgagatccgcaccgagggcctggtgctggccaccggctaccactacgagccgccggcgttcctcgacccggtgcgcgagcggatccgcttcgacggccacggccgtttcgacgtcgcccgcaactacgccatcgacgtcaccggccgggggatcttcctgcagaacgcgggcgtccacacgcacagcatcaccagccccgacctgggcatgggcccgtaccgcaacgcgtccatcatccgtgagctgctgggcaccgagtactacccggtcgagaagagcatcgcgttccaggagttcgccgtatga

SEQ ID NO: 23 - DNA, 540 bp, Streptomyces pilosus
  source 1..540: mol_type = genomic DNA
atgagcatcggtacgttcaccgtccgccccctggacccgctcgaggacgccgagctgctgcaccgctgggtcaccgaccccaaggcggcgttctggatgatgcaggacgccgcgctccaggacgtcgagcgcgagtacctgcgcatcgccgcccacgagcaccaccacgcctacctgggcctgcacgacggcgaacccgccttcctgatggagaagtacgacccccggtacgtcgaactcgtcggcctgtacgaccccgagcccggcgacgtcggcatgcacttcctggtcgcccccaccgaccgccccgtccacggcttcacccgggcggtcatcaccgccgtgatggaggagctgttcgccgaccccgccacccggcgggtggtggtcgaaccggacgtcggcaacaaggccgtgcacgccctcaacgaggccgtgggcttcgtgcccgagcgggagatcgacaagccggagaagcgcgcgctgctgagcttctgcacgcgtgaacagttcgaggccgcccgaggagcatccgcatga

SEQ ID NO: 24 - DNA, 1773 bp, Streptomyces pilosus
  source 1..1773: mol_type = genomic DNA
atgaccctgtccgacgccgtggcgcacctgtccccccaccgctgggcgcgggccaaccgcctgctgatccgcaaggcgctcgccgagttcgcccacgagcggctcatcacgccgcaggactccggcgacggccggtacgccgtccacagcgacgacggccggacccggtacacgttcaccgctgcgcggcgcgccctggaccactggcacatcgaccccgagtcgatcacccgccaccgcgacgacgccgaacgcgagctcgcggccctggacttcttcatcgagctgcagaagtccctgggcctgagcgaggagattctgccggtgtacctggaggagatctcctccaccctctccggcacctgctacaagctcaccaagccgcaggtgcgggccggagagctgatcgacgccggcttccaggccgtcgagaccggcatgaccgaggggcacccctgcttcgtcgccaacaacgggcggctcggcttcggcgtcgacgagtaccgcgcgtacgcgccggaggcggcggccccggtcaagctggtgtggctggccgcccaccgctcgcgggccgcgttcacggcgggcgtgggcatcgagtacgagtcgttcgtacggcaggaactgggcgaggagaccgtcgagggcttccacgacgtcctgcgcgcgcaggacctcgaccccggcgactacctcctgatacccgtccacccctggcagtggtggaacaagctgtccgtcaccttcgccgccgagatcgcccgccggcacctggtgtgcctgggcgagggcgacgacgagtacctggcccagcagtccatccgcaccttcttcaaccggtcgcaccccgggaagcactacgtgaagacggccctgtccgtcctcaacatgggcttcatgcgcgggctctccgccgcctacatggaggcgaccccggcgatcaacgactggctggcgcagctcgtcgacagcgacccggtgctgcgcgcgaccgggctgtcgatcatccgggagcgggccgccgtgggctaccggcacctggagtacgagcaggccacggaccgctactcgccgtaccgcaagatgctggccgcgctgtggcgggagagcccggtgccgtccctggaggacggcgagtccctcgccaccatggcctcgctggtccatgtcgaccacgagggcgcctccgtggcggccgcgctgatcgcacgctccgggctggcccccaccgagtggctgcgccactacctgcgcgcctactacgtgccgctgctgcacagcttctacgcctacgacctggcctacatgccgcacggcgagaacgtgatcctcgtgctgcgggacggcgtggtgcggcgcgcgatctacaaggacatcgccgaggagatcgtggtgatggacgccgacgcggtgctgccgccggaggtggcccgcatccgggcggaggtgccggacgacacgaagctgctgtcgatcttcacggacgtcttcgactgcttcttccgcttcctcgccgcgaacctggccgaggagggcgtcctggacgaggacggcttctggcgcacggtcgcggaggtcacccgcgagtaccaggcgtcggtgccggaactcgccgacaagttcgcccggtacgacatgttcgccccggagttcgccctgtcctgcctgaaccgcctgcagttgcgcaacaaccggcagatggtcgacctgtcggacccctccggcgcgctccagctggtcggcaccctgaagaaccccctcgcggagttctga

SEQ ID NO: 25 - protein, 480 aa, Streptomyces pilosus
MRSHLLNDTTAEHYRRSVTEGVERVAAKLATTARPFTGVTVDALAPRIDAIDLDRPLHDTTAVLDELEDVYLRDAIYFHHPRYLAHLNCPVVIPALLGEAVLSAVNSSLDTWDQSAGGTLIERKLIDWTTARIGLGPAADGVFTSGGTQSNLQALLLAREEAKTGDLAKLRVFASEVSHFSVKKSAKLLGLGPDAVISIPVDHDKRLQTVALARELERCVEAGLVPMAVVATAGTTDFGSIDPLPGIAELCGRYGAWMHVDAAYGCGLLASLKYRDRIAGIEHADSVTVDYHKSFFQPVSSSAVLVRDTATLRHATYHAEYLNPRRMVIERIPNQVDKSLQTTRRFDALKLWMTLRVMGADGIGGLFDEVCDLAAEGWKLLAADPRFDVVVAPSLSTLVFRYIPAAVTDPAEIDRANLYARKALFASGDAVVAGTKVAGRHYLKFTLLNPETTTDDISAVLDLIAGHAEQYLGESLDRAC

SEQ ID NO: 26 - protein, 430 aa, Streptomyces pilosus
LTALAEAPETTYDFVGVGLGPFNLGLACLTEPISELNGVFLESKPDFAWHAGMFLDGAHLQTPFMSDLVTLADPTSPYSFLNYLKEKGRLYSFYIRENFYPLRVEYDDYCRWAAAKLSSIRFGTTVTEVTYDEAAELYAVATAAGETYRARHLVLGTGTVPFLPEPCRGLDGGLFHNAQYMQRKAELLEKKSVTVVGSGQSAAEIYYELLSEIDVHGYQLNWVTRSPRFFPLEYTKLTLEMTSPDYIDYFRALPEETRYRLEKQQKGLFKGINSELIDAIFDLLYQKNVESGDRPVPTRLLTNSSLTGARYQDGAYTLGFHQDEQGKDFEIRTEGLVLATGYHYEPPAFLDPVRERIRFDGHGRFDVARNYAIDVTGRGIFLQNAGVHTHSITSPDLGMGPYRNASIIRELLGTEYYPVEKSIAFQEFAV

SEQ ID NO: 27 - protein, 179 aa, Streptomyces pilosus
MSIGTFTVRPLDPLEDAELLHRWVTDPKAAFWMMQDAALQDVEREYLRIAAHEHHHAYLGLHDGEPAFLMEKYDPRYVELVGLYDPEPGDVGMHFLVAPTDRPVHGFTRAVITAVMEELFADPATRRVVVEPDVGNKAVHALNEAVGFVPEREIDKPEKRALLSFCTREQFEAARGASA

SEQ ID NO: 28 - protein, 590 aa, Streptomyces pilosus
MTLSDAVAHLSPHRWARANRLLIRKALAEFAHERLITPQDSGDGRYAVHSDDGRTRYTFTAARRALDHWHIDPESITRHRDDAERELAALDFFIELQKSLGLSEEILPVYLEEISSTLSGTCYKLTKPQVRAGELIDAGFQAVETGMTEGHPCFVANNGRLGFGVDEYRAYAPEAAAPVKLVWLAAHRSRAAFTAGVGIEYESFVRQELGEETVEGFHDVLRAQDLDPGDYLLIPVHPWQWWNKLSVTFAAEIARRHLVCLGEGDDEYLAQQSIRTFFNRSHPGKHYVKTALSVLNMGFMRGLSAAYMEATPAINDWLAQLVDSDPVLRATGLSIIRERAAVGYRHLEYEQATDRYSPYRKMLAALWRESPVPSLEDGESLATMASLVHVDHEGASVAAALIARSGLAPTEWLRHYLRAYYVPLLHSFYAYDLAYMPHGENVILVLRDGVVRRAIYKDIAEEIVVMDADAVLPPEVARIRAEVPDDTKLLSIFTDVFDCFFRFLAANLAEEGVLDEDGFWRTVAEVTREYQASVPELADKFARYDMFAPEFALSCLNRLQLRNNRQMVDLSDPSGALQLVGTLKNPLAEF

SEQ ID NO: 29 - DNA, 5102 bp, synthetic construct
  misc_feature 1..5102: note = Vector Construct
  source 1..5102: mol_type = other DNA
acaggaaacagaattaattaagctttgcaggaaggagatatagatatgcgctcgcacctgctcaacgacaccaccgcggagcactaccgccgctccgtgaccgagggagtcgagcgggtggcggccaaactcgccaccacagcccggccgttcaccggcgtcacggtcgacgccctcgcgccccgcatcgacgcgatcgacctcgaccggcccctgcacgacaccaccgcggtactggacgaactggaggacgtctacctccgggacgcgatctacttccaccacccgcgctacctcgcccacctcaactgcccggtcgtcatcccggccctgctcggcgaggcggtgctctccgccgtcaactcctccctggacacctgggaccagtcggcgggcggcaccctcatcgagcgcaagctcatcgactggacgaccgcccgcatcggcctcggccccgccgccgacggcgtgttcacctccggcggcacccagtccaacctccaggcgctgctgctcgcccgcgaggaggccaagaccggtgacctggcgaaactgcgcgtcttcgcctccgaggtcagccacttcagcgtgaagaagtccgcgaaactgctcggcctcgggcccgacgccgtgatctcgatcccagtcgaccacgacaagcggctgcagaccgtcgccctcgcccgcgagctggagcggtgcgtcgaggcgggcctcgtccccatggccgtcgtcgccaccgccggcaccaccgacttcggctccatcgacccgctgcccgggatcgccgaactgtgcgggcggtacggcgcctggatgcacgtcgacgccgcctacggctgcggtctgctcgcctcactgaagtaccgcgaccgcatcgccggcatcgagcacgccgactccgtcaccgtcgactaccacaagtccttcttccagcccgtcagttcgtcggccgtactggtccgcgacaccgccacgctgcggcacgccacctaccacgccgagtacctcaacccgcgccgcatggtgatcgagcgcatccccaaccaggtcgacaagtccctgcagaccacccgccgcttcgacgccctgaaactgtggatgacgctgcgcgtgatgggtgccgacggcatcggcggcctcttcgacgaggtgtgcgacctggccgcggagggctggaagctgctcgccgccgacccgcgcttcgacgtcgtggtcgcgcccagcctctccaccctcgtcttccgctacatcccggcggccgtcaccgaccccgccgagatcgaccgcgccaacctctacgcccgcaaggccctcttcgcctccggcgacgcggtcgtcgccggcaccaaggtggccgggcgccactacctgaagttcaccctgctgaaccccgagaccacgacggacgacatctccgccgtcctcgatctgatcgccggccacgccgagcagtacctgggagagtcccttgaccgcgcttgctgaagccccggaaaccacctacgacttcgtgggcgtcgggctgggccccttcaacctcggcctcgcctgcctcaccgagccgatatccgaactgaacggcgtcttcctggagtccaagccggacttcgcctggcacgccgggatgttcctcgacggcgcccacctccagacccccttcatgtcggacctggtcaccctcgccgaccccacctccccctactccttcctcaactacctgaaggagaagggccggctgtactcgttctacatacgcgagaacttctacccgctgcgggtcgagtacgacgactactgccgctgggccgccgccaagctgagcagcatccgcttcggcacgacggtcaccgaggtgacctacgacgaggccgccgagctgtacgcggtcgcgacggcggccggtgagacgtaccgcgcccggcacctggtgctcggcaccggcaccgtgccgttcctcccggagccgtgccgcgggctggacggcggcctcttccacaacgcgcagtacatgcagcgcaaggcggaactgctggagaagaagtcggtcacggtcgtcggcagcggtcagagcgccgccgagatctactacgagctgctctccgagatcgacgtccacggctaccagctcaactgggtcacgcgttcgccgcggttcttcccgctggagtacaccaagctgaccctggagatgacctccccggactacatcgactacttccgcgccctgcccgaggagacccgctaccggctggagaagcagcagaagggcctgttcaagggcatcaactcggagctgatcgacgccatcttcgacctgctctaccagaagaacgtcgagagcggggaccgtccggtacccacccggctgctcaccaactccagcctcaccggcgcgcggtaccaggacggcgcgtacacgctcggcttccaccaggacgagcagggcaaggacttcgagatccgcaccgagggcctggtgctggccaccggctaccactacgagccgccggcgttcctcgacccggtgcgcgagcggatccgcttcgacggccacggccgtttcgacgtcgcccgcaactacgccatcgacgtcaccggccgggggatcttcctgcagaacgcgggcgtccacacgcacagcatcaccagccccgacctgggcatgggcccgtaccgcaacgcgtccatcatccgtgagctgctgggcaccgagtactacccggtcgagaagagcatcgcgttccaggagttcgccgtatgagcatcggtacgttcaccgtccgccccctggacccgctcgaggacgccgagctgctgcaccgctgggtcaccgaccccaaggcggcgttctggatgatgcaggacgccgcgctccaggacgtcgagcgcgagtacctgcgcatcgccgcccacgagcaccaccacgcctacctgggcctgcacgacggcgaacccgccttcctgatggagaagtacgacccccggtacgtcgaactcgtcggcctgtacgaccccgagcccggcgacgtcggcatgcacttcctggtcgcccccaccgaccgccccgtccacggcttcacccgggcggtcatcaccgccgtgatggaggagctgttcgccgaccccgccacccggcgggtggtggtcgaaccggacgtcggcaacaaggccgtgcacgccctcaacgaggccgtgggcttcgtgcccgagcgggagatcgacaagccggagaagcgcgcgctgctgagcttctgcacgcgtgaacagttcgaggccgcccgaggagcatccgcatgaccctgtccgacgccgtggcgcacctgtccccccaccgctgggcgcgggccaaccgcctgctgatccgcaaggcgctcgccgagttcgcccacgagcggctcatcacgccgcaggactccggcgacggccggtacgccgtccacagcgacgacggccggacccggtacacgttcaccgctgcgcggcgcgccctggaccactggcacatcgaccccgagtcgatcacccgccaccgcgacgacgccgaacgcgagctcgcggccctggacttcttcatcgagctgcagaagtccctgggcctgagcgaggagattctgccggtgtacctggaggagatctcctccaccctctccggcacctgctacaagctcaccaagccgcaggtgcgggccggagagctgatcgacgccggcttccaggccgtcgagaccggcatgaccgaggggcacccctgcttcgtcgccaacaacgggcggctcggcttcggcgtcgacgagtaccgcgcgtacgcgccggaggcggcggccccggtcaagctggtgtggctggccgcccaccgctcgcgggccgcgttcacggcgggcgtgggcatcgagtacgagtcgttcgtacggcaggaactgggcgaggagaccgtcgagggcttccacgacgtcctgcgcgcgcaggacctcgaccccggcgactacctcctgatacccgtccacccctggcagtggtggaacaagctgtccgtcaccttcgccgccgagatcgcccgccggcacctggtgtgcctgggcgagggcgacgacgagtacctggcccagcagtccatccgcaccttcttcaaccggtcgcaccccgggaagcactacgtgaagacggccctgtccgtcctcaacatgggcttcatgcgcgggctctccgccgcctacatggaggcgaccccggcgatcaacgactggctggcgcagctcgtcgacagcgacccggtgctgcgcgcgaccgggctgtcgatcatccgggagcgggccgccgtgggctaccggcacctggagtacgagcaggccacggaccgctactcgccgtaccgcaagatgctggccgcgctgtggcgggagagcccggtgccgtccctggaggacggcgagtccctcgccaccatggcctcgctggtccatgtcgaccacgagggcgcctccgtggcggccgcgctgatcgcacgctccgggctggcccccaccgagtggctgcgccactacctgcgcgcctactacgtgccgctgctgcacagcttctacgcctacgacctggcctacatgccgcacggcgagaacgtgatcctcgtgctgcgggacggcgtggtgcggcgcgcgatctacaaggacatcgccgaggagatcgtggtgatggacgccgacgcggtgctgccgccggaggtggcccgcatccgggcggaggtgccggacgacacgaagctgctgtcgatcttcacggacgtcttcgactgcttcttccgcttcctcgccgcgaacctggccgaggagggcgtcctggacgaggacggcttctggcgcacggtcgcggaggtcacccgcgagtaccaggcgtcggtgccggaactcgccgacaagttcgcccggtacgacatgttcgccccggagttcgccctgtcctgcctgaaccgcctgcagttgcgcaacaaccggcagatggtcgacctgtcggacccctccggcgcgctccagctggtcggcaccctgaagaaccccctcgcggagttctgacccacgaaaagcttgcatgcctgcaggtcgact

SEQ ID NO: 30 - DNA, 11659 bp, synthetic construct
  misc_feature 1..11659: note = Vector Construct
  source 1..11659: mol_type = other DNA
aattaagctttgcaggaaggagatatagatatgcgctcgcacctgctcaacgacaccaccgcggagcactaccgccgctccgtgaccgagggagtcgagcgggtggcggccaaactcgccaccacagcccggccgttcaccggcgtcacggtcgacgccctcgcgccccgcatcgacgcgatcgacctcgaccggcccctgcacgacaccaccgcggtactggacgaactggaggacgtctacctccgggacgcgatctacttccaccacccgcgctacctcgcccacctcaactgcccggtcgtcatcccggccctgctcggcgaggcggtgctctccgccgtcaactcctccctggacacctgggaccagtcggcgggcggcaccctcatcgagcgcaagctcatcgactggacgaccgcccgcatcggcctcggccccgccgccgacggcgtgttcacctccggcggcacccagtccaacctccaggcgctgctgctcgcccgcgaggaggccaagaccggtgacctggcgaaactgcgcgtcttcgcctccgaggtcagccacttcagcgtgaagaagtccgcgaaactgctcggcctcgggcccgacgccgtgatctcgatcccagtcgaccacgacaagcggctgcagaccgtcgccctcgcccgcgagctggagcggtgcgtcgaggcgggcctcgtccccatggccgtcgtcgccaccgccggcaccaccgacttcggctccatcgacccgctgcccgggatcgccgaactgtgcgggcggtacggcgcctggatgcacgtcgacgccgcctacggctgcggtctgctcgcctcactgaagtaccgcgaccgcatcgccggcatcgagcacgccgactccgtcaccgtcgactaccacaagtccttcttccagcccgtcagttcgtcggccgtactggtccgcgacaccgccacgctgcggcacgccacctaccacgccgagtacctcaacccgcgccgcatggtgatcgagcgcatccccaaccaggtcgacaagtccctgcagaccacccgccgcttcgacgccctgaaactgtggatgacgctgcgcgtgatgggtgccgacggcatcggcggcctcttcgacgaggtgtgcgacctggccgcggagggctggaagctgctcgccgccgacccgcgcttcgacgtcgtggtcgcgcccagcctctccaccctcgtcttccgctacatcccggcggccgtcaccgaccccgccgagatcgaccgcgccaacctctacgcccgcaaggccctcttcgcctccggcgacgcggtcgtcgccggcaccaaggtggccgggcgccactacctgaagttcaccctgctgaaccccgagaccacgacggacgacatctccgccgtcctcgatctgatcgccggccacgccgagcagtacctgggagagtcccttgaccgcgcttgctgaagccccggaaaccacctacgacttcgtgggcgtcgggctgggccccttcaacctcggcctcgcctgcctcaccgagccgatatccgaactgaacggcgtcttcctggagtccaagccggacttcgcctggcacgccgggatgttcctcgacggcgcccacctccagacccccttcatgtcggacctggtcaccctcgccgaccccacctccccctactccttcctcaactacctgaaggagaagggccggctgtactcgttctacatacgcgagaacttctacccgctgcgggtcgagtacgacgactactgccgctgggccgccgccaagctgagcagcatccgcttcggcacgacggtcaccgaggtgacctacgacgaggccgccgagctgtacgcggtcgcgacggcggccggtgagacgtaccgcgcccggcacctggtgctcggcaccggcaccgtgccgttcctcccggagccgtgccgcgggctggacggcggcctcttccacaacgcgcagtacatgcagcgcaaggcggaactgctggagaagaagtcggtcacggtcgtcggcagcggtcagagcgccgccgagatctactacgagctgctctccgagatcgacgtccacggctaccagctcaactgggtcacgcgttcgccgcggttcttcccgctggagtacaccaagctgaccctggagatgacctccccggactacatcgactacttccgcgccctgcccgaggagacccgctaccggctggagaagcagcagaagggcctgttcaagggcatcaactcggagctgatcgacgccatcttcgacctgctctaccagaagaacgtcgagagcggggaccgtccggtacccacccggctgctcaccaactccagcctcaccggcgcgcggtaccaggacggcgcgtacacgctcggcttccaccaggacgagcagggcaaggacttcgagatccgcaccgagggcctggtgctggccaccggctaccactacgagccgccggcgttcctcgacccggtgcgcgagcggatccgcttcgacggccacggccgtttcgacgtcgcccgcaactacgccatcgacgtcaccggccgggggatcttcctgcagaacgcgggcgtccacacgcacagcatcaccagccccgacctgggcatgggcccgtaccgcaacgcgtccatcatccgtgagctgctgggcaccgagtactacccggtcgagaagagcatcgcgttccaggagttcgccgtatgagcatcggtacgttcaccgtccgccccctggacccgctcgaggacgccgagctgctgcaccgctgggtcaccgaccccaaggcggcgttctggatgatgcaggacgccgcgctccaggacgtcgagcgcgagtacctgcgcatcgccgcccacgagcaccaccacgcctacctgggcctgcacgacggcgaacccgccttcctgatggagaagtacgacccccggtacgtcgaactcgtcggcctgtacgaccccgagcccggcgacgtcggcatgcacttcctggtcgcccccaccgaccgccccgtccacggcttcacccgggcggtcatcaccgccgtgatggaggagctgttcgccgaccccgccacccggcgggtggtggtcgaaccggacgtcggcaacaaggccgtgcacgccctcaacgaggccgtgggcttcgtgcccgagcgggagatcgacaagccggagaagcgcgcgctgctgagcttctgcacgcgtgaacagttcgaggccgcccgaggagcatccgcatgaccctgtccgacgccgtggcgcacctgtccccccaccgctgggcgcgggccaaccgcctgctgatccgcaaggcgctcgccgagttcgcccacgagcggctcatcacgccgcaggactccggcgacggccggtacgccgtccacagcgacgacggccggacccggtacacgttcaccgctgcgcggcgcgccctggaccactggcacatcgaccccgagtcgatcacccgccaccgcgacgacgccgaacgcgagctcgcggccctggacttcttcatcgagctgcagaagtccctgggcctgagcgaggagattctgccggtgtacctggaggagatctcctccaccctctccggcacctgctacaagctcaccaagccgcaggtgcgggccggagagctgatcgacgccggcttccaggccgtcgagaccggcatgaccgaggggcacccctgcttcgtcgccaacaacgggcggctcggcttcggcgtcgacgagtaccgcgcgtacgcgccggaggcggcggccccggtcaagctggtgtggctggccgcccaccgctcgcgggccgcgttcacggcgggcgtgggcatcgagtacgagtcgttcgtacggcaggaactgggcgaggagaccgtcgagggcttccacgacgtcctgcgcgcgcaggacctcgaccccggcgactacctcctgatacccgtccacccctggcagtggtggaacaagctgtccgtcaccttcgccgccgagatcgcccgccggcacctggtgtgcctgggcgagggcgacgacgagtacctggcccagcagtccatccgcaccttcttcaaccggtcgcaccccgggaagcactacgtgaagacggccctgtccgtcctcaacatgggcttcatgcgcgggctctccgccgcctacatggaggcgaccccggcgatcaacgactggctggcgcagctcgtcgacagcgacccggtgctgcgcgcgaccgggctgtcgatcatccgggagcgggccgccgtgggctaccggcacctggagtacgagcaggccacggaccgctactcgccgtaccgcaagatgctggccgcgctgtggcgggagagcccggtgccgtccctggaggacggcgagtccctcgccaccatggcctcgctggtccatgtcgaccacgagggcgcctccgtggcggccgcgctgatcgcacgctccgggctggcccccaccgagtggctgcgccactacctgcgcgcctactacgtgccgctgctgcacagcttctacgcctacgacctggcctacatgccgcacggcgagaacgtgatcctcgtgctgcgggacggcgtggtgcggcgcgcgatctacaaggacatcgccgaggagatcgtggtgatggacgccgacgcggtgctgccgccggaggtggcccgcatccgggcggaggtgccggacgacacgaagctgctgtcgatcttcacggacgtcttcgactgcttcttccgcttcctcgccgcgaacctggccgaggagggcgtcctggacgaggacggcttctggcgcacggtcgcggaggtcacccgcgagtaccaggcgtcggtgccggaactcgccgacaagttcgcccggtacgacatgttcgccccggagttcgccctgtcctgcctgaaccgcctgcagttgcgcaacaaccggcagatggtcgacctgtcggacccctccggcgcgctccagctggtcggcaccctgaagaaccccctcgcggagttctgacccacgaaaagcttgcatgcctgcaggtcgactctagaggatccccgggtaccgagctcgaattcagcttggctgttttggcggatgagagaagattttcagcctgatacagattaaatcagaacgcagaagcggtctgataaaacagaatttgcctggcggcagtagcgcggtggtcccacctgaccccatgccgaactcagaagtgaaacgccgtagcgccgatggtagtgtggggtctccccatgcgagagtagggaactgccaggcatcaaataaaacgaaaggctcagtcgaaagactgggcctttcgttttatctgttgtttgtcggtgaacgctctcctgagtaggacaaatccgccgggagcggatttgaacgttgcgaagcaacggcccggagggtggcgggcaggacgcccgccataaactgccaggcatcaaattaagcagaaggccatcctgacggatggcctttttgcgtttctacaaactcttttgtttatttttctaaatacattcaaatatgtatccgctcatgagacaataaccctgataaatgcttcaataatattgaaaaaggaagagtatgagtattcaacatttccgtgtcgcccttattcccttttttgcggcattttgccttcctgtttttgctcacccagaaacgctggtgaaagtaaaagatgctgaagatcagttgggtgcacgagtgggttacatcgaactggatctcaacagcggtaagatccttgagagttttcgccccgaagaacgttttccaatgatgagcacttttgcttcctcgctcactgactcgctgcgctcggtcgttcggctgcggcgagcggtatcagctcactcaaaggcggtaatacggttatccacagaatcaggggataacgcaggaaagaacatgtgagcaaaaggccagcaaaaggccaggaaccgtaaaaaggccgcgttgctggcgtttttccataggctccgcccccctgacgagcatcacaaaaatcgacgctcaagtcagaggtggcgaaacccgacaggactataaagataccaggcgtttccccctggaagctccctcgtgcgctctcctgttccgaccctgccgcttaccggatacctgtccgcctttctcccttcgggaagcgtggcgctttctcaatgctcacgctgtaggtatctcagttcggtgtaggtcgttcgctccaagctgggctgtgtgcacgaaccccccgttcagcccgaccgctgcgccttatccggtaactatcgtcttgagtccaacccggtaagacacgacttatcgccactggcagcagccactggtaacaggattagcagagcgaggtatgtaggcggtgctacagagttcttgaagtggtggcctaactacggctacactagaaggacagtatttggtatctgcgctctgctgaagccagttaccttcggaaaaagagttggtagctcttgatccggcaaacaaaccaccgctggtagcggtggtttttttgtttgcaagcagcagattacgcgcagaaaaaaaggatctcaagaagatcctttgatcttttctacggggtctgacgctcagtggaacgaaaactcacgttaagggattttggtcatgagattatcaaaaaggatcttcacctagatccttttggggtgggcgaagaactccagcatgagatccccgcgctggaggatcatccagccattcggggtcgttcactggttcccctttctgatttctggcatagaagaacccccgtgaactgtgtggttccgggggttgctgatttttgcgagacttctcgcgcaattccctagcttaggtgaaaacaccatgaaacactagggaaacacccatgaaacacccattagggcagtagggcggcttcttcgtctagggcttgcatttgggcggtgatctggtctttagcgtgtgaaagtgtgtcgtaggtggcgtgctcaatgcactcgaacgtcacgtcatttaccgggtcacggtgggcaaagagaactagtgggttagacattgttttcctcgttgtcggtggtggtgagcttttctagccgctcggtaaacgcggcgatcatgaactcttggaggttttcaccgttctgcatgcctgcgcgcttcatgtcctcacgtagtgccaaaggaacgcgtgcggtgaccacgacgggcttagcctttgcctgcgcttctagtgcttcgatggtggcttgtgcctgcgcttgctgcgcctgtagtgcctgttgagcttcttgtagttgctgttctagctgtgccttggttgccatgctttaagactctagtagctttcctgcgatatgtcatgcgcatgcgtagcaaacattgtcctgcaactcattcattatgtgcagtgctcctgttactagtcgtacatactcatatttacctagtctgcatgcagtgcatgcacatgcagtcatgtcgtgctaatgtgtaaaacatgtacatgcagattgctgggggtgcagggggcggagccaccctgtccatgcggggtgtggggcttgccccgccggtacagacagtgagcaccggggcacctagtcgcggataccccccctaggtatcggacacgtaaccctcccatgtcgatgcaaatctttaacattgagtacgggtaagctggcacgcatagccaagctaggcggccaccaaacaccactaaaaattaatagtccctagacaagacaaacccccgtgcgagctaccaactcatatgcacgggggccacataacccgaaggggtttcaattgacaaccatagcactagctaagacaacgggcacaacacccgcacaaactcgcactgcgcaaccccgcacaacatcgggtctaggtaacactgagtaacactgaaatagaagtgaacacctctaaggaaccgcaggtcaatgagggttctaaggtcactcgcgctagggcgtggcgtaggcaaaacgtcatgtacaagatcaccaatagtaaggctctggcggggtgccataggtggcgcagggacgaagctgttgcggtgtcctggtcgtctaacggtgcttcgcagtttgagggtctgcaaaactctcactctcgctgggggtcacctctggctgaattggaagtcatgggcgaacgccgcattgagctggctattgctactaagaatcacttggcggcgggtggcgcgctcatgatgtttgtgggcactgttcgacacaaccgctcacagtcatttgcgcaggttgaagcgggtattaagactgcgtactcttcgatggtgaaaacatctcagtggaagaaagaacgtgcacggtacggggtggagcacacctatagtgactatgaggtcacagactcttgggcgaacggttggcacttgcaccgcaacatgctgttgttcttggatcgtccactgtctgacgatgaactcaaggcgtttgaggattccatgttttcccgctggtctgctggtgtggttaaggccggtatggacgcgccactgcgtgagcacggggtcaaacttgatcaggtgtctacctggggtggagacgctgcgaaaatggcaacctacctcgctaagggcatgtctcaggaactgactggctccgctactaaaaccgcgtctaaggggtcgtacacgccgtttcagatgttggatatgttggccgatcaaagcgacgccggcgaggatatggacgctgttttggtggctcggtggcgtgagtatgaggttggttctaaaaacctgcgttcgtcctggtcacgtggggctaagcgtgctttgggcattgattacatagacgctgatgtacgtcgtgaaatggaagaagaactgtacaagctcgccggtctggaagcaccggaacgggtcgaatcaacccgcgttgctgttgctttggtgaagcccgatgattggaaactgattcagtctgatttcgcggttaggcagtacgttctcgattgcgtggataaggctaaggacgtggccgctgcgcaacgtgtcgctaatgaggtgctggcaagtctgggtgtggattccaccccgtgcatgatcgttatggatgatgtggacttggacgcggttctgcctactcatggggacgctactaagcgtgatctgaatgcggcggtgttcgcgggtaatgagcagactattcttcgcacccactaaaagcggcataaaccccgttcgatattttgtgcgatgaatttatggtcaatgtcgcgggggcaaactatgatgggtcttgttgttggcgtcccggaaaacgattccgaagcccaacctttcatagaaggcggcggtggaatcgaaatctcgtgatggcaggttgggcgtcgcttggtcggtcatttcgaagggcaccaataactgccttaaaaaaattacgccccgccctgccactcatcgcagtactgttgtaattcattaagcattctgccgacatggaagccatcacagacggcatgatgaacctgaatcgccagcggcatcagcaccttgtcgccttgcgtataatatttgcccatggtgaaaacgggggcgaagaagttgtccatattggccacgtttaaatcaaaactggtgaaactcacccagggattggctgagacgaaaaacatattctcaataaaccctttagggaaataggccaggttttcaccgtaacacgccacatcttgcgaatatatgtgtagaaactgccggaaatcgtcgtggtattcactccagagcgatgaaaacgtttcagtttgctcatggaaaacggtgtaacaagggtgaacactatcccatatcaccagctcaccgtctttcattgccatacggaactccggatgagcattcatcaggcgggcaagaatgtgaataaaggccggataaaacttgtgcttatttttctttacggtctttaaaaaggccgtaatatccagctgaacggtctggttataggtacattgagcaactgactgaaatgcctcaaaatgttctttacgatgccattgggatatatcaacggtggtatatccagtgatttttttctccattttagcttccttagctcctgaaaatctcgtcgaagctcggcggatttgtcctactcaagctgatccgacaaaatccacacattatcccaggtgtccggatcggtcaaatacgctgccagctcatagaccgtatccaaagcatccggggctgatccccggcgccagggtggtttttcttttcaccagtgagacgggcaacagctgattgcccttcaccgcctggccctgagagagttgcagcaagcggtccacgtggtttgccccagcaggcgaaaatcctgtttgatggtggttaacggcgggatataacatgagctgtcttcggtatcgtcgtatcccactaccgagatatccgcaccaacgcgcagcccggactcggtaatggcgcgcattgcgcccagcgccatctgatcgttggcaaccagcatcgcagtgggaacgatgccctcattcagcatttgcatggtttgttgaaaaccggacatggcactccagtcgccttcccgttccgctatcggctgaatttgattgcgagtgagatatttatgccagccagccagacgcagacgcgccgagacagaacttaatgggcccgctaacagcgcgatttgctggtgacccaatgcgaccagatgctccacgcccagtcgcgtaccgtcttcatgggagaaaataatactgttgatgggtgtctggtcagagacatcaagaaataacgccggaacattagtgcaggcagcttccacagcaatggcatcctggtcatccagcggatagttaatgatcagcccactgacgcgttgcgcgagaagattgtgcaccgccgctttacaggcttcgacgccgcttcgttctaccatcgacaccaccacgctggcacccagttgatcggcgcgagatttaatcgccgcgacaatttgcgacggcgcgtgcagggccagactggaggtggcaacgccaatcagcaacgactgtttgcccgccagttgttgtgccacgcggttgggaatgtaattcagctccgccatcgccgcttccactttttcccgcgttttcgcagaaacgtggctggcctggttcaccacgcgggaaacggtctgataagagacaccggcatactctgcgacatcgtataacgttactggtttcacattcaccaccctgaattgactctcttccgggcgctatcatgccataccgcgaaaggttttgcaccattcgatggtgtcaacgtaaatgccgcttcgccttcgcgcgcgaattgcaagctgatccgggcttatcgactgcacggtgcaccaatgcttctggcgtcaggcagccatcggaagctgtggtatggctgtgcaggtcgtaaatcactgcataattcgtgtcgctcaaggcgcactcccgttctggataatgttttttgcgccgacatcataacggttctggcaaatattctgaaatgagctgttgacaattaatcatcggctcgtataatgtgtggaattgtgagcggataacaatttcacacaggaaacagaatt

SEQ ID NO: 31 - DNA, 1293 bp, Erwinia amylovora
  source 1..1293: mol_type = genomic DNA
atgaataacaccatctatgattttattggtattggcattggaccattcaatctgggccttgcctgtctgagcgaaccggttgaagggttgaacggcgtttttctcgatcagaaccccggctttgactggcataccggcatgatgctggaaagcgcccatttgcaaacgccttttatggccgatctggtgacgctggccgatccgaccagcccttacagcctgctcaattttatgaagcagaagggaaaactttactctttttacatccgcgaagattttttcctgatgagaaaagagtacaaccagtattgccaatgggccgctgaacggctcggcaacctgcgctggaacacccgggttgaatacgtcagctacgatgacaatctgcaatgctatcgtgtccgttcgacagataccgtcagcggtaaacagcaggaatggctggcgcatcgtctggtactgggcaccggccccagcgcctggagtcccgcctgcagccaaccgtatcgcgagcgcttcgtccactccagcgaatatctgctcaacaaagaaaaattgcagaaaaaacgctccatcaccgtactgggcagcggccagagcgcggccgaaatctattacgatctgctgacggatatcgatcgtttcggctatcagctgaactggataactcgcgcgccgcgcttctacccgcttgagtacacgaaactgacgctggaaatgacctcgccagaatggattgactattttcacagtctgccggcggcgaaacgcgacgagcttaacgccagccagaaaaatctctataaaggcatcaacagcagcctgattaatgcgatttacgacctgttgtacgttaagcagctggacggaaagctcgacgtcaatctctttacccattcggagctgaccgacatgcgctggctggcggaaggtgagtttgagctcaagctgcatcagcaggaacaggatcgtgcctacagccgccgtactgagggattagtgatggccacgggctatcactatcaaccaccggcgtttgttgaaggcatccagcagcggatccaatgggatgagaaagaccgttatgacgtacaacgtaattacagcatcgatcgccataaccaggtcttcgtgcaaaatgccgagctgcatacgcacggctttgtcacgcctgatttaggcatggcctgctaccgcaattccgtgttactgcgcgaaatcaccggccgggaagtctaccccgtcgaacgccagatcgctttccagactttccccgcacaatcggaaatgtga

SEQ ID NO: 32 - DNA, 2355 bp, Erwinia amylovora
  source 1..2355: mol_type = genomic DNA
atgccaaattccactctttacagtacgggccgtcccgcgggccggttcaccctccgcccaatgcgccatgaagacgccgcaatggtccaccgttgggtcacacaagagtatgcccgcttctgggggatgcaggacaacagcatcgaacaggttgcggccttttatcaccagctgacggctcataacccgcacgccgcgctgatcggttgctgcaacgaccagccggtgttcctgatggagttctacaaggccagtgaggatgacatcggcaagttctatgccgcgcagccgggcgattacggtatgcatctgctgatagcgcctgccactcacccggtgcagcagttcagctggcaggttttctcgacggtaatcgactttatgttcagcctgccggaggttaagcgggtagtggtggagccggacgagcgtaatacaaaaattcatcgactgaacaagcgcgcgggcttttgctaccagcacaccatcgatatgggccataaaaccgcctggctggccttctgccagcgcgaaaattatcaacaggctttactgaaggaatcgctgaatatgaatgatacccatctgctgcaagccggcacctggctgaccggagataactgggctgaggccaaccgtctgctgatccgcaaagctatcgccgagttcgctcatgagaaaatcgtaacgcctgctgaatgcgctcacggccgctactctctggccgtgccgggcagcgaaacagaataccagtttaccgccagccgcctcgcgctggatcactgggagatagacgccgcttcgctgactaaacaggaaaacggtcatcccctggcgctggacgccttacaatttattacggaattcaatgaggtaatcggtattccacaggctctgctggcaacctatatggaagagatcagcagcacgttgtgcagcagcgttttcaaactgcagaagaataacccggacagccgggcactggtcaacgcagactttcagaccgttgaatcctcaatgaccgaagggcacccgtgcttcgtggcgaacaacgggcgcattggctttgatgcgcgtgactatctggcttacgcgcctgaagctgccacgccggttaatcttatctgggttgccgtgcaccggcgcaacgcccacttctccagcctgagtgacctgcaatacgagcgcctgatgcgtgaagaactggggcagtcaacggttgaacagtttaatgcacagctgacggagaaaggacttacccacgctgattacctctttatgccggttcacccctggcagtggcagaacaagctgctgacggtatttgcggcagatatcgccaataacgatattgtctggcttggcgtcggcgacgatcaatatcaggcgcagcagtctattcggacctttttcaaccgcagccatcctaacaagcgctatgtcaaaacagcactgtcagtgctgaatatgggctttatgcgcggtctttctccctattatatggcgaccacgccggcgattaatgaatggctgcaagatctggtggccggggatgaatggctacagcgctgtgatttccgcattctgcgcgaagtggcggcagtgggttaccataaccgccactatgaaaaagccatcaagggtgattccgcctacaagaaaatgtttgccgcgctgtggcgtgataatccggttgccgagctcaaacccggccagcgcctgatgaccatggcctcattcctgcacgttgatcatcaccagaaagccctgctgccagcgctgatcgccgattccgggctggccgctgaacgctgggtggaacgctatctgagctgctacctcagtccgctgctgcactgcttctaccagcacgatctggtgtttatgccgcacggcgaaaacctgatcctgctgctggagaataacgtcccggtcagcgcctatatgaaagacatcggcgaagaaattgcggtgatgaacccggatgccgtgctgccggaaaaagtacagcgcctggcggtggacgtgccggaaaacctcaagctgctgtcggtctttaccgacgtgttcgactgcattttccgctttatcagcgctattcttcaccagtccgccactctgccggaagaacaattctggcaggcggtcgcgcgctgcgtgaaggagtaccagcaggcccatccgcatctggccagcaagttttcccgttacgatatgttcgcgccggaattcacccgctcctgcctcaaccgactacagctggccaataaccagcaaatgatcaatctgtcagacccggctgaaaatctgaaatttgccggtacgctggtcaacccgatcgcccgctggcgttaa

SEQ ID NO: 33 - protein, 430 aa, Erwinia amylovora
MNNTIYDFIGIGIGPFNLGLACLSEPVEGLNGVFLDQNPGFDWHTGMMLESAHLQTPFMADLVTLADPTSPYSLLNFMKQKGKLYSFYIREDFFLMRKEYNQYCQWAAERLGNLRWNTRVEYVSYDDNLQCYRVRSTDTVSGKQQEWLAHRLVLGTGPSAWSPACSQPYRERFVHSSEYLLNKEKLQKKRSITVLGSGQSAAEIYYDLLTDIDRFGYQLNWITRAPRFYPLEYTKLTLEMTSPEWIDYFHSLPAAKRDELNASQKNLYKGINSSLINAIYDLLYVKQLDGKLDVNLFTHSELTDMRWLAEGEFELKLHQQEQDRAYSRRTEGLVMATGYHYQPPAFVEGIQQRIQWDEKDRYDVQRNYSIDRHNQVFVQNAELHTHGFVTPDLGMACYRNSVLLREITGREVYPVERQIAFQTFPAQSEM

SEQ ID NO: 34 - protein, 784 aa, Erwinia amylovora
MPNSTLYSTGRPAGRFTLRPMRHEDAAMVHRWVTQEYARFWGMQDNSIEQVAAFYHQLTAHNPHAALIGCCNDQPVFLMEFYKASEDDIGKFYAAQPGDYGMHLLIAPATHPVQQFSWQVFSTVIDFMFSLPEVKRVVVEPDERNTKIHRLNKRAGFCYQHTIDMGHKTAWLAFCQRENYQQALLKESLNMNDTHLLQAGTWLTGDNWAEANRLLIRKAIAEFAHEKIVTPAECAHGRYSLAVPGSETEYQFTASRLALDHWEIDAASLTKQENGHPLALDALQFITEFNEVIGIPQALLATYMEEISSTLCSSVFKLQKNNPDSRALVNADFQTVESSMTEGHPCFVANNGRIGFDARDYLAYAPEAATPVNLIWVAVHRRNAHFSSLSDLQYERLMREELGQSTVEQFNAQLTEKGLTHADYLFMPVHPWQWQNKLLTVFAADIANNDIVWLGVGDDQYQAQQSIRTFFNRSHPNKRYVKTALSVLNMGFMRGLSPYYMATTPAINEWLQDLVAGDEWLQRCDFRILREVAAVGYHNRHYEKAIKGDSAYKKMFAALWRDNPVAELKPGQRLMTMASFLHVDHHQKALLPALIADSGLAAERWVERYLSCYLSPLLHCFYQHDLVFMPHGENLILLLENNVPVSAYMKDIGEEIAVMNPDAVLPEKVQRLAVDVPENLKLLSVFTDVFDCIFRFISAILHQSATLPEEQFWQAVARCVKEYQQAHPHLASKFSRYDMFAPEFTRSCLNRLQLANNQQMINLSDPAENLKFAGTLVNPIARWR

SEQ ID NO: 35 - DNA, 3830 bp, synthetic construct
  misc_feature 1..3830: note = Vector Construct
  source 1..3830: mol_type = other DNA
aagcttagacgtgattgctctgattgtgcattacggccgtgaacaggtacgtggcccggccgtcacgacggcacctttgtgagatctccgttatgaataacaccatctatgattttattggtattggcattggaccattcaatctgggccttgcctgtctgagcgaaccggttgaagggttgaacggcgtttttctcgatcagaaccccggctttgactggcataccggcatgatgctggaaagcgcccatttgcaaacgccttttatggccgatctggtgacgctggccgatccgaccagcccttacagcctgctcaattttatgaagcagaagggaaaactttactctttttacatccgcgaagattttttcctgatgagaaaagagtacaaccagtattgccaatgggccgctgaacggctcggcaacctgcgctggaacacccgggttgaatacgtcagctacgatgacaatctgcaatgctatcgtgtccgttcgacagataccgtcagcggtaaacagcaggaatggctggcgcatcgtctggtactgggcaccggccccagcgcctggagtcccgcctgcagccaaccgtatcgcgagcgcttcgtccactccagcgaatatctgctcaacaaagaaaaattgcagaaaaaacgctccatcaccgtactgggcagcggccagagcgcggccgaaatctattacgatctgctgacggatatcgatcgtttcggctatcagctgaactggataactcgcgcgccgcgcttctacccgcttgagtacacgaaactgacgctggaaatgacctcgccagaatggattgactattttcacagtctgccggcggcgaaacgcgacgagcttaacgccagccagaaaaatctctataaaggcatcaacagcagcctgattaatgcgatttacgacctgttgtacgttaagcagctggacggaaagctcgacgtcaatctctttacccattcggagctgaccgacatgcgctggctggcggaaggtgagtttgagctcaagctgcatcagcaggaacaggatcgtgcctacagccgccgtactgagggattagtgatggccacgggctatcactatcaaccaccggcgtttgttgaaggcatccagcagcggatccaatgggatgagaaagaccgttatgacgtacaacgtaattacagcatcgatcgccataaccaggtcttcgtgcaaaatgccgagctgcatacgcacggctttgtcacgcctgatttaggcatggcctgctaccgcaattccgtgttactgcgcgaaatcaccggccgggaagtctaccccgtcgaacgccagatcgctttccagactttccccgcacaatcggaaatgtgatatgccaaattccactctttacagtacgggccgtcccgcgggccggttcaccctccgcccaatgcgccatgaagacgccgcaatggtccaccgttgggtcacacaagagtatgcccgcttctgggggatgcaggacaacagcatcgaacaggttgcggccttttatcaccagctgacggctcataacccgcacgccgcgctgatcggttgctgcaacgaccagccggtgttcctgatggagttctacaaggccagtgaggatgacatcggcaagttctatgccgcgcagccgggcgattacggtatgcatctgctgatagcgcctgccactcacccggtgcagcagttcagctggcaggttttctcgacggtaatcgactttatgttcagcctgccggaggttaagcgggtagtggtggagccggacgagcgtaatacaaaaattcatcgactgaacaagcgcgcgggcttttgctaccagcacaccatcgatatgggccataaaaccgcctggctggccttctgccagcgcgaaaattatcaacaggctttactgaaggaatcgctgaatatgaatgatacccatctgctgcaagccggcacctggctgaccggagataactgggctgaggccaaccgtctgctgatccgcaaagctatcgccgagttcgctcatgagaaaatcgtaacgcctgctgaatgcgctcacggccgctactctctggccgtgccgggcagcgaaacagaataccagtttaccgccagccgcctcgcgctggatcactgggagatagacgccgcttcgctgactaaacaggaaaacggtcatcccctggcgctggacgccttacaatttattacggaattcaatgaggtaatcggtattccacaggctctgctggcaacctatatggaagagatcagcagcacgttgtgcagcagcgttttcaaactgcagaagaataacccggacagccgggcactggtcaacgcagactttcagaccgttgaatcctcaatgaccgaagggcacccgtgcttcgtggcgaacaacgggcgcattggctttgatgcgcgtgactatctggcttacgcgcctgaagctgccacgccggttaatcttatctgggttgccgtgcaccggcgcaacgcccacttctccagcctgagtgacctgcaatacgagcgcctgatgcgtgaagaactggggcagtcaacggttgaacagtttaatgcacagctgacggagaaaggacttacccacgctgattacctctttatgccggttcacccctggcagtggcagaacaagctgctgacggtatttgcggcagatatcgccaataacgatattgtctggcttggcgtcggcgacgatcaatatcaggcgcagcagtctattcggacctttttcaaccgcagccatcctaacaagcgctatgtcaaaacagcactgtcagtgctgaatatgggctttatgcgcggtctttctccctattatatggcgaccacgccggcgattaatgaatggctgcaagatctggtggccggggatgaatggctacagcgctgtgatttccgcattctgcgcgaagtggcggcagtgggttaccataaccgccactatgaaaaagccatcaagggtgattccgcctacaagaaaatgtttgccgcgctgtggcgtgataatccggttgccgagctcaaacccggccagcgcctgatgaccatggcctcattcctgcacgttgatcatcaccagaaagccctgctgccagcgctgatcgccgattccgggctggccgctgaacgctgggtggaacgctatctgagctgctacctcagtccgctgctgcactgcttctaccagcacgatctggtgtttatgccgcacggcgaaaacctgatcctgctgctggagaataacgtcccggtcagcgcctatatgaaagacatcggcgaagaaattgcggtgatgaacccggatgccgtgctgccggaaaaagtacagcgcctggcggtggacgtgccggaaaacctcaagctgctgtcggtctttaccgacgtgttcgactgcattttccgctttatcagcgctattcttcaccagtccgccactctgccggaagaacaattctggcaggcggtcgcgcgctgcgtgaaggagtaccagcaggcccatccgcatctggccagcaagttttcccgttacgatatgttcgcgccggaattcacccgctcctgcctcaaccgactacagctggccaataaccagcaaatgatcaatctgtcagacccggctgaaaatctgaaatttgccggtacgctggtcaacccgatcgcccgctggcgttaacgtcctccttcttctgggtaaaaaaaagcacggccgcttaaacggccgtgctttttattcaggtaaaccgaatcgcgggttagaagctt

SEQ ID NO: 36 - DNA, 10415 bp, synthetic construct
  misc_feature 1..10415: note = Vector Construct
  source 1..10415: mol_type = other DNA
aattaagacgtgattgctctgattgtgcattacggccgtgaacaggtacgtggcccggccgtcacgacggcacctttgtgagatctccgttatgaataacaccatctatgattttattggtattggcattggaccattcaatctgggccttgcctgtctgagcgaaccggttgaagggttgaacggcgtttttctcgatcagaaccccggctttgactggcataccggcatgatgctggaaagcgcccatttgcaaacgccttttatggccgatctggtgacgctggccgatccgaccagcccttacagcctgctcaattttatgaagcagaagggaaaactttactctttttacatccgcgaagattttttcctgatgagaaaagagtacaaccagtattgccaatgggccgctgaacggctcggcaacctgcgctggaacacccgggttgaatacgtcagctacgatgacaatctgcaatgctatcgtgtccgttcgacagataccgtcagcggtaaacagcaggaatggctggcgcatcgtctggtactgggcaccggccccagcgcctggagtcccgcctgcagccaaccgtatcgcgagcgcttcgtccactccagcgaatatctgctcaacaaagaaaaattgcagaaaaaacgctccatcaccgtactgggcagcggccagagcgcggccgaaatctattacgatctgctgacggatatcgatcgtttcggctatcagctgaactggataactcgcgcgccgcgcttctacccgcttgagtacacgaaactgacgctggaaatgacctcgccagaatggattgactattttcacagtctgccggcggcgaaacgcgacgagcttaacgccagccagaaaaatctctataaaggcatcaacagcagcctgattaatgcgatttacgacctgttgtacgttaagcagctggacggaaagctcgacgtcaatctctttacccattcggagctgaccgacatgcgctggctggcggaaggtgagtttgagctcaagctgcatcagcaggaacaggatcgtgcctacagccgccgtactgagggattagtgatggccacgggctatcactatcaaccaccggcgtttgttgaaggcatccagcagcggatccaatgggatgagaaagaccgttatgacgtacaacgtaattacagcatcgatcgccataaccaggtcttcgtgcaaaatgccgagctgcatacgcacggctttgtcacgcctgatttaggcatggcctgctaccgcaattccgtgttactgcgcgaaatcaccggccgggaagtctaccccgtcgaacgccagatcgctttccagactttccccgcacaatcggaaatgtgatatgccaaattccactctttacagtacgggccgtcccgcgggccggttcaccctccgcccaatgcgccatgaagacgccgcaatggtccaccgttgggtcacacaagagtatgcccgcttctgggggatgcaggacaacagcatcgaacaggttgcggccttttatcaccagctgacggctcataacccgcacgccgcgctgatcggttgctgcaacgaccagccggtgttcctgatggagttctacaaggccagtgaggatgacatcggcaagttctatgccgcgcagccgggcgattacggtatgcatctgctgatagcgcctgccactcacccggtgcagcagttcagctggcaggttttctcgacggtaatcgactttatgttcagcctgccggaggttaagcgggtagtggtggagccggacgagcgtaatacaaaaattcatcgactgaacaagcgcgcgggcttttgctaccagcacaccatcgatatgggccataaaaccgcctggctggccttctgccagcgcgaaaattatcaacaggctttactgaaggaatcgctgaatatgaatgatacccatctgctgcaagccggcacctggctgaccggagataactgggctgaggccaaccgtctgctgatccgcaaagctatcgccgagttcgctcatgagaaaatcgtaacgcctgctgaatgcgctcacggccgctactctctggccgtgccgggcagcgaaacagaataccagtttaccgccagccgcctcgcgctggatcactgggagatagacgccgcttcgctgactaaacaggaaaacggtcatcccctggcgctggacgccttacaatttattacggaattcaatgaggtaatcggtattccacaggctctgctggcaacctatatggaagagatcagcagcacgttgtgcagcagcgttttcaaactgcagaagaataacccggacagccgggcactggtcaacgcagactttcagaccgttgaatcctcaatgaccgaagggcacccgtgcttcgtggcgaacaacgggcgcattggctttgatgcgcgtgactatctggcttacgcgcctgaagctgccacgccggttaatcttatctgggttgccgtgcaccggcgcaacgcccacttctccagcctgagtgacctgcaatacgagcgcctgatgcgtgaagaactggggcagtcaacggttgaacagtttaatgcacagctgacggagaaaggacttacccacgctgattacctctttatgccggttcacccctggcagtggcagaacaagctgctgacggtatttgcggcagatatcgccaataacgatattgtctggcttggcgtcggcgacgatcaatatcaggcgcagcagtctattcggacctttttcaaccgcagccatcctaacaagcgctatgtcaaaacagcactgtcagtgctgaatatgggctttatgcgcggtctttctccctattatatggcgaccacgccggcgattaatgaatggctgcaagatctggtggccggggatgaatggctacagcgctgtgatttccgcattctgcgcgaagtggcggcagtgggttaccataaccgccactatgaaaaagccatcaagggtgattccgcctacaagaaaatgtttgccgcgctgtggcgtgataatccggttgccgagctcaaacccggccagcgcctgatgaccatggcctcattcctgcacgttgatcatcaccagaaagccctgctgccagcgctgatcgccgattccgggctggccgctgaacgctgggtggaacgctatctgagctgctacctcagtccgctgctgcactgcttctaccagcacgatctggtgtttatgccgcacggcgaaaacctgatcctgctgctggagaataacgtcccggtcagcgcctatatgaaagacatcggcgaagaaattgcggtgatgaacccggatgccgtgctgccggaaaaagtacagcgcctggcggtggacgtgccggaaaacctcaagctgctgtcggtctttaccgacgtgttcgactgcattttccgctttatcagcgctattcttcaccagtccgccactctgccggaagaacaattctggcaggcggtcgcgcgctgcgtgaaggagtaccagcaggcccatccgcatctggccagcaagttttcccgttacgatatgttcgcgccggaattcacccgctcctgcctcaaccgactacagctggccaataaccagcaaatgatcaatctgtcagacccggctgaaaatctgaaatttgccggtacgctggtcaacccgatcgcccgctggcgttaacgtcctccttcttctgggtaaaaaaaagcacggccgcttaaacggccgtgctttttattcaggtaaaccgaatcgcgggttagtgcatgcctgcaggtcgactctagaggatccccgggtaccgagctcgaattcagcttggctgttttggcggatgagagaagattttcagcctgatacagattaaatcagaacgcagaagcggtctgataaaacagaatttgcctggcggcagtagcgcggtggtcccacctgaccccatgccgaactcagaagtgaaacgccgtagcgccgatggtagtgtggggtctccccatgcgagagtagggaactgccaggcatcaaataaaacgaaaggctcagtcgaaagactgggcctttcgttttatctgttgtttgtcggtgaacgctctcctgagtaggacaaatccgccgggagcggatttgaacgttgcgaagcaacggcccggagggtggcgggcaggacgcccgccataaactgccaggcatcaaattaagcagaaggccatcctgacggatggcctttttgcgtttctacaaactcttttgtttatttttctaaatacattcaaatatgtatccgctcatgagacaataaccctgataaatgcttcaataatattgaaaaaggaagagtatgagtattcaacatttccgtgtcgcccttattcccttttttgcggcattttgccttcctgtttttgctcacccagaaacgctggtgaaagtaaaagatgctgaagatcagttgggtgcacgagtgggttacatcgaactggatctcaacagcggtaagatccttgagagttttcgccccgaagaacgttttccaatgatgagcacttttgcttcctcgctcactgactcgctgcgctcggtcgttcggctgcggcgagcggtatcagctcactcaaaggcggtaatacggttatccacagaatcaggggataacgcaggaaagaacatgtgagcaaaaggccagcaaaaggccaggaaccgtaaaaaggccgcgttgctggcgtttttccataggctccgcccccctgacgagcatcacaaaaatcgacgctcaagtcagaggtggcgaaacccgacaggactataaagataccaggcgtttccccctggaagctccctcgtgcgctctcctgttccgaccctgccgcttaccggatacctgtccgcctttctcccttcgggaagcgtggcgctttctcaatgctcacgctgtaggtatctcagttcggtgtaggtcgttcgctccaagctgggctgtgtgcacgaaccccccgttcagcccgaccgctgcgccttatccggtaactatcgtcttgagtccaacccggtaagacacgacttatcgccactggcagcagccactggtaacaggattagcagagcgaggtatgtaggcggtgctacagagttcttgaagtggtggcctaactacggctacactagaaggacagtatttggtatctgcgctctgctgaagccagttaccttcggaaaaagagttggtagctcttgatccggcaaacaaaccaccgctggtagcggtggtttttttgtttgcaagcagcagattacgcgcagaaaaaaaggatctcaagaagatcctttgatcttttctacggggtctgacgctcagtggaacgaaaactcacgttaagggattttggtcatgagattatcaaaaaggatcttcacctagatccttttggggtgggcgaagaactccagcatgagatccccgcgctggaggatcatccagccattcggggtcgttcactggttcccctttctgatttctggcatagaagaacccccgtgaactgtgtggttccgggggttgctgatttttgcgagacttctcgcgcaattccctagcttaggtgaaaacaccatgaaacactagggaaacacccatgaaacacccattagggcagtagggcggcttcttcgtctagggcttgcatttgggcggtgatctggtctttagcgtgtgaaagtgtgtcgtaggtggcgtgctcaatgcactcgaacgtcacgtcatttaccgggtcacggtgggcaaagagaactagtgggttagacattgttttcctcgttgtcggtggtggtgagcttttctagccgctcggtaaacgcggcgatcatgaactcttggaggttttcaccgttctgcatgcctgcgcgcttcatgtcctcacgtagtgccaaaggaacgcgtgcggtgaccacgacgggcttagcctttgcctgcgcttctagtgcttcgatggtggcttgtgcctgcgcttgctgcgcctgtagtgcctgttgagcttcttgtagttgctgttctagctgtgccttggttgccatgctttaagactctagtagctttcctgcgatatgtcatgcgcatgcgtagcaaacattgtcctgcaactcattcattatgtgcagtgctcctgttactagtcgtacatactcatatttacctagtctgcatgcagtgcatgcacatgcagtcatgtcgtgctaatgtgtaaaacatgtacatgcagattgctgggggtgcagggggcggagccaccctgtccatgcggggtgtggggcttgccccgccggtacagacagtgagcaccggggcacctagtcgcggataccccccctaggtatcggacacgtaaccctcccatgtcgatgcaaatctttaacattgagtacgggtaagctggcacgcatagccaagctaggcggccaccaaacaccactaaaaattaatagtccctagacaagacaaacccccgtgcgagctaccaactcatatgcacgggggccacataacccgaaggggtttcaattgacaaccatagcactagctaagacaacgggcacaacacccgcacaaactcgcactgcgcaaccccgcacaacatcgggtctaggtaacactgagtaacactgaaatagaagtgaacacctctaaggaaccgcaggtcaatgagggttctaaggtcactcgcgctagggcgtggcgtaggcaaaacgtcatgtacaagatcaccaatagtaaggctctggcggggtgccataggtggcgcagggacgaagctgttgcggtgtcctggtcgtctaacggtgcttcgcagtttgagggtctgcaaaactctcactctcgctgggggtcacctctggctgaattggaagtcatgggcgaacgccgcattgagctggctattgctactaagaatcacttggcggcgggtggcgcgctcatgatgtttgtgggcactgttcgacacaaccgctcacagtcatttgcgcaggttgaagcgggtattaagactgcgtactcttcgatggtgaaaacatctcagtggaagaaagaacgtgcacggtacggggtggagcacacctatagtgactatgaggtcacagactcttgggcgaacggttggcacttgcaccgcaacatgctgttgttcttggatcgtccactgtctgacgatgaactcaaggcgtttgaggattccatgttttcccgctggtctgctggtgtggttaaggccggtatggacgcgccactgcgtgagcacggggtcaaacttgatcaggtgtctacctggggtggagacgctgcgaaaatggcaacctacctcgctaagggcatgtctcaggaactgactggctccgctactaaaaccgcgtctaaggggtcgtacacgccgtttcagatgttggatatgttggccgatcaaagcgacgccggcgaggatatggacgctgttttggtggctcggtggcgtgagtatgaggttggttctaaaaacctgcgttcgtcctggtcacgtggggctaagcgtgctttgggcattgattacatagacgctgatgtacgtcgtgaaatggaagaagaactgtacaagctcgccggtctggaagcaccggaacgggtcgaatcaacccgcgttgctgttgctttggtgaagcccgatgattggaaactgattcagtctgatttcgcggttaggcagtacgttctcgattgcgtggataaggctaaggacgtggccgctgcgcaacgtgtcgctaatgaggtgctggcaagtctgggtgtggattccaccccgtgcatgatcgttatggatgatgtggacttggacgcggttctgcctactcatggggacgctactaagcgtgatctgaatgcggcggtgttcgcgggtaatgagcagactattcttcgcacccactaaaagcggcataaaccccgttcgatattttgtgcgatgaatttatggtcaatgtcgcgggggcaaactatgatgggtcttgttgttggcgtcccggaaaacgattccgaagcccaacctttcatagaaggcggcggtggaatcgaaatctcgtgatggcaggttgggcgtcgcttggtcggtcatttcgaagggcaccaataactgccttaaaaaaattacgccccgccctgccactcatcgcagtactgttgtaattcattaagcattctgccgacatggaagccatcacagacggcatgatgaacctgaatcgccagcggcatcagcaccttgtcgccttgcgtataatatttgcccatggtgaaaacgggggcgaagaagttgtccatattggccacgtttaaatcaaaactggtgaaactcacccagggattggctgagacgaaaaacatattctcaataaaccctttagggaaataggccaggttttcaccgtaacacgccacatcttgcgaatatatgtgtagaaactgccggaaatcgtcgtggtattcactccagagcgatgaaaacgtttcagtttgctcatggaaaacggtgtaacaagggtgaacactatcccatatcaccagctcaccgtctttcattgccatacggaactccggatgagcattcatcaggcgggcaagaatgtgaataaaggccggataaaacttgtgcttatttttctttacggtctttaaaaaggccgtaatatccagctgaacggtctggttataggtacattgagcaactgactgaaatgcctcaaaatgttctttacgatgccattgggatatatcaacggtggtatatccagtgatttttttctccattttagcttccttagctcctgaaaatctcgtcgaagctcggcggatttgtcctactcaagctgatccgacaaaatccacacattatcccaggtgtccggatcggtcaaatacgctgccagctcatagaccgtatccaaagcatccggggctgatccccggcgccagggtggtttttcttttcaccagtgagacgggcaacagctgattgcccttcaccgcctggccctgagagagttgcagcaagcggtccacgtggtttgccccagcaggcgaaaatcctgtttgatggtggttaacggcgggatataacatgagctgtcttcggtatcgtcgtatcccactaccgagatatccgcaccaacgcgcagcccggactcggtaatggcgcgcattgcgcccagcgccatctgatcgttggcaaccagcatcgcagtgggaacgatgccctcattcagcatttgcatggtttgttgaaaaccggacatggcactccagtcgccttcccgttccgctatcggctgaatttgattgcgagtgagatatttatgccagccagccagacgcagacgcgccgagacagaacttaatgggcccgctaacagcgcgatttgctggtgacccaatgcgaccagatgctccacgcccagtcgcgtaccgtcttcatgggagaaaataatactgttgatgggtgtctggtcagagacatcaagaaataacgccggaacattagtgcaggcagcttccacagcaatggcatcctggtcatccagcggatagttaatgatcagcccactgacgcgttgcgcgagaagattgtgcaccgccgctttacaggcttcgacgccgcttcgttctaccatcgacaccaccacgctggcacccagttgatcggcgcgagatttaatcgccgcgacaatttgcgacggcgcgtgcagggccagactggaggtggcaacgccaatcagcaacgactgtttgcccgccagttgttgtgccacgcggttgggaatgtaattcagctccgccatcgccgcttccactttttcccgcgttttcgcagaaacgtggctggcctggttcaccacgcgggaaacggtctgataagagacaccggcatactctgcgacatcgtataacgttactggtttcacattcaccaccctgaattgactctcttccgggcgctatcatgccataccgcgaaaggttttgcaccattcgatggtgtcaacgtaaatgccgcttcgccttcgcgcgcgaattgcaagctgatccgggcttatcgactgcacggtgcaccaatgcttctggcgtcaggcagccatcggaagctgtggtatggctgtgcaggtcgtaaatcactgcataattcgtgtcgctcaaggcgcactcccgttctggataatgttttttgcgccgacatcataacggttctggcaaatattctgaaatgagctgttgacaattaatcatcggctcgtataatgtgtggaattgtgagcggataacaatttcacacaggaaacagaatt

SEQ ID NO: 37 - DNA, 1293 bp, Pantoea agglomerans
  source 1..1293: mol_type = genomic DNA
atgaataattccgtttacgattttattggtatcggtatcggccctttcaacctgagtctggcctgtctgagtgagccggttgagggactgaacggtcttttcctggatgagaacccaggctttgactggcacaccggcatgatgctggaaaatgcccatctgcagacgccgtttatggccgatctggtgacactcgccgatccgaccagcccttacagcctgcttaactacatgaaggaaaaggggaaattatactctttttatatccgtgaagacttcttcctgatgcgcaaagagtataatcagtactgccagtgggccagttcacggctctctaatctgcgctggaacagccacgttgagtatgtcagctacgatgaggcggctggcgtctatcaactccaggtgaccgacacccggaatggtcagaaacagaactatctggcacgacatctgatcctcggcaccgggcctaaagcctggatgccggagtgcagccagccgcaccgccagcgcctgacgcactcaagccactatctggtcaacaaagcggaactgcagcagaagcgttccatcaccgtgctgggcagcggccagagcgcggcagaaatctactacgacctgctgaccgatatcgaccgctttggctatcagctcaactggatcacccgcgcgccgcgcttctatccgctggagtacaccaagctcacgctggagatgacttcgccggagtgggtcgactatttccacgcgctgcccgccagcacccgcgacgaactgaatgcgcgccacaagaatctctacaaaggcatcaacagcagcctgattaacgacatttatgacctgatgtatgtcaaacagctcgacggcgatctgaacgttaacctgtttactcactcggcgctgaccgctatgcgctggctgccacagggagagttcgagctgacgctgcatcaggaggagcaggattgcaccttcacccgtcgcaccgaaggactggtgatggcgaccggctatcactaccagccaccgatgtttttagagggcatcaacgcccgcctgcgctgggatgacaaaggccgctacgacgtgcagcgcaactacagcatcgattatcacaatcagatcttcgtgcagaacgccgaactgcacacccacggttttgttacgccggatctcggcatggcctgttaccgcaactcggtgctgctgcgcgaactgaccggacgcgaggtctacccgatcgagcgtcagattgccttccagaccttcccggctaaatcggagcactga

SEQ ID NO: 38 - DNA, 2355 bp, Pantoea agglomerans
  source 1..2355: mol_type = genomic DNA
atgagttcacaaacactgttcagcgcagcccgccccgcaggccagttcaccctgaggcccatgctcgccagcgatgcgccgctgattcatcgctgggtcacccgcgattacgcccgcttctggggcatgcagcagcagagcctgaatcaggtcgctgagttctaccagacgctgaccaaagccgatccccatgctgcgctgattggttgctgcaacgaccagccggtctgcctgattgagtgctatcgcgcctgcgacgatgaggtcggcaaattttatcctgccgcacccgatgattacggcatgcatattctgattgcccccgccagccagccgatcagagccttcagctggcaggtcttcacgctggtgatggactacatgttcagccgccccgaggtgcgccgcgtggtggtagagccagatgtgcgcaatgagaagattcacgtgctgaataagcgtgccgggttccgctatcagcacaccatcgacatgggtcataaaaccgcctggctggccttttgccagcgggaagattatcaacacgcgttactgcaggagtcgcagactatgaacaccccctcttcgctgatgaacggtacacatctgacgggcgaccaatgggcgcaggcaaaccgcatgctgatccggaaagcgattgccgaattcgcgcatgagaaaatcattacgccacaggagtcgggcgacggcagctatcagcttgcggtgccaggcggtgaagcgagctaccatttccgggcgtcgcggctggcgctggatcactgggaaattgacgccggctcactgcgcaagcaggagaacggtcgtgatctgccgctggatgcgctgaagtttatcgtggagtttaacggggagatcggtattacacaggcactgctggcgacctacatggaagagatcagcagcacgctgtgcagtagcgtttataagctgcagaagaataatcctgacagccaggcgctggtctcagccgatttccagacggtggaagcggcgatgaccgaaggccatccctgctttgttgccaacaacgggcgtattggcttcgatgcccatgattatctggcgtatgcgcccgaggccgccgcgcccgttcacctcatctgggtcgcggttcatcgccgcaacgcccatttctccagcctcagcgagctgagctatgagcagttgatgcgtgatgaactgggcgacaccaccctggagcagtttactgcgcagctggtgaataaagggctggcggttgaggagtatatcctgatgccggtgcatccgtggcagtggcagaacaaactgctgaccgtatttgcggcggacatcgccagtcacgatattgtttatctcggcaccggagacgatgcttaccaggcgcagcagtcgatccgcaccttctttaaccgcagccagcccacgaagcgctacgtgaaaaccgccctgtcggtgctgaacatgggctttatgcgcggactgtccccctactatatggcgacaacgcctgcgataaacggctggctggaacaactggttgctggcgatgcgtggctgaatcgctgtgatttccgcatcctgcgcgaagtcgcggcggtcggctatcacaaccgctactatgagcaggcgatcaaaggcgactccgcctataaaaagatgttcgctgcgctgtggcgggataatcctgcggccagcctgcagcccggccagcgtctgatgaccatggcctctttcctgcacgtcgatcaccatcagcaggcactgctgccagcgctgatagcggattctggtttgcccgcgaagcagtggatagaacgctacctgacctgctatctcagcccgctgctgcactgcttctatcagcatgacctggtgtttatgccgcacggtgaaaacctcatcatgctgctggagaacaacgtgccggtcagtgcatacatgaaggatatcggcgaagagatcgccgtgatgaatccggatgcggtgctgccggaaggcgtgcagcgtctggcggtggatgtgccggagaacctgaagctgctctcgatcttcaccgatgtgtttgactgcatcttccgctttatcagcgcgattctgcatcagtcaggaacgctgccggaggaagaattctggcaggcggtggcgcagtgcgtgaaggattaccagcaggcgcacccggagcatgccactaagttcgcgcgctatgacatgttcgcgccggagtttacccgctcctgtctgaaccgcctgcagctggcgaataaccagcagatgataaacctcgccgatcccgctgagaatctcaagttcgccggaacgctgaataacccgattgcccgctggcgataa

SEQ ID NO: 39 - protein, 430 aa, Pantoea agglomerans
MNNSVYDFIGIGIGPFNLSLACLSEPVEGLNGLFLDENPGFDWHTGMMLENAHLQTPFMADLVTLADPTSPYSLLNYMKEKGKLYSFYIREDFFLMRKEYNQYCQWASSRLSNLRWNSHVEYVSYDEAAGVYQLQVTDTRNGQKQNYLARHLILGTGPKAWMPECSQPHRQRLTHSSHYLVNKAELQQKRSITVLGSGQSAAEIYYDLLTDIDRFGYQLNWITRAPRFYPLEYTKLTLEMTSPEWVDYFHALPASTRDELNARHKNLYKGINSSLINDIYDLMYVKQLDGDLNVNLFTHSALTAMRWLPQGEFELTLHQEEQDCTFTRRTEGLVMATGYHYQPPMFLEGINARLRWDDKGRYDVQRNYSIDYHNQIFVQNAELHTHGFVTPDLGMACYRNSVLLRELTGREVYPIERQIAFQTFPAKSEH

SEQ ID NO: 40 - protein, 784 aa, Pantoea agglomerans
MSSQTLFSAARPAGQFTLRPMLASDAPLIHRWVTRDYARFWGMQQQSLNQVAEFYQTLTKADPHAALIGCCNDQPVCLIECYRACDDEVGKFYPAAPDDYGMHILIAPASQPIRAFSWQVFTLVMDYMFSRPEVRRVVVEPDVRNEKIHVLNKRAGFRYQHTIDMGHKTAWLAFCQREDYQHALLQESQTMNTPSSLMNGTHLTGDQWAQANRMLIRKAIAEFAHEKIITPQESGDGSYQLAVPGGEASYHFRASRLALDHWEIDAGSLRKQENGRDLPLDALKFIVEFNGEIGITQALLATYMEEISSTLCSSVYKLQKNNPDSQALVSADFQTVEAAMTEGHPCFVANNGRIGFDAHDYLAYAPEAAAPVHLIWVAVHRRNAHFSSLSELSYEQLMRDELGDTTLEQFTAQLVNKGLAVEEYILMPVHPWQWQNKLLTVFAADIASHDIVYLGTGDDAYQAQQSIRTFFNRSQPTKRYVKTALSVLNMGFMRGLSPYYMATTPAINGWLEQLVAGDAWLNRCDFRILREVAAVGYHNRYYEQAIKGDSAYKKMFAALWRDNPAASLQPGQRLMTMASFLHVDHHQQALLPALIADSGLPAKQWIERYLTCYLSPLLHCFYQHDLVFMPHGENLIMLLENNVPVSAYMKDIGEEIAVMNPDAVLPEGVQRLAVDVPENLKLLSIFTDVFDCIFRFISAILHQSGTLPEEEFWQAVAQCVKDYQQAHPEHATKFARYDMFAPEFTRSCLNRLQLANNQQMINLADPAENLKFAGTLNNPIARWR

SEQ ID NO: 41 - DNA, 3842 bp, synthetic construct
  misc_feature 1..3842: note = Vector Construct
  source 1..3842: mol_type = other DNA
aagcttgagcaggtacgtgcgtctgcgctgaacgcggcgaaacagtgagagctctgaaatgaataattccgtttacgattttattggtatcggtatcggccctttcaacctgagtctggcctgtctgagtgagccggttgagggactgaacggtcttttcctggatgagaacccaggctttgactggcacaccggcatgatgctggaaaatgcccatctgcagacgccgtttatggccgatctggtgacactcgccgatccgaccagcccttacagcctgcttaactacatgaaggaaaaggggaaattatactctttttatatccgtgaagacttcttcctgatgcgcaaagagtataatcagtactgccagtgggccagttcacggctctctaatctgcgctggaacagccacgttgagtatgtcagctacgatgaggcggctggcgtctatcaactccaggtgaccgacacccggaatggtcagaaacagaactatctggcacgacatctgatcctcggcaccgggcctaaagcctggatgccggagtgcagccagccgcaccgccagcgcctgacgcactcaagccactatctggtcaacaaagcggaactgcagcagaagcgttccatcaccgtgctgggcagcggccagagcgcggcagaaatctactacgacctgctgaccgatatcgaccgctttggctatcagctcaactggatcacccgcgcgccgcgcttctatccgctggagtacaccaagctcacgctggagatgacttcgccggagtgggtcgactatttccacgcgctgcccgccagcacccgcgacgaactgaatgcgcgccacaagaatctctacaaaggcatcaacagcagcctgattaacgacatttatgacctgatgtatgtcaaacagctcgacggcgatctgaacgttaacctgtttactcactcggcgctgaccgctatgcgctggctgccacagggagagttcgagctgacgctgcatcaggaggagcaggattgcaccttcacccgtcgcaccgaaggactggtgatggcgaccggctatcactaccagccaccgatgtttttagagggcatcaacgcccgcctgcgctgggatgacaaaggccgctacgacgtgcagcgcaactacagcatcgattatcacaatcagatcttcgtgcagaacgccgaactgcacacccacggttttgttacgccggatctcggcatggcctgttaccgcaactcggtgctgctgcgcgaactgaccggacgcgaggtctacccgatcgagcgtcagattgccttccagaccttcccggctaaatcggagcactgagatgagttcacaaacactgttcagcgcagcccgccccgcaggccagttcaccctgaggcccatgctcgccagcgatgcgccgctgattcatcgctgggtcacccgcgattacgcccgcttctggggcatgcagcagcagagcctgaatcaggtcgctgagttctaccagacgctgaccaaagccgatccccatgctgcgctgattggttgctgcaacgaccagccggtctgcctgattgagtgctatcgcgcctgcgacgatgaggtcggcaaattttatcctgccgcacccgatgattacggcatgcatattctgattgcccccgccagccagccgatcagagccttcagctggcaggtcttcacgctggtgatggactacatgttcagccgccccgaggtgcgccgcgtggtggtagagccagatgtgcgcaatgagaagattcacgtgctgaataagcgtgccgggttccgctatcagcacaccatcgacatgggtcataaaaccgcctggctggccttttgccagcgggaagattatcaacacgcgttactgcaggagtcgcagactatgaacaccccctcttcgctgatgaacggtacacatctgacgggcgaccaatgggcgcaggcaaaccgcatgctgatccggaaagcgattgccgaattcgcgcatgagaaaatcattacgccacaggagtcgggcgacggcagctatcagcttgcggtgccaggcggtgaagcgagctaccatttccgggcgtcgcggctggcgctggatcactgggaaattgacgccggctcactgcgcaagcaggagaacggtcgtgatctgccgctggatgcgctgaagtttatcgtggagtttaacggggagatcggtattacacaggcactgctggcgacctacatggaagagatcagcagcacgctgtgcagtagcgtttataagctgcagaagaataatcctgacagccaggcgctggtctcagccgatttccagacggtggaagcggcgatgaccgaaggccatccctgctttgttgccaacaacgggcgtattggcttcgatgcccatgattatctggcgtatgcgcccgaggccgccgcgcccgttcacctcatctgggtcgcggttcatcgccgcaacgcccatttctccagcctcagcgagctgagctatgagcagttgatgcgtgatgaactgggcgacaccaccctggagcagtttactgcgcagctggtgaataaagggctggcggttgaggagtatatcctgatgccggtgcatccgtggcagtggcagaacaaactgctgaccgtatttgcggcggacatcgccagtcacgatattgtttatctcggcaccggagacgatgcttaccaggcgcagcagtcgatccgcaccttctttaaccgcagccagcccacgaagcgctacgtgaaaaccgccctgtcggtgctgaacatgggctttatgcgcggactgtccccctactatatggcgacaacgcctgcgataaacggctggctggaacaactggttgctggcgatgcgtggctgaatcgctgtgatttccgcatcctgcgcgaagtcgcggcggtcggctatcacaaccgctactatgagcaggcgatcaaaggcgactccgcctataaaaagatgttcgctgcgctgtggcgggataatcctgcggccagcctgcagcccggccagcgtctgatgaccatggcctctttcctgcacgtcgatcaccatcagcaggcactgctgccagcgctgatagcggattctggtttgcccgcgaagcagtggatagaacgctacctgacctgctatctcagcccgctgctgcactgcttctatcagcatgacctggtgtttatgccgcacggtgaaaacctcatcatgctgctggagaacaacgtgccggtcagtgcatacatgaaggatatcggcgaagagatcgccgtgatgaatccggatgcggtgctgccggaaggcgtgcagcgtctggcggtggatgtgccggagaacctgaagctgctctcgatcttcaccgatgtgtttgactgcatcttccgctttatcagcgcgattctgcatcagtcaggaacgctgccggaggaagaattctggcaggcggtggcgcagtgcgtgaaggattaccagcaggcgcacccggagcatgccactaagttcgcgcgctatgacatgttcgcgccggagtttacccgctcctgtctgaaccgcctgcagctggcgaataaccagcagatgataaacctcgccgatcccgctgagaatctcaagttcgccggaacgctgaataacccgattgcccgctggcgataagcgttacaccgtcacgctgaaattatgcggtcaccctggccgctgtgtgccgttgataaaatataacccagcaggatggcagaaatttatttgccatcctgcaactgaaacaaagagattacatcccacaagctt

SEQ ID NO: 42 - DNA, 10427 bp, synthetic construct
  misc_feature 1..10427: note = Vector Construct
  source 1..10427: mol_type = other DNA
aattagagcaggtacgtgcgtctgcgctgaacgcggcgaaacagtgagagctctgaaatgaataattccgtttacgattttattggtatcggtatcggccctttcaacctgagtctggcctgtctgagtgagccggttgagggactgaacggtcttttcctggatgagaacccaggctttgactggcacaccggcatgatgctggaaaatgcccatctgcagacgccgtttatggccgatctggtgacactcgccgatccgaccagcccttacagcctgcttaactacatgaaggaaaaggggaaattatactctttttatatccgtgaagacttcttcctgatgcgcaaagagtataatcagtactgccagtgggccagttcacggctctctaatctgcgctggaacagccacgttgagtatgtcagctacgatgaggcggctggcgtctatcaactccaggtgaccgacacccggaatggtcagaaacagaactatctggcacgacatctgatcctcggcaccgggcctaaagcctggatgccggagtgcagccagccgcaccgccagcgcctgacgcactcaagccactatctggtcaacaaagcggaactgcagcagaagcgttccatcaccgtgctgggcagcggccagagcgcggcagaaatctactacgacctgctgaccgatatcgaccgctttggctatcagctcaactggatcacccgcgcgccgcgcttctatccgctggagtacaccaagctcacgctggagatgacttcgccggagtgggtcgactatttccacgcgctgcccgccagcacccgcgacgaactgaatgcgcgccacaagaatctctacaaaggcatcaacagcagcctgattaacgacatttatgacctgatgtatgtcaaacagctcgacggcgatctgaacgttaacctgtttactcactcggcgctgaccgctatgcgctggctgccacagggagagttcgagctgacgctgcatcaggaggagcaggattgcaccttcacccgtcgcaccgaaggactggtgatggcgaccggctatcactaccagccaccgatgtttttagagggcatcaacgcccgcctgcgctgggatgacaaaggccgctacgacgtgcagcgcaactacagcatcgattatcacaatcagatcttcgtgcagaacgccgaactgcacacccacggttttgttacgccggatctcggcatggcctgttaccgcaactcggtgctgctgcgcgaactgaccggacgcgaggtctacccgatcgagcgtcagattgccttccagaccttcccggctaaatcggagcactgagatgagttcacaaacactgttcagcgcagcccgccccgcaggccagttcaccctgaggcccatgctcgccagcgatgcgccgctgattcatcgctgggtcacccgcgattacgcccgcttctggggcatgcagcagcagagcctgaatcaggtcgctgagttctaccagacgctgaccaaagccgatccccatgctgcgctgattggttgctgcaacgaccagccggtctgcctgattgagtgctatcgcgcctgcgacgatgaggtcggcaaattttatcctgccgcacccgatgattacggcatgcatattctgattgcccccgccagccagccgatcagagccttcagctggcaggtcttcacgctggtgatggactacatgttcagccgccccgaggtgcgccgcgtggtggtagagccagatgtgcgcaatgagaagattcacgtgctgaataagcgtgccgggttccgctatcagcacaccatcgacatgggtcataaaaccgcctggctggccttttgccagcgggaagattatcaacacgcgttactgcaggagtcgcagactatgaacaccccctcttcgctgatgaacggtacacatctgacgggcgaccaatgggcgcaggcaaaccgcatgctgatccggaaagcgattgccgaattcgcgcatgagaaaatcattacgccacaggagtcgggcgacggcagctatcagcttgcggtgccaggcggtgaagcgagctaccatttccgggcgtcgcggctggcgctggatcactgggaaattgacgccggctcactgcgcaagcaggagaacggtcgtgatctgccgctggatgcgctgaagtttatcgtggagtttaacggggagatcggtattacacaggcactgctggcgacctacatggaagagatcagcagcacgctgtgcagtagcgtttataagctgcagaagaataatcctgacagccaggcgctggtctcagccgatttccagacggtggaagcggcgatgaccgaaggccatccctgctttgttgccaacaacgggcgtattggcttcgatgcccatgattatctggcgtatgcgcccgaggccgccgcgcccgttcacctcatctgggtcgcggttcatcgccgcaacgcccatttctccagcctcagcgagctgagctatgagcagttgatgcgtgatgaactgggcgacaccaccctggagcagtttactgcgcagctggtgaataaagggctggcggttgaggagtatatcctgatgccggtgcatccgtggcagtggcagaacaaactgctgaccgtatttgcggcggacatcgccagtcacgatattgtttatctcggcaccggagacgatgcttaccaggcgcagcagtcgatccgcaccttctttaaccgcagccagcccacgaagcgctacgtgaaaaccgccctgtcggtgctgaacatgggctttatgcgcggactgtccccctactatatggcgacaacgcctgcgataaacggctggctggaacaactggttgctggcgatgcgtggctgaatcgctgtgatttccgcatcctgcgcgaagtcgcggcggtcggctatcacaaccgctactatgagcaggcgatcaaaggcgactccgcctataaaaagatgttcgctgcgctgtggcgggataatcctgcggccagcctgcagcccggccagcgtctgatgaccatggcctctttcctgcacgtcgatcaccatcagcaggcactgctgccagcgctgatagcggattctggtttgcccgcgaagcagtggatagaacgctacctgacctgctatctcagcccgctgctgcactgcttctatcagcatgacctggtgtttatgccgcacggtgaaaacctcatcatgctgctggagaacaacgtgccggtcagtgcatacatgaaggatatcggcgaagagatcgccgtgatgaatccggatgcggtgctgccggaaggcgtgcagcgtctggcggtggatgtgccggagaacctgaagctgctctcgatcttcaccgatgtgtttgactgcatcttccgctttatcagcgcgattctgcatcagtcaggaacgctgccggaggaagaattctggcaggcggtggcgcagtgcgtgaaggattaccagcaggcgcacccggagcatgccactaagttcgcgcgctatgacatgttcgcgccggagtttacccgctcctgtctgaaccgcctgcagctggcgaataaccagcagatgataaacctcgccgatcccgctgagaatctcaagttcgccggaacgctgaataacccgattgcccgctggcgataagcgttacaccgtcacgctgaaattatgcggtcaccctggccgctgtgtgccgttgataaaatataacccagcaggatggcagaaatttatttgccatcctgcaactgaaacaaagagattacatcccactgcatgcctgcaggtcgactctagaggatccccgggtaccgagctcgaattcagcttggctgttttggcggatgagagaagattttcagcctgatacagattaaatcagaacgcagaagcggtctgataaaacagaatttgcctggcggcagtagcgcggtggtcccacctgaccccatgccgaactcagaagtgaaacgccgtagcgccgatggtagtgtggggtctccccatgcgagagtagggaactgccaggcatcaaataaaacgaaaggctcagtcgaaagactgggcctttcgttttatctgttgtttgtcggtgaacgctctcctgagtaggacaaatccgccgggagcggatttgaacgttgcgaagcaacggcccggagggtggcgggcaggacgcccgccataaactgccaggcatcaaattaagcagaaggccatcctgacggatggcctttttgcgtttctacaaactcttttgtttatttttctaaatacattcaaatatgtatccgctcatgagacaataaccctgataaatgcttcaataatattgaaaaaggaagagtatgagtattcaacatttccgtgtcgcccttattcccttttttgcggcattttgccttcctgtttttgctcacccagaaacgctggtgaaagtaaaagatgctgaagatcagttgggtgcacgagtgggttacatcgaactggatctcaacagcggtaagatccttgagagttttcgccccgaagaacgttttccaatgatgagcacttttgcttcctcgctcactgactcgctgcgctcggtcgttcggctgcggcgagcggtatcagctcactcaaaggcggtaatacggttatccacagaatcaggggataacgcaggaaagaacatgtgagcaaaaggccagcaaaaggccaggaaccgtaaaaaggccgcgttgctggcgtttttccataggctccgcccccctgacgagcatcacaaaaatcgacgctcaagtcagaggtggcgaaacccgacaggactataaagataccaggcgtttccccctggaagctccctcgtgcgctctcctgttccgaccctgccgcttaccggatacctgtccgcctttctcccttcgggaagcgtggcgctttctcaatgctcacgctgtaggtatctcagttcggtgtaggtcgttcgctccaagctgggctgtgtgcacgaaccccccgttcagcccgaccgctgcgccttatccggtaactatcgtcttgagtccaacccggtaagacacgacttatcgccactggcagcagccactggtaacaggattagcagagcgaggtatgtaggcggtgctacagagttcttgaagtggtggcctaactacggctacactagaaggacagtatttggtatctgcgctctgctgaagccagttaccttcggaaaaagagttggtagctcttgatccggcaaacaaaccaccgctggtagcggtggtttttttgtttgcaagcagcagattacgcgcagaaaaaaaggatctcaagaagatcctttgatcttttctacggggtctgacgctcagtggaacgaaaactcacgttaagggattttggtcatgagattatcaaaaaggatcttcacctagatccttttggggtgggcgaagaactccagcatgagatccccgcgctggaggatcatccagccattcggggtcgttcactggttcccctttctgatttctggcatagaagaacccccgtgaactgtgtggttccgggggttgctgatttttgcgagacttctcgcgcaattccctagcttaggtgaaaacaccatgaaacactagggaaacacccatgaaacacccattagggcagtagggcggcttcttcgtctagggcttgcatttgggcggtgatctggtctttagcgtgtgaaagtgtgtcgtaggtggcgtgctcaatgcactcgaacgtcacgtcatttaccgggtcacggtgggcaaagagaactagtgggttagacattgttttcctcgttgtcggtggtggtgagcttttctagccgctcggtaaacgcggcgatcatgaactcttggaggttttcaccgttctgcatgcctgcgcgcttcatgtcctcacgtagtgccaaaggaacgcgtgcggtgaccacgacgggcttagcctttgcctgcgcttctagtgcttcgatggtggcttgtgcctgcgcttgctgcgcctgtagtgcctgttgagcttcttgtagttgctgttctagctgtgccttggttgccatgctttaagactctagtagctttcctgcgatatgtcatgcgcatgcgtagcaaacattgtcctgcaactcattcattatgtgcagtgctcctgttactagtcgtacatactcatatttacctagtctgcatgcagtgcatgcacatgcagtcatgtcgtgctaatgtgtaaaacatgtacatgcagattgctgggggtgcagggggcggagccaccctgtccatgcggggtgtggggcttgccccgccggtacagacagtgagcaccggggcacctagtcgcggataccccccctaggtatcggacacgtaaccctcccatgtcgatgcaaatctttaacattgagtacgggtaagctggcacgcatagccaagctaggcggccaccaaacaccactaaaaattaatagtccctagacaagacaaacccccgtgcgagctaccaactcatatgcacgggggccacataacccgaaggggtttcaattgacaaccatagcactagctaagacaacgggcacaacacccgcacaaactcgcactgcgcaaccccgcacaacatcgggtctaggtaacactgagtaacactgaaatagaagtgaacacctctaaggaaccgcaggtcaatgagggttctaaggtcactcgcgctagggcgtggcgtaggcaaaacgtcatgtacaagatcaccaatagtaaggctctggcggggtgccataggtggcgcagggacgaagctgttgcggtgtcctggtcgtctaacggtgcttcgcagtttgagggtctgcaaaactctcactctcgctgggggtcacctctggctgaattggaagtcatgggcgaacgccgcattgagctggctattgctactaagaatcacttggcggcgggtggcgcgctcatgatgtttgtgggcactgttcgacacaaccgctcacagtcatttgcgcaggttgaagcgggtattaagactgcgtactcttcgatggtgaaaacatctcagtggaagaaagaacgtgcacggtacggggtggagcacacctatagtgactatgaggtcacagactcttgggcgaacggttggcacttgcaccgcaacatgctgttgttcttggatcgtccactgtctgacgatgaactcaaggcgtttgaggattccatgttttcccgctggtctgctggtgtggttaaggccggtatggacgcgccactgcgtgagcacggggtcaaacttgatcaggtgtctacctggggtggagacgctgcgaaaatggcaacctacctcgctaagggcatgtctcaggaactgactggctccgctactaaaaccgcgtctaaggggtcgtacacgccgtttcagatgttggatatgttggccgatcaaagcgacgccggcgaggatatggacgctgttttggtggctcggtggcgtgagtatgaggttggttctaaaaacctgcgttcgtcctggtcacgtggggctaagcgtgctttgggcattgattacatagacgctgatgtacgtcgtgaaatggaagaagaactgtacaagctcgccggtctggaagcaccggaacgggtcgaatcaacccgcgttgctgttgctttggtgaagcccgatgattggaaactgattcagtctgatttcgcggttaggcagtacgttctcgattgcgtggataaggctaaggacgtggccgctgcgcaacgtgtcgctaatgaggtgctggcaagtctgggtgtggattccaccccgtgcatgatcgttatggatgatgtggacttggacgcggttctgcctactcatggggacgctactaagcgtgatctgaatgcggcggtgttcgcgggtaatgagcagactattcttcgcacccactaaaagcggcataaaccccgttcgatattttgtgcgatgaatttatggtcaatgtcgcgggggcaaactatgatgggtcttgttgttggcgtcccggaaaacgattccgaagcccaacctttcatagaaggcggcggtggaatcgaaatctcgtgatggcaggttgggcgtcgcttggtcggtcatttcgaagggcaccaataactgccttaaaaaaattacgccccgccctgccactcatcgcagtactgttgtaattcattaagcattctgccgacatggaagccatcacagacggcatgatgaacctgaatcgccagcggcatcagcaccttgtcgccttgcgtataatatttgcccatggtgaaaacgggggcgaagaagttgtccatattggccacgtttaaatcaaaactggtgaaactcacccagggattggctgagacgaaaaacatattctcaataaaccctttagggaaataggccaggttttcaccgtaacacgccacatcttgcgaatatatgtgtagaaactgccggaaatcgtcgtggtattcactccagagcgatgaaaacgtttcagtttgctcatggaaaacggtgtaacaagggtgaacactatcccatatcaccagctcaccgtctttcattgccatacggaactccggatgagcattcatcaggcgggcaagaatgtgaataaaggccggataaaacttgtgcttatttttctttacggtctttaaaaaggccgtaatatccagctgaacggtctggttataggtacattgagcaactgactgaaatgcctcaaaatgttctttacgatgccattgggatatatcaacggtggtatatccagtgatttttttctccattttagcttccttagctcctgaaaatctcgtcgaagctcggcggatttgtcctactcaagctgatccgacaaaatccacacattatcccaggtgtccggatcggtcaaatacgctgccagctcatagaccgtatccaaagcatccggggctgatccccggcgccagggtggtttttcttttcaccagtgagacgggcaacagctgattgcccttcaccgcctggccctgagagagttgcagcaagcggtccacgtggtttgccccagcaggcgaaaatcctgtttgatggtggttaacggcgggatataacatgagctgtcttcggtatcgtcgtatcccactaccgagatatccgcaccaacgcgcagcccggactcggtaatggcgcgcattgcgcccagcgccatctgatcgttggcaaccagcatcgcagtgggaacgatgccctcattcagcatttgcatggtttgttgaaaaccggacatggcactccagtcgccttcccgttccgctatcggctgaatttgattgcgagtgagatatttatgccagccagccagacgcagacgcgccgagacagaacttaatgggcccgctaacagcgcgatttgctggtgacccaatgcgaccagatgctccacgcccagtcgcgtaccgtcttcatgggagaaaataatactgttgatgggtgtctggtcagagacatcaagaaataacgccggaacattagtgcaggcagcttccacagcaatggcatcctggtcatccagcggatagttaatgatcagcccactgacgcgttgcgcgagaagattgtgcaccgccgctttacaggcttcgacgccgcttcgttctaccatcgacaccaccacgctggcacccagttgatcggcgcgagatttaatcgccgcgacaatttgcgacggcgcgtgcagggccagactggaggtggcaacgccaatcagcaacgactgtttgcccgccagttgttgtgccacgcggttgggaatgtaattcagctccgccatcgccgcttccactttttcccgcgttttcgcagaaacgtggctggcctggttcaccacgcgggaaacggtctgataagagacaccggcatactctgcgacatcgtataacgttactggtttcacattcaccaccctgaattgactctcttccgggcgctatcatgccataccgcgaaaggttttgcaccattcgatggtgtcaacgtaaatgccgcttcgccttcgcgcgcgaattgcaagctgatccgggcttatcgactgcacggtgcaccaatgcttctggcgtcaggcagccatcggaagctgtggtatggctgtgcaggtcgtaaatcactgcataattcgtgtcgctcaaggcgcactcccgttctggataatgttttttgcgccgacatcataacggttctggcaaatattctgaaatgagctgttgacaattaatcatcggctcgtataatgtgtggaattgtgagcggataacaatttcacacaggaaacagaatt

SEQ ID NO: 43 - DNA, 1344 bp, Corynebacterium xerosis
  source 1..1344: mol_type = genomic DNA
gtgcacgacgaggagatccacgacctcatcggcatcgggatcggccccttcgggctgggactggctgcgcttgccgacccgctgccggacgtcgacgccgtgttcctggaccaggccgacaggttctcctggcacccgggactgatgatcgagggcaccaccctccaggtccccttcctcgcggacctcgtgacgatggcggatcccacctcgccctactccttcctcgccttcctcaagcagaccggcaggctctaccccttctacatccgggaatccttctacccgctgcgcagcgagtacgacgagtactgccgctgggtcgccgcacagctggactgcctgcgctggcggcgtcgggtggtcgccgtggaggaggagggcgatcacctgctcgtcacggccgccgtgctcgatgcaaccggggctgtgatcggctgcgagcacctgcgcggccgccacgtggctctcgccgtcggcaccgcgccgcaccttccgccgcccctcgccgagctgatcggcccggccggtggtgctccagcagacgaggccccagcccccgtgctgcacagcgccgactacctccggcggaaggacgagctgctcgccgccggatccgtgacggtggtgggcagcgggcagtccgccgcagagatctatcgggacctgctccaggagggcggggccgacgggctgcgggtggactgggtgacccgttccccgcggttcttccccatggagtacacgaagctcaccctcgagatgacctcgccggagtacaccgacctgcaccgctcccttcccgaggggacgcgcgaccgcctggcgcgggagcagcgtgccctgcacaagggcatcagcgcggacctgatcgacgagatccacgagctcctctaccgcctctccgccgggggccgggaggtgccctcgagcctgctcacgggagccgccgtccgcgccgcccgcagggactccgggagcggacggatcgtcctggacctcgagcatccgctcacgggctcggtcgcggagcatcgcaccggcgccgtggtcgccgcgaccggctaccggccccgctccacggagctgctcgcaccgctcggggaccggatccgccacgacgacgcgggccggctcgacgtcacccgcgactacaccgtcgaccgcgaggagcggatccatgtgctgggcggcgaggagcacacccacggcgtcaccgcccctgacctcggcttcggcaccttgcgcgcctccgtgatcctcgccgcgctcaccgggcgggagccgtatccgatcgagcgtcgcatcgccttccagaccttcggcctccccgccgcccgctga

SEQ ID NO: 44 - DNA, 2430 bp, Corynebacterium xerosis
  source 1..2430: mol_type = genomic DNA
atgaacctgatgaacccgaacgacccgttggacctgagcgtcgaaccgctccgtcctgcggaccacaccggcctgctgcacagctggctgagcaccccgcgcgcccgtttctggggcatggtcgaccattcgcccgcacaggtgcgcgcctacctcgacgccgtcgccgcctccgagcacgagaacggccggatcggcctgcgggacggggtcccgctcgtctacgtcgagacctatgatcccgcccgactgctgcccgccggggtgctgcatccggaacccggcgatctcggcatgcacctcctcatcgcgccgccggacggcccgaccgagcacggcctcaccgccgcggtgctggcaggcgtcgtgcgctggtgcttcgagaaccgtggcgccgcccggatcgtcgtcgaacccgacgaacgcaacagcgcagtgctcgccaagaacgccgcagccggtttccgcgtgctgcgcaccgtcgaactgcccgagggatcgggcacgaagcgcgcggtgctgagcatctgcacccgggcggacttcgcggcttccccgctcggggaccggcggcagcgcaaggaactccggggcggcgccggagccgacgacgcgactgcggagcgcgcacatctcggcgctcccgtcgccccgacgtcccatctgcgcgccgacgtagccgagcgggcccaccggcacctgatcgccaaggccctcgccgagctcagccacgaacgagtcctcgcccccgaggcgctcggcgacgatcgcttcgccctggcagtccccggcaccgacgtacgctacgagttccgggcccgcgtgctcccgctcgagcactggctggtggacccggcctcgatccggcgcctcgaggacggtgccccgacggcgctggacgtgcagatcctcgtgttggagctgcaggatccgctcggcatcgccgacgatctgctctccacctacctcgaagagctcgcctccaccttcgccgcccgctgcgcgacgctggacgaggcccgtcgcggcgagcggccgtcggcagagggcctgctcacggcggacctcccggacgtcgaggccgccatgacggagggccacccgggcttcctcgcgaacaacgggcgcatcgggttctccctgcccgactaccgcgcctacgcaccggagcagggtcggcacacgcgcctgcagtgggtcgcggtgcacgccgcgcgcagcaccctgtccctcggcgaggggctggacgaggccgcgcatgcccgctggagcctctcgtccgaggagcgcgactccttcgcggaccgtctggccggccggggcctggacccgtcggactaccacctgctgcccctgcatccctggcaggcagagcatcgtctgcccatcaccttcgccccggacatcgcccgtggggacctcgtgcccctcggggcgggaggcgacgagatgcagccccagcagtccctgcgcaccttcctcaaccgcacgcgagcctgggcgccctatgtgaaggtcgccctcgcgatccagaacatggggttcctgcgcggcctctcgccgcagtacatgcgggacacccccacgatcaacgactggctcgccgcgctcgtggacagcgaccccgagttcgcgggcggcggcttccgcgtcctgcgggagcgggcagcactgggctacaccggggacgcctaccaccgcacgcccgccacgaatccccaccgcaagatgctcgcggcgctgtggcgggagagccccctgccgctgctcgagccgggggagcgggccttcacgatggcggcgctcctgcaccgcgatcacgacggcacggcgctcgtgagcacgatgatccgcacctcggagctgccggcggaggtctgggtcgcccagtacctgcgcgcctacctccgcccgctcgtccatgcgctgctcgcgcacgacgtggtggtcatgccgcacggcgagaacctcatcctgcgggttcaggagcagcaggtggtcggggcattcctcaaggacatcggggaggagatggcggtgctgggccaccgcccgctgcctgcggtgatggagcgggtacgggccgtggtccccggcgaggacaaggccctgtcgatcttcaccgacgtcttcgacggggtgctgcggcatctcgcggggatcctcgacgccgacggggtgcttcccgccgatcgcttctggcgggtcgtggcgggcatcctggacgagtacgaggcggaccatccggatctcgcgcgggggatctccggggacatcgacctgcgtgcgggcaccttcgcgcactcgtgcctgaaccgcctgcagctgcggaacaccctgcagatggtcgacctcggcgaccaggcctcgtcgctgctcttcgccggggacatggacaacccggtggctcgggcgtccgtccctgcctga

SEQ ID NO: 45 - protein, 447 aa, Corynebacterium xerosis
VHDEEIHDLIGIGIGPFGLGLAALADPLPDVDAVFLDQADRFSWHPGLMIEGTTLQVPFLADLVTMADPTSPYSFLAFLKQTGRLYPFYIRESFYPLRSEYDEYCRWVAAQLDCLRWRRRVVAVEEEGDHLLVTAAVLDATGAVIGCEHLRGRHVALAVGTAPHLPPPLAELIGPAGGAPADEAPAPVLHSADYLRRKDELLAAGSVTVVGSGQSAAEIYRDLLQEGGADGLRVDWVTRSPRFFPMEYTKLTLEMTSPEYTDLHRSLPEGTRDRLAREQRALHKGISADLIDEIHELLYRLSAGGREVPSSLLTGAAVRAARRDSGSGRIVLDLEHPLTGSVAEHRTGAVVAATGYRPRSTELLAPLGDRIRHDDAGRLDVTRDYTVDREERIHVLGGEEHTHGVTAPDLGFGTLRASVILAALTGREPYPIERRIAFQTFGLPAAR

SEQ ID NO: 46 - protein, 809 aa, Corynebacterium xerosis
MNLMNPNDPLDLSVEPLRPADHTGLLHSWLSTPRARFWGMVDHSPAQVRAYLDAVAASEHENGRIGLRDGVPLVYVETYDPARLLPAGVLHPEPGDLGMHLLIAPPDGPTEHGLTAAVLAGVVRWCFENRGAARIVVEPDERNSAVLAKNAAAGFRVLRTVELPEGSGTKRAVLSICTRADFAASPLGDRRQRKELRGGAGADDATAERAHLGAPVAPTSHLRADVAERAHRHLIAKALAELSHERVLAPEALGDDRFALAVPGTDVRYEFRARVLPLEHWLVDPASIRRLEDGAPTALDVQILVLELQDPLGIADDLLSTYLEELASTFAARCATLDEARRGERPSAEGLLTADLPDVEAAMTEGHPGFLANNGRIGFSLPDYRAYAPEQGRHTRLQWVAVHAARSTLSLGEGLDEAAHARWSLSSEERDSFADRLAGRGLDPSDYHLLPLHPWQAEHRLPITFAPDIARGDLVPLGAGGDEMQPQQSLRTFLNRTRAWAPYVKVALAIQNMGFLRGLSPQYMRDTPTINDWLAALVDSDPEFAGGGFRVLRERAALGYTGDAYHRTPATNPHRKMLAALWRESPLPLLEPGERAFTMAALLHRDHDGTALVSTMIRTSELPAEVWVAQYLRAYLRPLVHALLAHDVVVMPHGENLILRVQEQQVVGAFLKDIGEEMAVLGHRPLPAVMERVRAVVPGEDKALSIFTDVFDGVLRHLAGILDADGVLPADRFWRVVAGILDEYEADHPDLARGISGDIDLRAGTFAHSCLNRLQLRNTLQMVDLGDQASSLLFAGDMDNPVARASVPA

SEQ ID NO: 47 - DNA, 3922 bp, synthetic construct
  misc_feature 1..3922: note = Vector Construct
  source 1..3922: mol_type = other DNA
aagcttgcgaccggggtggaccgatgagcgcccgggccacgccggaggcggagagcccggaacccgcggtgcacgacgaggagatccacgacctcatcggcatcgggatcggccccttcgggctgggactggctgcgcttgccgacccgctgccggacgtcgacgccgtgttcctggaccaggccgacaggttctcctggcacccgggactgatgatcgagggcaccaccctccaggtccccttcctcgcggacctcgtgacgatggcggatcccacctcgccctactccttcctcgccttcctcaagcagaccggcaggctctaccccttctacatccgggaatccttctacccgctgcgcagcgagtacgacgagtactgccgctgggtcgccgcacagctggactgcctgcgctggcggcgtcgggtggtcgccgtggaggaggagggcgatcacctgctcgtcacggccgccgtgctcgatgcaaccggggctgtgatcggctgcgagcacctgcgcggccgccacgtggctctcgccgtcggcaccgcgccgcaccttccgccgcccctcgccgagctgatcggcccggccggtggtgctccagcagacgaggccccagcccccgtgctgcacagcgccgactacctccggcggaaggacgagctgctcgccgccggatccgtgacggtggtgggcagcgggcagtccgccgcagagatctatcgggacctgctccaggagggcggggccgacgggctgcgggtggactgggtgacccgttccccgcggttcttccccatggagtacacgaagctcaccctcgagatgacctcgccggagtacaccgacctgcaccgctcccttcccgaggggacgcgcgaccgcctggcgcgggagcagcgtgccctgcacaagggcatcagcgcggacctgatcgacgagatccacgagctcctctaccgcctctccgccgggggccgggaggtgccctcgagcctgctcacgggagccgccgtccgcgccgcccgcagggactccgggagcggacggatcgtcctggacctcgagcatccgctcacgggctcggtcgcggagcatcgcaccggcgccgtggtcgccgcgaccggctaccggccccgctccacggagctgctcgcaccgctcggggaccggatccgccacgacgacgcgggccggctcgacgtcacccgcgactacaccgtcgaccgcgaggagcggatccatgtgctgggcggcgaggagcacacccacggcgtcaccgcccctgacctcggcttcggcaccttgcgcgcctccgtgatcctcgccgcgctcaccgggcgggagccgtatccgatcgagcgtcgcatcgccttccagaccttcggcctccccgccgcccgctgaccaggagcgtccccatgaacctgatgaacccgaacgacccgttggacctgagcgtcgaaccgctccgtcctgcggaccacaccggcctgctgcacagctggctgagcaccccgcgcgcccgtttctggggcatggtcgaccattcgcccgcacaggtgcgcgcctacctcgacgccgtcgccgcctccgagcacgagaacggccggatcggcctgcgggacggggtcccgctcgtctacgtcgagacctatgatcccgcccgactgctgcccgccggggtgctgcatccggaacccggcgatctcggcatgcacctcctcatcgcgccgccggacggcccgaccgagcacggcctcaccgccgcggtgctggcaggcgtcgtgcgctggtgcttcgagaaccgtggcgccgcccggatcgtcgtcgaacccgacgaacgcaacagcgcagtgctcgccaagaacgccgcagccggtttccgcgtgctgcgcaccgtcgaactgcccgagggatcgggcacgaagcgcgcggtgctgagcatctgcacccgggcggacttcgcggcttccccgctcggggaccggcggcagcgcaaggaactccggggcggcgccggagccgacgacgcgactgcggagcgcgcacatctcggcgctcccgtcgccccgacgtcccatctgcgcgccgacgtagccgagcgggcccaccggcacctgatcgccaaggccctcgccgagctcagccacgaacgagtcctcgcccccgaggcgctcggcgacgatcgcttcgccctggcagtccccggcaccgacgtacgctacgagttccgggcccgcgtgctcccgctcgagcactggctggtggacccggcctcgatccggcgcctcgaggacggtgccccgacggcgctggacgtgcagatcctcgtgttggagctgcaggatccgctcggcatcgccgacgatctgctctccacctacctcgaagagctcgcctccaccttcgccgcccgctgcgcgacgctggacgaggcccgtcgcggcgagcggccgtcggcagagggcctgctcacggcggacctcccggacgtcgaggccgccatgacggagggccacccgggcttcctcgcgaacaacgggcgcatcgggttctccctgcccgactaccgcgcctacgcaccggagcagggtcggcacacgcgcctgcagtgggtcgcggtgcacgccgcgcgcagcaccctgtccctcggcgaggggctggacgaggccgcgcatgcccgctggagcctctcgtccgaggagcgcgactccttcgcggaccgtctggccggccggggcctggacccgtcggactaccacctgctgcccctgcatccctggcaggcagagcatcgtctgcccatcaccttcgccccggacatcgcccgtggggacctcgtgcccctcggggcgggaggcgacgagatgcagccccagcagtccctgcgcaccttcctcaaccgcacgcgagcctgggcgccctatgtgaaggtcgccctcgcgatccagaacatggggttcctgcgcggcctctcgccgcagtacatgcgggacacccccacgatcaacgactggctcgccgcgctcgtggacagcgaccccgagttcgcgggcggcggcttccgcgtcctgcgggagcgggcagcactgggctacaccggggacgcctaccaccgcacgcccgccacgaatccccaccgcaagatgctcgcggcgctgtggcgggagagccccctgccgctgctcgagccgggggagcgggccttcacgatggcggcgctcctgcaccgcgatcacgacggcacggcgctcgtgagcacgatgatccgcacctcggagctgccggcggaggtctgggtcgcccagtacctgcgcgcctacctccgcccgctcgtccatgcgctgctcgcgcacgacgtggtggtcatgccgcacggcgagaacctcatcctgcgggttcaggagcagcaggtggtcggggcattcctcaaggacatcggggaggagatggcggtgctgggccaccgcccgctgcctgcggtgatggagcgggtacgggccgtggtccccggcgaggacaaggccctgtcgatcttcaccgacgtcttcgacggggtgctgcggcatctcgcggggatcctcgacgccgacggggtgcttcccgccgatcgcttctggcgggtcgtggcgggcatcctggacgagtacgaggcggaccatccggatctcgcgcgggggatctccggggacatcgacctgcgtgcgggcaccttcgcgcactcgtgcctgaaccgcctgcagctgcggaacaccctgcagatggtcgacctcggcgaccaggcctcgtcgctgctcttcgccggggacatggacaacccggtggctcgggcgtccgtccctgcctgaggtccggggcggcggcgctcagctctccaggagccgcgccgccgccgcgagggtgtcgccaagctt

SEQ ID NO: 48 - DNA, 10507 bp, synthetic construct
  misc_feature 1..10507: note = Vector Sequence
  source 1..10507: mol_type = other DNA
aattagcgaccggggtggaccgatgagcgcccgggccacgccggaggcggagagcccggaacccgcggtgcacgacgaggagatccacgacctcatcggcatcgggatcggccccttcgggctgggactggctgcgcttgccgacccgctgccggacgtcgacgccgtgttcctggaccaggccgacaggttctcctggcacccgggactgatgatcgagggcaccaccctccaggtccccttcctcgcggacctcgtgacgatggcggatcccacctcgccctactccttcctcgccttcctcaagcagaccggcaggctctaccccttctacatccgggaatccttctacccgctgcgcagcgagtacgacgagtactgccgctgggtcgccgcacagctggactgcctgcgctggcggcgtcgggtggtcgccgtggaggaggagggcgatcacctgctcgtcacggccgccgtgctcgatgcaaccggggctgtgatcggctgcgagcacctgcgcggccgccacgtggctctcgccgtcggcaccgcgccgcaccttccgccgcccctcgccgagctgatcggcccggccggtggtgctccagcagacgaggccccagcccccgtgctgcacagcgccgactacctccggcggaaggacgagctgctcgccgccggatccgtgacggtggtgggcagcgggcagtccgccgcagagatctatcgggacctgctccaggagggcggggccgacgggctgcgggtggactgggtgacccgttccccgcggttcttccccatggagtacacgaagctcaccctcgagatgacctcgccggagtacaccgacctgcaccgctcccttcccgaggggacgcgcgaccgcctggcgcgggagcagcgtgccctgcacaagggcatcagcgcggacctgatcgacgagatccacgagctcctctaccgcctctccgccgggggccgggaggtgccctcgagcctgctcacgggagccgccgtccgcgccgcccgcagggactccgggagcggacggatcgtcctggacctcgagcatccgctcacgggctcggtcgcggagcatcgcaccggcgccgtggtcgccgcgaccggctaccggccccgctccacggagctgctcgcaccgctcggggaccggatccgccacgacgacgcgggccggctcgacgtcacccgcgactacaccgtcgaccgcgaggagcggatccatgtgctgggcggcgaggagcacacccacggcgtcaccgcccctgacctcggcttcggcaccttgcgcgcctccgtgatcctcgccgcgctcaccgggcgggagccgtatccgatcgagcgtcgcatcgccttccagaccttcggcctccccgccgcccgctgaccaggagcgtccccatgaacctgatgaacccgaacgacccgttggacctgagcgtcgaaccgctccgtcctgcggaccacaccggcctgctgcacagctggctgagcaccccgcgcgcccgtttctggggcatggtcgaccattcgcccgcacaggtgcgcgcctacctcgacgccgtcgccgcctccgagcacgagaacggccggatcggcctgcgggacggggtcccgctcgtctacgtcgagacctatgatcccgcccgactgctgcccgccggggtgctgcatccggaacccggcgatctcggcatgcacctcctcatcgcgccgccggacggcccgaccgagcacggcctcaccgccgcggtgctggcaggcgtcgtgcgctggtgcttcgagaaccgtggcgccgcccggatcgtcgtcgaacccgacgaacgcaacagcgcagtgctcgccaagaacgccgcagccggtttccgcgtgctgcgcaccgtcgaactgcccgagggatcgggcacgaagcgcgcggtgctgagcatctgcacccgggcggacttcgcggcttccccgctcggggaccggcggcagcgcaaggaactccggggcggcgccggagccgacgacgcgactgcggagcgcgcacatctcggcgctcccgtcgccccgacgtcccatctgcgcgccgacgtagccgagcgggcccaccggcacctgatcgccaaggccctcgccgagctcagccacgaacgagtcctcgcccccgaggcgctcggcgacgatcgcttcgccctggcagtccccggcaccgacgtacgctacgagttccgggcccgcgtgctcccgctcgagcactggctggtggacccggcctcgatccggcgcctcgaggacggtgccccgacggcgctggacgtgcagatcctcgtgttggagctgcaggatccgctcggcatcgccgacgatctgctctccacctacctcgaagagctcgcctccaccttcgccgcccgctgcgcgacgctggacgaggcccgtcgcggcgagcggccgtcggcagagggcctgctcacggcggacctcccggacgtcgaggccgccatgacggagggccacccgggcttcctcgcgaacaacgggcgcatcgggttctccctgcccgactaccgcgcctacgcaccggagcagggtcggcacacgcgcctgcagtgggtcgcggtgcacgccgcgcgcagcaccctgtccctcggcgaggggctggacgaggccgcgcatgcccgctggagcctctcgtccgaggagcgcgactccttcgcggaccgtctggccggccggggcctggacccgtcggactaccacctgctgcccctgcatccctggcaggcagagcatcgtctgcccatcaccttcgccccggacatcgcccgtggggacctcgtgcccctcggggcgggaggcgacgagatgcagccccagcagtccctgcgcaccttcctcaaccgcacgcgagcctgggcgccctatgtgaaggtcgccctcgcgatccagaacatggggttcctgcgcggcctctcgccgcagtacatgcgggacacccccacgatcaacgactggctcgccgcgctcgtggacagcgaccccgagttcgcgggcggcggcttccgcgtcctgcgggagcgggcagcactgggctacaccggggacgcctaccaccgcacgcccgccacgaatccccaccgcaagatgctcgcggcgctgtggcgggagagccccctgccgctgctcgagccgggggagcgggccttcacgatggcggcgctcctgcaccgcgatcacgacggcacggcgctcgtgagcacgatgatccgcacctcggagctgccggcggaggtctgggtcgcccagtacctgcgcgcctacctccgcccgctcgtccatgcgctgctcgcgcacgacgtggtggtcatgccgcacggcgagaacctcatcctgcgggttcaggagcagcaggtggtcggggcattcctcaaggacatcggggaggagatggcggtgctgggccaccgcccgctgcctgcggtgatggagcgggtacgggccgtggtccccggcgaggacaaggccctgtcgatcttcaccgacgtcttcgacggggtgctgcggcatctcgcggggatcctcgacgccgacggggtgcttcccgccgatcgcttctggcgggtcgtggcgggcatcctggacgagtacgaggcggaccatccggatctcgcgcgggggatctccggggacatcgacctgcgtgcgggcaccttcgcgcactcgtgcctgaaccgcctgcagctgcggaacaccctgcagatggtcgacctcggcgaccaggcctcgtcgctgctcttcgccggggacatggacaacccggtggctcgggcgtccgtccctgcctgaggtccggggcggcggcgctcagctctccaggagccgcgccgccgccgcgagggtgtcgcctgcatgcctgcaggtcgactctagaggatccccgggtaccgagctcgaattcagcttggctgttttggcggatgagagaagattttcagcctgatacagattaaatcagaacgcagaagcggtctgataaaacagaatttgcctggcggcagtagcgcggtggtcccacctgaccccatgccgaactcagaagtgaaacgccgtagcgccgatggtagtgtggggtctccccatgcgagagtagggaactgccaggcatcaaataaaacgaaaggctcagtcgaaagactgggcctttcgttttatctgttgtttgtcggtgaacgctctcctgagtaggacaaatccgccgggagcggatttgaacgttgcgaagcaacggcccggagggtggcgggcaggacgcccgccataaactgccaggcatcaaattaagcagaaggccatcctgacggatggcctttttgcgtttctacaaactcttttgtttatttttctaaatacattcaaatatgtatccgctcatgagacaataaccctgataaatgcttcaataatattgaaaaaggaagagtatgagtattcaacatttccgtgtcgcccttattcccttttttgcggcattttgccttcctgtttttgctcacccagaaacgctggtgaaagtaaaagatgctgaagatcagttgggtgcacgagtgggttacatcgaactggatctcaacagcggtaagatccttgagagttttcgccccgaagaacgttttccaatgatgagcacttttgcttcctcgctcactgactcgctgcgctcggtcgttcggctgcggcgagcggtatcagctcactcaaaggcggtaatacggttatccacagaatcaggggataacgcaggaaagaacatgtgagcaaaaggccagcaaaaggccaggaaccgtaaaaaggccgcgttgctggcgtttttccataggctccgcccccctgacgagcatcacaaaaatcgacgctcaagtcagaggtggcgaaacccgacaggactataaagataccaggcgtttccccctggaagctccctcgtgcgctctcctgttccgaccctgccgcttaccggatacctgtccgcctttctcccttcgggaagcgtggcgctttctcaatgctcacgctgtaggtatctcagttcggtgtaggtcgttcgctccaagctgggctgtgtgcacgaaccccccgttcagcccgaccgctgcgccttatccggtaactatcgtcttgagtccaacccggtaagacacgacttatcgccactggcagcagccactggtaacaggattagcagagcgaggtatgtaggcggtgctacagagttcttgaagtggtggcctaactacggctacactagaaggacagtatttggtatctgcgctctgctgaagccagttaccttcggaaaaagagttggtagctcttgatccggcaaacaaaccaccgctggtagcggtggtttttttgtttgcaagcagcagattacgcgcagaaaaaaaggatctcaagaagatcctttgatcttttctacggggtctgacgctcagtggaacgaaaactcacgttaagggattttggtcatgagattatcaaaaaggatcttcacctagatccttttggggtgggcgaagaactccagcatgagatccccgcgctggaggatcatccagccattcggggtcgttcactggttcccctttctgatttctggcatagaagaacccccgtgaactgtgtggttccgggggttgctgatttttgcgagacttctcgcgcaattccctagcttaggtgaaaacaccatgaaacactagggaaacacccatgaaacacccattagggcagtagggcggcttcttcgtctagggcttgcatttgggcggtgatctggtctttagcgtgtgaaagtgtgtcgtaggtggcgtgctcaatgcactcgaacgtcacgtcatttaccgggtcacggtgggcaaagagaactagtgggttagacattgttttcctcgttgtcggtggtggtgagcttttctagccgctcggtaaacgcggcgatcatgaactcttggaggttttcaccgttctgcatgcctgcgcgcttcatgtcctcacgtagtgccaaaggaacgcgtgcggtgaccacgacgggcttagcctttgcctgcgcttctagtgcttcgatggtggcttgtgcctgcgcttgctgcgcctgtagtgcctgttgagcttcttgtagttgctgttctagctgtgccttggttgccatgctttaagactctagtagctttcctgcgatatgtcatgcgcatgcgtagcaaacattgtcctgcaactcattcattatgtgcagtgctcctgttactagtcgtacatactcatatttacctagtctgcatgcagtgcatgcacatgcagtcatgtcgtgctaatgtgtaaaacatgtacatgcagattgctgggggtgcagggggcggagccaccctgtccatgcggggtgtggggcttgccccgccggtacagacagtgagcaccggggcacctagtcgcggataccccccctaggtatcggacacgtaaccctcccatgtcgatgcaaatctttaacattgagtacgggtaagctggcacgcatagccaagctaggcggccaccaaacaccactaaaaattaatagtccctagacaagacaaacccccgtgcgagctaccaactcatatgcacgggggccacataacccgaaggggtttcaattgacaaccatagcactagctaagacaacgggcacaacacccgcacaaactcgcactgcgcaaccccgcacaacatcgggtctaggtaacactgagtaacactgaaatagaagtgaacacctctaaggaaccgcaggtcaatgagggttctaaggtcactcgcgctagggcgtggcgtaggcaaaacgtcatgtacaagatcaccaatagtaaggctctggcggggtgccataggtggcgcagggacgaagctgttgcggtgtcctggtcgtctaacggtgcttcgcagtttgagggtctgcaaaactctcactctcgctgggggtcacctctggctgaattggaagtcatgggcgaacgccgcattgagctggctattgctactaagaatcacttggcggcgggtggcgcgctcatgatgtttgtgggcactgttcgacacaaccgctcacagtcatttgcgcaggttgaagcgggtattaagactgcgtactcttcgatggtgaaaacatctcagtggaagaaagaacgtgcacggtacggggtggagcacacctatagtgactatgaggtcacagactcttgggcgaacggttggcacttgcaccgcaacatgctgttgttcttggatcgtccactgtctgacgatgaactcaaggcgtttgaggattccatgttttcccgctggtctgctggtgtggttaaggccggtatggacgcgccactgcgtgagcacggggtcaaacttgatcaggtgtctacctggggtggagacgctgcgaaaatggcaacctacctcgctaagggcatgtctcaggaactgactggctccgctactaaaaccgcgtctaaggggtcgtacacgccgtttcagatgttggatatgttggccgatcaaagcgacgccggcgaggatatggacgctgttttggtggctcggtggcgtgagtatgaggttggttctaaaaacctgcgttcgtcctggtcacgtggggctaagcgtgctttgggcattgattacatagacgctgatgtacgtcgtgaaatggaagaagaactgtacaagctcgccggtctggaagcaccggaacgggtcgaatcaacccgcgttgctgttgctttggtgaagcccgatgattggaaactgattcagtctgatttcgcggttaggcagtacgttctcgattgcgtggataaggctaaggacgtggccgctgcgcaacgtgtcgctaatgaggtgctggcaagtctgggtgtggattccaccccgtgcatgatcgttatggatgatgtggacttggacgcggttctgcctactcatggggacgctactaagcgtgatctgaatgcggcggtgttcgcgggtaatgagcagactattcttcgcacccactaaaagcggcataaaccccgttcgatattttgtgcgatgaatttatggtcaatgtcgcgggggcaaactatgatgggtcttgttgttggcgtcccggaaaacgattccgaagcccaacctttcatagaaggcggcggtggaatcgaaatctcgtgatggcaggttgggcgtcgcttggtcggtcatttcgaagggcaccaataactgccttaaaaaaattacgccccgccctgccactcatcgcagtactgttgtaattcattaagcattctgccgacatggaagccatcacagacggcatgatgaacctgaatcgccagcggcatcagcaccttgtcgccttgcgtataatatttgcccatggtgaaaacgggggcgaagaagttgtccatattggccacgtttaaatcaaaactggtgaaactcacccagggattggctgagacgaaaaacatattctcaataaaccctttagggaaataggccaggttttcaccgtaacacgccacatcttgcgaatatatgtgtagaaactgccggaaatcgtcgtggtattcactccagagcgatgaaaacgtttcagtttgctcatggaaaacggtgtaacaagggtgaacactatcccatatcaccagctcaccgtctttcattgccatacggaactccggatgagcattcatcaggcgggcaagaatgtgaataaaggccggataaaacttgtgcttatttttctttacggtctttaaaaaggccgtaatatccagctgaacggtctggttataggtacattgagcaactgactgaaatgcctcaaaatgttctttacgatgccattgggatatatcaacggtggtatatccagtgatttttttctccattttagcttccttagctcctgaaaatctcgtcgaagctcggcggatttgtcctactcaagctgatccgacaaaatccacacattatcccaggtgtccggatcggtcaaatacgctgccagctcatagaccgtatccaaagcatccggggctgatccccggcgccagggtggtttttcttttcaccagtgagacgggcaacagctgattgcccttcaccgcctggccctgagagagttgcagcaagcggtccacgtggtttgccccagcaggcgaaaatcctgtttgatggtggttaacggcgggatataacatgagctgtcttcggtatcgtcgtatcccactaccgagatatccgcaccaacgcgcagcccggactcggtaatggcgcgcattgcgcccagcgccatctgatcgttggcaaccagcatcgcagtgggaacgatgccctcattcagcatttgcatggtttgttgaaaaccggacatggcactccagtcgccttcccgttccgctatcggctgaatttgattgcgagtgagatatttatgccagccagccagacgcagacgcgccgagacagaacttaatgggcccgctaacagcgcgatttgctggtgacccaatgcgaccagatgctccacgcccagtcgcgtaccgtcttcatgggagaaaataatactgttgatgggtgtctggtcagagacatcaagaaataacgccggaacattagtgcaggcagcttccacagcaatggcatcctggtcatccagcggatagttaatgatcagcccactgacgcgttgcgcgagaagattgtgcaccgccgctttacaggcttcgacgccgcttcgttctaccatcgacaccaccacgctggcacccagttgatcggcgcgagatttaatcgccgcgacaatttgcgacggcgcgtgcagggccagactggaggtggcaacgccaatcagcaacgactgtttgcccgccagttgttgtgccacgcggttgggaatgtaattcagctccgccatcgccgcttccactttttcccgcgttttcgcagaaacgtggctggcctggttcaccacgcgggaaacggtctgataagagacaccggcatactctgcgacatcgtataacgttactggtttcacattcaccaccctgaattgactctcttccgggcgctatcatgccataccgcgaaaggttttgcaccattcgatggtgtcaacgtaaatgccgcttcgccttcgcgcgcgaattgcaagctgatccgggcttatcgactgcacggtgcaccaatgcttctggcgtcaggcagccatcggaagctgtggtatggctgtgcaggtcgtaaatcactgcataattcgtgtcgctcaaggcgcactcccgttctggataatgttttttgcgccgacatcataacggttctggcaaatattctgaaatgagctgttgacaattaatcatcggctcgtataatgtgtggaattgtgagcggataacaatttcacacaggaaacagaatt

SEQ ID NO: 49 - DNA, 2142 bp, Escherichia coli
  source 1..2142: mol_type = genomic DNA
atgaacatcattgccattatgggaccgcatggcgtcttttataaagatgagcccatcaaagaactggagtcggcgctggtggcgcaaggctttcagattatctggccacaaaacagcgttgatttgctgaaatttatcgagcataaccctcgaatttgcggcgtgatttttgactgggatgagtacagtctcgatttatgtagcgatatcaatcagcttaatgaatatctcccgctttatgccttcatcaacacccactcgacgatggatgtcagcgtgcaggatatgcggatggcgctctggttttttgaatatgcgctggggcaggcggaagatatcgccattcgtatgcgtcagtacaccgacgaatatcttgataacattacaccgccgttcacgaaagccttgtttacctacgtcaaagagcggaagtacaccttttgtacgccggggcatatgggcggcaccgcatatcaaaaaagcccggttggctgtctgttttatgattttttcggcgggaatactcttaaggctgatgtctctatttcggtcaccgagcttggttcgttgctcgaccacaccgggccacacctggaagcggaagagtacatcgcgcggacttttggcgcggaacagagttatatcgttaccaacggaacatcgacgtcgaacaaaattgtgggtatgtacgccgcgccatccggcagtacgctgttgatcgaccgcaattgtcataaatcgctggcgcatctgttgatgatgaacgatgtagtgccagtctggctgaaaccgacgcgtaatgcgttggggattcttggtgggatcccgcgccgtgaatttactcgcgacagcatcgaagagaaagtcgctgctaccacgcaagcacaatggccggttcatgcggtgatcaccaactccacctatgatggcttgctctacaacaccgactggatcaaacagacgctggatgtcccgtcgattcacttcgattctgcctgggtgccgtacacccattttcatccgatctaccagggtaaaagtggtatgagcggcgagcgtgttgcgggaaaagtgatcttcgaaacgcaatcgacccacaaaatgctggcggcgttatcgcaggcttcgctgatccacattaaaggcgagtatgacgaagaggcctttaacgaagcctttatgatgcataccaccacctcgcccagttatcccattgttgcttcggttgagacggcggcggcgatgctgcgtggtaatccgggcaaacggctgattaaccgttcagtagaacgagctctgcattttcgcaaagaggtccagcggctgcgggaagagtctgacggttggtttttcgatatctggcaaccgccgcaggtggatgaagccgaatgctggcccgttgcgcctggcgaacagtggcacggctttaacgatgcggatgccgatcatatgtttctcgatccggttaaagtcactattttgacaccggggatggacgagcagggcaatatgagcgaggaggggatcccggcggcgctggtagcaaaattcctcgacgaacgtgggatcgtagtagagaaaaccggcccttataacctgctgtttctctttagtattggcatcgataaaaccaaagcaatgggattattgcgtgggttgacggaattcaaacgctcttacgatctcaacctgcggatcaaaaatatgctacccgatctctatgcagaagatcccgatttctaccgcaatatgcgtattcaggatctggcacaagggatccataagctgattcgtaaacacgatcttcccggtttgatgttgcgggcattcgatactttgccggagatgatcatgacgccacatcaggcatggcaacgacaaattaaaggcgaagtagaaaccattgcgctggaacaactggtcggtagagtatcggcaaatatgatcctgccttatccaccgggcgtaccgctgttgatgcctggagaaatgctgaccaaagagagccgcacagtactcgattttctactgatgctttgttccgtcgggcaacattaccccggttttgaaacggatattcacggcgcgaaacaggacgaagacggcgtttaccgcgtacgagtcctaaaaatggcgggataa

SEQ ID NO: 50 - protein, 713 aa, Escherichia coli
MNIIAIMGPHGVFYKDEPIKELESALVAQGFQIIWPQNSVDLLKFIEHNPRICGVIFDWDEYSLDLCSDINQLNEYLPLYAFINTHSTMDVSVQDMRMALWFFEYALGQAEDIAIRMRQYTDEYLDNITPPFTKALFTYVKERKYTFCTPGHMGGTAYQKSPVGCLFYDFFGGNTLKADVSISVTELGSLLDHTGPHLEAEEYIARTFGAEQSYIVTNGTSTSNKIVGMYAAPSGSTLLIDRNCHKSLAHLLMMNDVVPVWLKPTRNALGILGGIPRREFTRDSIEEKVAATTQAQWPVHAVITNSTYDGLLYNTDWIKQTLDVPSIHFDSAWVPYTHFHPIYQGKSGMSGERVAGKVIFETQSTHKMLAALSQASLIHIKGEYDEEAFNEAFMMHTTTSPSYPIVASVETAAAMLRGNPGKRLINRSVERALHFRKEVQRLREESDGWFFDIWQPPQVDEAECWPVAPGEQWHGFNDADADHMFLDPVKVTILTPGMDEQGNMSEEGIPAALVAKFLDERGIVVEKTGPYNLLFLFSIGIDKTKAMGLLRGLTEFKRSYDLNLRIKNMLPDLYAEDPDFYRNMRIQDLAQGIHKLIRKHDLPGLMLRAFDTLPEMIMTPHQAWQRQIKGEVETIALEQLVGRVSANMILPYPPGVPLLMPGEMLTKESRTVLDFLLMLCSVGQHYPGFETDIHGAKQDEDGVYRVRVLKMAG

SEQ ID NO: 51 - DNA, 2433 bp, synthetic construct
  misc_feature 1..2433: note = Vector Construct
  source 1..2433: mol_type = other DNA
gcaagcaggatgtcaggaggaccggtgttttagcgtgtcagtaggcgcgtagggtaagtggggtagcggcttgttagatatcttgaaatcggctttcaacagcattgatttcgatgtatttagctggccgttaccctgcgaatgtccacagggtagctggtagtttgaaaatcaacgccgttgcccttaggattcagtaactggcaaggaaggattttccaggaggaacacatgaacatcatcgctatcatgggccctcacggtgttttctacaaggatgagccaatcaaggagctggaatccgcactagttgcacagggctttcagatcatctggccccagaactccgttgaccttctcaaattcatcgagcacaatcctcgcatttgtggtgtgatttttgactgggacgagtactctcttgatttatgctccgacatcaaccagctcaacgagtacctgccactctacgcattcatcaacactcactccaccatggacgtttccgtgcaggacatgcgtatggcactctggttctttgaatacgctctgggccaggctgaggacatcgcgatccgcatgcgtcagtacaccgacgagtacctggacaacatcacccctccattcaccaaggctctcttcacctacgtaaaggaacgcaagtacactttctgcaccccaggccacatgggcggcaccgcctaccagaagtccccagtcggatgcctcttctacgacttcttcggcggtaacactcttaaggcagatgtctccatttccgtcaccgagttgggctctctgctggaccacaccggccctcacctggaggcagaagagtacatcgctcgtaccttcggtgctgaacagtcctacatcgtcaccaacggtacttccaccagcaacaagatcgttggtatgtacgcagctccttctggctccaccctgttgatcgaccgcaactgtcacaagtccctcgcgcatcttcttatgatgaacgatgtggtccctgtatggctgaagccaacccgtaacgctctgggcatccttggcggtatcccccgtcgcgagttcacccgtgattccatcgaggaaaaggttgcagccactacccaggcacagtggcctgtccacgctgtcattaccaactcgacctacgacggcctgctctacaacaccgattggatcaagcagaccctagatgttccttccattcacttcgacagcgcatgggttccttacactcacttccacccaatctaccagggtaagtccggaatgtccggcgagcgtgtcgctggcaaggttatcttcgaaacccaatcaacccacaagatgctggctgctctctcccaggcttctctgatccacatcaagggcgagtacgacgaggaagctttcaacgaggctttcatgatgcacaccaccacctccccatcctaccctatcgtcgcgtccgtcgagactgctgccgcaatgcttcgcggtaacccaggtaagcgcctcatcaaccgttccgttgagcgcgctcttcacttccgtaaggaagtgcagcgcctgcgtgaggaatctgacggttggttcttcgacatttggcagccacctcaggttgatgaggccgagtgctggccagttgctccaggtgaacagtggcacggattcaacgatgcagatgctgaccacatgtttttggacccggtcaaggtcaccattcttactcctggtatggatgagcagggcaacatgtctgaggagggtatcccagctgctctggttgcaaagttcctcgacgaacgtggcatcgttgttgagaagaccggaccatacaacctgctgttcctgttcagcatcggcatcgacaaaaccaaggcaatgggtctgctgcgcggccttaccgagttcaagcgctcctacgacctgaaccttcgcatcaagaatatgctgccggacctgtacgctgaagatcctgatttctaccgcaacatgcgcatccaggacctcgcacagggcatccacaagctcattcgcaagcacgacctgccaggccttatgctccgtgcattcgataccctcccagagatgatcatgacccctcaccaggcttggcagcgccagatcaagggcgaggtggaaaccatcgcactggagcagctggttggtcgtgtctccgccaacatgatcctgccatatccacctggcgttccgctgctgatgccaggcgagatgctcaccaaggagtcccgcaccgtattggacttccttctcatgttgtgctctgttggccagcactacccaggcttcgagaccgacatccacggcgctaagcaagatgaagacggcgtttaccgcgttcgcgtccttaagatggcaggctaacttgccagagcggcttccgggcgagtaacgtgcggatccgcctccacagttttcccggtt

SEQ ID NO: 52 - DNA, 1046 bp, synthetic construct
  misc_feature 1..1046: note = Vector Construct
  source 1..1046: mol_type = other DNA
acagctatgacatgattacggacggcgaattcctcctcgttgccacctccggcggctacggcaagcgcaccccacttgaggattactccacccagggccgtggtggcctcggcgtggtgaccttcaagtacaccccgaagcgcggtcgcctcgtcagcgccatcgcagttgaggaagatgacgagatcttcgccatcacctccgccggcggcgttgttcgcaccgaagtcaagcagatccgaccatcctcccgtgcaacaatgggtgttcgactggtcaacttggaagaaggtgtagaactgcttgccatcgacaagaacgtcgaagaccagggcgaagcatccgcagaagcagtagcaaagggtgcagtcgaaggaccagcatccaagactgctgccgaagaaaccgactccgttgacaacggatccgacgaaaacggcgaggaataatttatggcatcccgagaagtatccatcacccgaatctcaccactagcaaccttccgagttgcactggcaatgtccatcatcggactcgtggcgtggatcatctgcgtaaccgtcctctatttcggacttaacgtggctggcgtctggcagaacttcaacgatgtcatcggcggtgttggtgcagaacaaaccatcaccttcgggctcgtcctgagcatttccgcacttctgggagctatcggagcgattaccgtcgctgtgcttgcaccattgtgtgcaatcatctacaactcgattgttgacctcttcggtggactgcagattcaactgcaagaagaagtagactaacctctgaaacacaaacccctagacactgctaaatatagcctttgaacaggggatttgttgtattgttaacttgaaggtagagtcttatctcgttcctagaggggcctatagctcagtcggttagagcgcatcgctgataacgatgaggtcgcaagttcgattcttgctaggcccaccaggaacaaaaaaggggcattagctcagttggtagagcacctgctttgcaagcaggatgtcaggaggcgcgcc

SEQ ID NO: 53 - DNA, 1028 bp, synthetic construct
  misc_feature 1..1028: note = Vector Construct
  source 1..1028: mol_type = other DNA
gcaggatgtcaggaggcgcgcctccacagttttcccggttcatcttgtttaaggtgggccgggatttttgttttttagtgtttctgggatacctcggtggcactccggcggcactctgggtcattggaaagctgtgtgtactttcgacaacaagatttgggcaaaatggtggtcaaaatcaggaaatcttgttgtcgaaagtacaactgggtcttcggttctatccgaggtgggtgagtagggtgcctgcaagtgcgatactggtgacaagtgtcgtggatccgaaagccagaatgaaaggcttgaccccaacatggatcaggttctggatttttacgccacacccgagaccaaacattgctgcagagagcaaggctgtctgtaggaaacctccagccgcaattacctcgtctgggagcgcaacagtggagcgcaaaactaccatcgccaagaatccaaggataaataggggaacgaccggtggtctctttccatcgggggacgtgtaaccctggcggcgctggcgaaaacttaaaatggcagcaatgggtgcaagtaggagtactcgggcgagtttcaccacaactgcaacacctaatgctccaccaccaatgactcctccagctgctactacttgggcgatttcatggatggatccgcctgcccacatcccaccgatttcaggggataaccccaagactttggttgcgaatgggataaaaggaatcatcagcgttccgaaaataacaacaagtgcaaccgcagtaacgacctcttcttcttcggaatcagttactccttcaacacctgccacggccgcagcgccacaaatagaaaagccacaagcaatcaacagaacttgggttggtttcattctgagcaggtgtcccatgaggatggtcccaaaaataccaccggcaacgatgcacacaatcaccgccagcatggggaaaccaagtgacaaaatatctgagaaaactaactgcagaccaaggaagacgatgaattcgagctcggtacccggggat

SEQ ID NO: 54 - DNA, 7727 bp, synthetic construct
  misc_feature 1..7727: note = Vector Construct
  source 1..7727: mol_type = other DNA
cgataagctagcttcacgctgccgcaagcactcagggcgcaagggctgctaaaggaagcggaacacgtagaaagccagtccgcagaaacggtgctgaccccggatgaatgtcagctactgggctatctggacaagggaaaacgcaagcgcaaagagaaagcaggtagcttgcagtgggcttacatggcgatagctagactgggcggttttatggacagcaagcgaaccggaattgccagctggggcgccctctggtaaggttgggaagccctgcaaagtaaactggatggctttcttgccgccaaggatctgatggcgcaggggatcaagatctgatcaagagacaggatgaggatcgtttcgcatgattgaacaagatggattgcacgcaggttctccggccgcttgggtggagaggctattcggctatgactgggcacaacagacaatcggctgctctgatgccgccgtgttccggctgtcagcgcaggggcgcccggttctttttgtcaagaccgacctgtccggtgccctgaatgaactccaagacgaggcagcgcggctatcgtggctggccacgacgggcgttccttgcgcagctgtgctcgacgttgtcactgaagcgggaagggactggctgctattgggcgaagtgccggggcaggatctcctgtcatctcaccttgctcctgccgagaaagtatccatcatggctgatgcaatgcggcggctgcatacgcttgatccggctacctgcccattcgaccaccaagcgaaacatcgcatcgagcgagcacgtactcggatggaagccggtcttgtcgatcaggatgatctggacgaagagcatcaggggctcgcgccagccgaactgttcgccaggctcaaggcgcggatgcccgacggcgaggatctcgtcgtgacccatggcgatgcctgcttgccgaatatcatggtggaaaatggccgcttttctggattcatcgactgtggccggctgggtgtggcggaccgctatcaggacatagcgttggctacccgtgatattgctgaagagcttggcggcgaatgggctgaccgcttcctcgtgctttacggtatcgccgctcccgattcgcagcgcatcgccttctatcgccttcttgacgagttcttctgagcgggactctggggttcgctagaggatcgatcctttttaacccatcacatatacctgccgttcactattatttagtgaaatgagatattatgatattttctgaattgtgattaaaaaggcaactttatgcccatgcaacagaaactataaaaaatacagagaatgaaaagaaacagatagattttttagttctttaggcccgtagtctgcaaatccttttatgattttctatcaaacaaaagaggaaaatagaccagttgcaatccaaacgagagtctaatagaatgaggtcgaaaagtaaatcgcgcgggtttgttactgataaagcaggcaagacctaaaatgtgtaaagggcaaagtgtatactttggcgtcaccccttacatattttaggtctttttttattgtgcgtaactaacttgccatcttcaaacaggagggctggaagaagcagaccgctaacacagtacataaaaaaggagacatgaacgatgaacatcaaaaagtttgcaaaacaagcaacagtattaacctttactaccgcactgctggcaggaggcgcaactcaagcgtttgcgaaagaaacgaaccaaaagccatataaggaaacatacggcatttcccatattacacgccatgatatgctgcaaatccctgaacagcaaaaaaatgaaaaatatcaagtttctgaatttgattcgtccacaattaaaaatatctcttctgcaaaaggcctggacgtttgggacagctggccattacaaaacgctgacggcactgtcgcaaactatcacggctaccacatcgtctttgcattagccggagatcctaaaaatgcggatgacacatcgatttacatgttctatcaaaaagtcggcgaaacttctattgacagctggaaaaacgctggccgcgtctttaaagacagcgacaaattcgatgcaaatgattctatcctaaaagaccaaacacaagaatggtcaggttcagccacatttacatctgacggaaaaatccgtttattctacactgatttctccggtaaacattacggcaaacaaacactgacaactgcacaagttaacgtatcagcatcagacagctctttgaacatcaacggtgtagaggattataaatcaatctttgacggtgacggaaaaacgtatcaaaatgtacagcagttcatcgatgaaggcaactacagctcaggcgacaaccatacgctgagagatcctcactacgtagaagataaaggccacaaatacttagtatttgaagcaaacactggaactgaagatggctaccaaggcgaagaatctttatttaacaaagcatactatggcaaaagcacatcattcttccgtcaagaaagtcaaaaacttctgcaaagcgataaaaaacgcacggctgagttagcaaacggcgctctcggtatgattgagctaaacgatgattacacactgaaaaaagtgatgaaaccgctgattgcatctaacacagtaacagatgaaattgaacgcgcgaacgtctttaaaatgaacggcaaatggtacctgttcactgactcccgcggatcaaaaatgacgattgacggcattacgtctaacgatatttacatgcttggttatgtttctaattctttaactggcccatacaagccgctgaacaaaactggccttgtgttaaaaatggatcttgatcctaacgatgtaacctttacttactcacacttcgctgtacctcaagcgaaaggaaacaatgtcgtgattacaagctatatgacaaacagaggattctacgcagacaaacaatcaacgtttgcgccgagcttcctgctgaacatcaaaggcaagaaaacatctgttgtcaaagacagcatccttgaacaaggacaattaacagttaacaaataaaaacgcaaaagaaaatgccgatgggtaccgagcgaaatgaccgaccaagcgacgcccaacctgccatcacgagatttcgattccaccgccgccttctatgaaaggttgggcttcggaatcgttttccgggacgccctcgcggacgtgctcatagtccacgacgcccgtgattttgtagccctggccgacggccagcaggtaggccgacaggctcatgccggccgccgccgccttttcctcaatcgctcttcgttcgtctggaaggcagtacaccttgataggtgggctgcccttcctggttggcttggtttcatcagccatccgcttgccctcatctgttacgccggcggtagccggccagcctcgcagagcaggattcccgttgagcaccgccaggtgcgaataagggacagtgaagaaggaacacccgctcgcgggtgggcctacttcacctatcctgcccggctgacgccgttggatacaccaaggaaagtctacacgaaccctttggcaaaatcctgtatatcgtgcgaaaaaggatggatataccgaaaaaatcgctataatgaccccgaagcagggttatgcagcggaaaagcgctgcttccctgctgttttgtggaatatctaccgactggaaacaggcaaatgcaggaaattactgaactgaggggacaggcgagagacgatgccaaagagctcctgaaaatctcgataactcaaaaaatacgcccggtagtgatcttatttcattatggtgaaagttggaacctcttacgtgccgatcaacgtctcattttcgccaaaagttggcccagggcttcccggtatcaacagggacaccaggatttatttattctgcgaagtgatcttccgtcacaggtatttattcggcgcaaagtgcgtcgggtgatgctgccaacttactgatttagtgtatgatggtgtttttgaggtgctccagtggcttctgtttctatcagctcctgaaaatctcgataactcaaaaaatacgcccggtagtgatcttatttcattatggtgaaagttggaacctcttacgtgccgatcaacgtctcattttcgccaaaagttggcccagggcttcccggtatcaacagggacaccaggatttatttattctgcgaagtgatcttccgtcacaggtatttattcggcgcaaagtgcgtcgggtgatgctgccaacttactgatttagtgtatgatggtgtttttgaggtgctccagtggcttctgtttctatcagggctggatgatcctccagcgcggggatctcatgctggagttcttcgcccaccccaaaaggatctaggtgaagatcctttttgataatctcatgaccaaaatcccttaacgtgagttttcgttccactgagcgtcagaccccgtagaaaagatcaaaggatcttcttgagatcctttttttctgcgcgtaatctgctgcttgcaaacaaaaaaaccaccgctaccagcggtggtttgtttgccggatcaagagctaccaactctttttccgaaggtaactggcttcagcagagcgcagataccaaatactgttcttctagtgtagccgtagttaggccaccacttcaagaactctgtagcaccgcctacatacctcgctctgctaatcctgttaccagtggctgctgccagtggcgataagtcgtgtcttaccgggttggactcaagacgatagttaccggataaggcgcagcggtcgggctgaacggggggttcgtgcacacagcccagcttggagcgaacgacctacaccgaactgagatacctacagcgtgagctatgagaaagcgccacgcttcccgaagggagaaaggcggacaggtatccggtaagcggcagggtcggaacaggagagcgcacgagggagcttccagggggaaacgcctggtatctttatagtcctgtcgggtttcgccacctctgacttgagcgtcgatttttgtgatgctcgtcaggggggcggagcctatggaaaaacgccagcaacgcggcctttttacggttcctggccttttgctggccttttgctcacatgttctttcctgcgttatcccctgattctgtggataaccgtattaccgcctttgagtgagctgataccgctcgccgcagccgaacgaccgagcgcagcgagtcagtgagcgaggaagcggaagagcgcccaatacgcaaaccgcctctccccgcgcgttggccgattcattaatgcagctggcacgacaggtttcccgactggaaagcgggcagtgagcgcaacgcaattaatgtgagttagctcactcattaggcaccccaggctttacactttatgcttccggctcgtatgttgtgtggaattgtgagcggataacaatttcacacaggaaacagctatgacatgattacggacggcgaattcctcctcgttgccacctccggcggctacggcaagcgcaccccacttgaggattactccacccagggccgtggtggcctcggcgtggtgaccttcaagtacaccccgaagcgcggtcgcctcgtcagcgccatcgcagttgaggaagatgacgagatcttcgccatcacctccgccggcggcgttgttcgcaccgaagtcaagcagatccgaccatcctcccgtgcaacaatgggtgttcgactggtcaacttggaagaaggtgtagaactgcttgccatcgacaagaacgtcgaagaccagggcgaagcatccgcagaagcagtagcaaagggtgcagtcgaaggaccagcatccaagactgctgccgaagaaaccgactccgttgacaacggatccgacgaaaacggcgaggaataatttatggcatcccgagaagtatccatcacccgaatctcaccactagcaaccttccgagttgcactggcaatgtccatcatcggactcgtggcgtggatcatctgcgtaaccgtcctctatttcggacttaacgtggctggcgtctggcagaacttcaacgatgtcatcggcggtgttggtgcagaacaaaccatcaccttcgggctcgtcctgagcatttccgcacttctgggagctatcggagcgattaccgtcgctgtgcttgcaccattgtgtgcaatcatctacaactcgattgttgacctcttcggtggactgcagattcaactgcaagaagaagtagactaacctctgaaacacaaacccctagacactgctaaatatagcctttgaacaggggatttgttgtattgttaacttgaaggtagagtcttatctcgttcctagaggggcctatagctcagtcggttagagcgcatcgctgataacgatgaggtcgcaagttcgattcttgctaggcccaccaggaacaaaaaaggggcattagctcagttggtagagcacctgctttgcaagcaggatgtcaggaggcgcgcctccacagttttcccggttcatcttgtttaaggtgggccgggatttttgttttttagtgtttctgggatacctcggtggcactccggcggcactctgggtcattggaaagctgtgtgtactttcgacaacaagatttgggcaaaatggtggtcaaaatcaggaaatcttgttgtcgaaagtacaactgggtcttcggttctatccgaggtgggtgagtagggtgcctgcaagtgcgatactggtgacaagtgtcgtggatccgaaagccagaatgaaaggcttgaccccaacatggatcaggttctggatttttacgccacacccgagaccaaacattgctgcagagagcaaggctgtctgtaggaaacctccagccgcaattacctcgtctgggagcgcaacagtggagcgcaaaactaccatcgccaagaatccaaggataaataggggaacgaccggtggtctctttccatcgggggacgtgtaaccctggcggcgctggcgaaaacttaaaatggcagcaatgggtgcaagtaggagtactcgggcgagtttcaccacaactgcaacacctaatgctccaccaccaatgactcctccagctgctactacttgggcgatttcatggatggatccgcctgcccacatcccaccgatttcaggggataaccccaagactttggttgcgaatgggataaaaggaatcatcagcgttccgaaaataacaacaagtgcaaccgcagtaacgacctcttcttcttcggaatcagttactccttcaacacctgccacggccgcagcgccacaaatagaaaagccacaagcaatcaacagaacttgggttggtttcattctgagcaggtgtcccatgaggatggtcccaaaaataccaccggcaacgatgcacacaatcaccgccagcatggggaaaccaagtgacaaaatatctgagaaaactaactgcagaccaaggaagacgatgaattcgagctcggtacccggggatcctctagagtcgacctgcaggcatgcaagcttggcactggccgtcgttttacaacgtcgtgactgggaaaaccctggcgttacccaacttaatcgccttgcagcacatccccctttcgccagctggcgtaatagcgaagaggcccgcaccgatcgcccttcccaacagttgcgcagcctgaatggcgaatgg

SEQ ID NO: 55 - DNA, 10116 bp, synthetic construct
  misc_feature 1..10116: note = Vector Construct
  source 1..10116: mol_type = other DNA
cgataagctagcttcacgctgccgcaagcactcagggcgcaagggctgctaaaggaagcggaacacgtagaaagccagtccgcagaaacggtgctgaccccggatgaatgtcagctactgggctatctggacaagggaaaacgcaagcgcaaagagaaagcaggtagcttgcagtgggcttacatggcgatagctagactgggcggttttatggacagcaagcgaaccggaattgccagctggggcgccctctggtaaggttgggaagccctgcaaagtaaactggatggctttcttgccgccaaggatctgatggcgcaggggatcaagatctgatcaagagacaggatgaggatcgtttcgcatgattgaacaagatggattgcacgcaggttctccggccgcttgggtggagaggctattcggctatgactgggcacaacagacaatcggctgctctgatgccgccgtgttccggctgtcagcgcaggggcgcccggttctttttgtcaagaccgacctgtccggtgccctgaatgaactccaagacgaggcagcgcggctatcgtggctggccacgacgggcgttccttgcgcagctgtgctcgacgttgtcactgaagcgggaagggactggctgctattgggcgaagtgccggggcaggatctcctgtcatctcaccttgctcctgccgagaaagtatccatcatggctgatgcaatgcggcggctgcatacgcttgatccggctacctgcccattcgaccaccaagcgaaacatcgcatcgagcgagcacgtactcggatggaagccggtcttgtcgatcaggatgatctggacgaagagcatcaggggctcgcgccagccgaactgttcgccaggctcaaggcgcggatgcccgacggcgaggatctcgtcgtgacccatggcgatgcctgcttgccgaatatcatggtggaaaatggccgcttttctggattcatcgactgtggccggctgggtgtggcggaccgctatcaggacatagcgttggctacccgtgatattgctgaagagcttggcggcgaatgggctgaccgcttcctcgtgctttacggtatcgccgctcccgattcgcagcgcatcgccttctatcgccttcttgacgagttcttctgagcgggactctggggttcgctagaggatcgatcctttttaacccatcacatatacctgccgttcactattatttagtgaaatgagatattatgatattttctgaattgtgattaaaaaggcaactttatgcccatgcaacagaaactataaaaaatacagagaatgaaaagaaacagatagattttttagttctttaggcccgtagtctgcaaatccttttatgattttctatcaaacaaaagaggaaaatagaccagttgcaatccaaacgagagtctaatagaatgaggtcgaaaagtaaatcgcgcgggtttgttactgataaagcaggcaagacctaaaatgtgtaaagggcaaagtgtatactttggcgtcaccccttacatattttaggtctttttttattgtgcgtaactaacttgccatcttcaaacaggagggctggaagaagcagaccgctaacacagtacataaaaaaggagacatgaacgatgaacatcaaaaagtttgcaaaacaagcaacagtattaacctttactaccgcactgctggcaggaggcgcaactcaagcgtttgcgaaagaaacgaaccaaaagccatataaggaaacatacggcatttcccatattacacgccatgatatgctgcaaatccctgaacagcaaaaaaatgaaaaatatcaagtttctgaatttgattcgtccacaattaaaaatatctcttctgcaaaaggcctggacgtttgggacagctggccattacaaaacgctgacggcactgtcgcaaactatcacggctaccacatcgtctttgcattagccggagatcctaaaaatgcggatgacacatcgatttacatgttctatcaaaaagtcggcgaaacttctattgacagctggaaaaacgctggccgcgtctttaaagacagcgacaaattcgatgcaaatgattctatcctaaaagaccaaacacaagaatggtcaggttcagccacatttacatctgacggaaaaatccgtttattctacactgatttctccggtaaacattacggcaaacaaacactgacaactgcacaagttaacgtatcagcatcagacagctctttgaacatcaacggtgtagaggattataaatcaatctttgacggtgacggaaaaacgtatcaaaatgtacagcagttcatcgatgaaggcaactacagctcaggcgacaaccatacgctgagagatcctcactacgtagaagataaaggccacaaatacttagtatttgaagcaaacactggaactgaagatggctaccaaggcgaagaatctttatttaacaaagcatactatggcaaaagcacatcattcttccgtcaagaaagtcaaaaacttctgcaaagcgataaaaaacgcacggctgagttagcaaacggcgctctcggtatgattgagctaaacgatgattacacactgaaaaaagtgatgaaaccgctgattgcatctaacacagtaacagatgaaattgaacgcgcgaacgtctttaaaatgaacggcaaatggtacctgttcactgactcccgcggatcaaaaatgacgattgacggcattacgtctaacgatatttacatgcttggttatgtttctaattctttaactggcccatacaagccgctgaacaaaactggccttgtgttaaaaatggatcttgatcctaacgatgtaacctttacttactcacacttcgctgtacctcaagcgaaaggaaacaatgtcgtgattacaagctatatgacaaacagaggattctacgcagacaaacaatcaacgtttgcgccgagcttcctgctgaacatcaaaggcaagaaaacatctgttgtcaaagacagcatccttgaacaaggacaattaacagttaacaaataaaaacgcaaaagaaaatgccgatgggtaccgagcgaaatgaccgaccaagcgacgcccaacctgccatcacgagatttcgattccaccgccgccttctatgaaaggttgggcttcggaatcgttttccgggacgccctcgcggacgtgctcatagtccacgacgcccgtgattttgtagccctggccgacggccagcaggtaggccgacaggctcatgccggccgccgccgccttttcctcaatcgctcttcgttcgtctggaaggcagtacaccttgataggtgggctgcccttcctggttggcttggtttcatcagccatccgcttgccctcatctgttacgccggcggtagccggccagcctcgcagagcaggattcccgttgagcaccgccaggtgcgaataagggacagtgaagaaggaacacccgctcgcgggtgggcctacttcacctatcctgcccggctgacgccgttggatacaccaaggaaagtctacacgaaccctttggcaaaatcctgtatatcgtgcgaaaaaggatggatataccgaaaaaatcgctataatgaccccgaagcagggttatgcagcggaaaagcgctgcttccctgctgttttgtggaatatctaccgactggaaacaggcaaatgcaggaaattactgaactgaggggacaggcgagagacgatgccaaagagctcctgaaaatctcgataactcaaaaaatacgcccggtagtgatcttatttcattatggtgaaagttggaacctcttacgtgccgatcaacgtctcattttcgccaaaagttggcccagggcttcccggtatcaacagggacaccaggatttatttattctgcgaagtgatcttccgtcacaggtatttattcggcgcaaagtgcgtcgggtgatgctgccaacttactgatttagtgtatgatggtgtttttgaggtgctccagtggcttctgtttctatcagctcctgaaaatctcgataactcaaaaaatacgcccggtagtgatcttatttcattatggtgaaagttggaacctcttacgtgccgatcaacgtctcattttcgccaaaagttggcccagggcttcccggtatcaacagggacaccaggatttatttattctgcgaagtgatcttccgtcacaggtatttattcggcgcaaagtgcgtcgggtgatgctgccaacttactgatttagtgtatgatggtgtttttgaggtgctccagtggcttctgtttctatcagggctggatgatcctccagcgcggggatctcatgctggagttcttcgcccaccccaaaaggatctaggtgaagatcctttttgataatctcatgaccaaaatcccttaacgtgagttttcgttccactgagcgtcagaccccgtagaaaagatcaaaggatcttcttgagatcctttttttctgcgcgtaatctgctgcttgcaaacaaaaaaaccaccgctaccagcggtggtttgtttgccggatcaagagctaccaactctttttccgaaggtaactggcttcagcagagcgcagataccaaatactgttcttctagtgtagccgtagttaggccaccacttcaagaactctgtagcaccgcctacatacctcgctctgctaatcctgttaccagtggctgctgccagtggcgataagtcgtgtcttaccgggttggactcaagacgatagttaccggataaggcgcagcggtcgggctgaacggggggttcgtgcacacagcccagcttggagcgaacgacctacaccgaactgagatacctacagcgtgagctatgagaaagcgccacgcttcccgaagggagaaaggcggacaggtatccggtaagcggcagggtcggaacaggagagcgcacgagggagcttccagggggaaacgcctggtatctttatagtcctgtcgggtttcgccacctctgacttgagcgtcgatttttgtgatgctcgtcaggggggcggagcctatggaaaaacgccagcaacgcggcctttttacggttcctggccttttgctggccttttgctcacatgttctttcctgcgttatcccctgattctgtggataaccgtattaccgcctttgagtgagctgataccgctcgccgcagccgaacgaccgagcgcagcgagtcagtgagcgaggaagcggaagagcgcccaatacgcaaaccgcctctccccgcgcgttggccgattcattaatgcagctggcacgacaggtttcccgactggaaagcgggcagtgagcgcaacgcaattaatgtgagttagctcactcattaggcaccccaggctttacactttatgcttccggctcgtatgttgtgtggaattgtgagcggataacaatttcacacaggaaacagctatgacatgattacggacggcgaattcctcctcgttgccacctccggcggctacggcaagcgcaccccacttgaggattactccacccagggccgtggtggcctcggcgtggtgaccttcaagtacaccccgaagcgcggtcgcctcgtcagcgccatcgcagttgaggaagatgacgagatcttcgccatcacctccgccggcggcgttgttcgcaccgaagtcaagcagatccgaccatcctcccgtgcaacaatgggtgttcgactggtcaacttggaagaaggtgtagaactgcttgccatcgacaagaacgtcgaagaccagggcgaagcatccgcagaagcagtagcaaagggtgcagtcgaaggaccagcatccaagactgctgccgaagaaaccgactccgttgacaacggatccgacgaaaacggcgaggaataatttatggcatcccgagaagtatccatcacccgaatctcaccactagcaaccttccgagttgcactggcaatgtccatcatcggactcgtggcgtggatcatctgcgtaaccgtcctctatttcggacttaacgtggctggcgtctggcagaacttcaacgatgtcatcggcggtgttggtgcagaacaaaccatcaccttcgggctcgtcctgagcatttccgcacttctgggagctatcggagcgattaccgtcgctgtgcttgcaccattgtgtgcaatcatctacaactcgattgttgacctcttcggtggactgcagattcaactgcaagaagaagtagactaacctctgaaacacaaacccctagacactgctaaatatagcctttgaacaggggatttgttgtattgttaacttgaaggtagagtcttatctcgttcctagaggggcctatagctcagtcggttagagcgcatcgctgataacgatgaggtcgcaagttcgattcttgctaggcccaccaggaacaaaaaaggggcattagctcagttggtagagcacctgctttgcaagcaggatgtcaggaggaccggtgttttagcgtgtcagtaggcgcgtagggtaagtggggtagcggcttgttagatatcttgaaatcggctttcaacagcattgatttcgatgtatttagctggccgttaccctgcgaatgtccacagggtagctggtagtttgaaaatcaacgccgttgcccttaggattcagtaactggcaaggaaggattttccaggaggaacacatgaacatcatcgctatcatgggccctcacggtgttttctacaaggatgagccaatcaaggagctggaatccgcactagttgcacagggctttcagatcatctggccccagaactccgttgaccttctcaaattcatcgagcacaatcctcgcatttgtggtgtgatttttgactgggacgagtactctcttgatttatgctccgacatcaaccagctcaacgagtacctgccactctacgcattcatcaacactcactccaccatggacgtttccgtgcaggacatgcgtatggcactctggttctttgaatacgctctgggccaggctgaggacatcgcgatccgcatgcgtcagtacaccgacgagtacctggacaacatcacccctccattcaccaaggctctcttcacctacgtaaaggaacgcaagtacactttctgcaccccaggccacatgggcggcaccgcctaccagaagtccccagtcggatgcctcttctacgacttcttcggcggtaacactcttaaggcagatgtctccatttccgtcaccgagttgggctctctgctggaccacaccggccctcacctggaggcagaagagtacatcgctcgtaccttcggtgctgaacagtcctacatcgtcaccaacggtacttccaccagcaacaagatcgttggtatgtacgcagctccttctggctccaccctgttgatcgaccgcaactgtcacaagtccctcgcgcatcttcttatgatgaacgatgtggtccctgtatggctgaagccaacccgtaacgctctgggcatccttggcggtatcccccgtcgcgagttcacccgtgattccatcgaggaaaaggttgcagccactacccaggcacagtggcctgtccacgctgtcattaccaactcgacctacgacggcctgctctacaacaccgattggatcaagcagaccctagatgttccttccattcacttcgacagcgcatgggttccttacactcacttccacccaatctaccagggtaagtccggaatgtccggcgagcgtgtcgctggcaaggttatcttcgaaacccaatcaacccacaagatgctggctgctctctcccaggcttctctgatccacatcaagggcgagtacgacgaggaagctttcaacgaggctttcatgatgcacaccaccacctccccatcctaccctatcgtcgcgtccgtcgagactgctgccgcaatgcttcgcggtaacccaggtaagcgcctcatcaaccgttccgttgagcgcgctcttcacttccgtaaggaagtgcagcgcctgcgtgaggaatctgacggttggttcttcgacatttggcagccacctcaggttgatgaggccgagtgctggccagttgctccaggtgaacagtggcacggattcaacgatgcagatgctgaccacatgtttttggacccggtcaaggtcaccattcttactcctggtatggatgagcagggcaacatgtctgaggagggtatcccagctgctctggttgcaaagttcctcgacgaacgtggcatcgttgttgagaagaccggaccatacaacctgctgttcctgttcagcatcggcatcgacaaaaccaaggcaatgggtctgctgcgcggccttaccgagttcaagcgctcctacgacctgaaccttcgcatcaagaatatgctgccggacctgtacgctgaagatcctgatttctaccgcaacatgcgcatccaggacctcgcacagggcatccacaagctcattcgcaagcacgacctgccaggccttatgctccgtgcattcgataccctcccagagatgatcatgacccctcaccaggcttggcagcgccagatcaagggcgaggtggaaaccatcgcactggagcagctggttggtcgtgtctccgccaacatgatcctgccatatccacctggcgttccgctgctgatgccaggcgagatgctcaccaaggagtcccgcaccgtattggacttccttctcatgttgtgctctgttggccagcactacccaggcttcgagaccgacatccacggcgctaagcaagatgaagacggcgtttaccgcgttcgcgtccttaagatggcaggctaacttgccagagcggcttccgggcgagtaacgtgcggatccgcctccacagttttcccggttcatcttgtttaaggtgggccgggatttttgttttttagtgtttctgggatacctcggtggcactccggcggcactctgggtcattggaaagctgtgtgtactttcgacaacaagatttgggcaaaatggtggtcaaaatcaggaaatcttgttgtcgaaagtacaactgggtcttcggttctatccgaggtgggtgagtagggtgcctgcaagtgcgatactggtgacaagtgtcgtggatccgaaagccagaatgaaaggcttgaccccaacatggatcaggttctggatttttacgccacacccgagaccaaacattgctgcagagagcaaggctgtctgtaggaaacctccagccgcaattacctcgtctgggagcgcaacagtggagcgcaaaactaccatcgccaagaatccaaggataaataggggaacgaccggtggtctctttccatcgggggacgtgtaaccctggcggcgctggcgaaaacttaaaatggcagcaatgggtgcaagtaggagtactcgggcgagtttcaccacaactgcaacacctaatgctccaccaccaatgactcctccagctgctactacttgggcgatttcatggatggatccgcctgcccacatcccaccgatttcaggggataaccccaagactttggttgcgaatgggataaaaggaatcatcagcgttccgaaaataacaacaagtgcaaccgcagtaacgacctcttcttcttcggaatcagttactccttcaacacctgccacggccgcagcgccacaaatagaaaagccacaagcaatcaacagaacttgggttggtttcattctgagcaggtgtcccatgaggatggtcccaaaaataccaccggcaacgatgcacacaatcaccgccagcatggggaaaccaagtgacaaaatatctgagaaaactaactgcagaccaaggaagacgatgaattcgagctcggtacccggggatcctctagagtcgacctgcaggcatgcaagcttggcactggccgtcgttttacaacgtcgtgactgggaaaaccctggcgttacccaacttaatcgccttgcagcacatccccctttcgccagctggcgtaatagcgaagaggcccgcaccgatcgcccttcccaacagttgcgcagcctgaatggcgaatgg

SEQ ID NO: 56 - DNA, 48 bp, synthetic construct
  misc_feature 1..48: note = Primer
  source 1..48: mol_type = other DNA
acaggaaacagaattaattaagcttccccaccggaggacccccccatg

SEQ ID NO: 57 - DNA, 49 bp, synthetic construct
  misc_feature 1..49: note = Primer
  source 1..49: mol_type = other DNA
agtcgacctgcaggcatgcaagcttccggttggctaccggcctgccagg

SEQ ID NO: 58 - DNA, 101 bp, synthetic construct
  misc_feature 1..101: note = primer
  source 1..101: mol_type = other DNA
acaggaaacagaattaattaagctttgcaggaaggagatatagatatgcgctcgcacctgctcaacgacaccaccgcggagcactaccgccgctccgtgac

SEQ ID NO: 59 - DNA, 55 bp, synthetic construct
  misc_feature 1..55: note = primer
  source 1..55: mol_type = other DNA
agtcgacctgcaggcatgcaagcttttcgtgggtcagaactccgcgagggggttc

SEQ ID NO: 60 - DNA, 42 bp, synthetic construct
  misc_feature 1..42: note = Primer
  source 1..42: mol_type = other DNA
acagctatgacatgattacggacggcgaattcctcctcgttg

SEQ ID NO: 61 - DNA, 30 bp, synthetic construct
  misc_feature 1..30: note = Primer
  source 1..30: mol_type = other DNA
ggcgcgcctcctgacatcctgcttgcaaag

SEQ ID NO: 62 - DNA, 47 bp, synthetic construct
  misc_feature 1..47: note = Primer
  source 1..47: mol_type = other DNA
gcaggatgtcaggaggcgcgcctccacagttttcccggttcatcttg

SEQ ID NO: 63 - DNA, 50 bp, synthetic construct
  misc_feature 1..50: note = Primer
  source 1..50: mol_type = other DNA
atccccgggtaccgagctcgaattcatcgtcttccttggtctgcagttag

SEQ ID NO: 64 - DNA, 33 bp, synthetic construct
  misc_feature 1..33: note = Primer
  source 1..33: mol_type = other DNA
gcaagcaggatgtcaggaggaccggtgttttag

SEQ ID NO: 65 - DNA, 25 bp, synthetic construct
  misc_feature 1..25: note = Primer
  source 1..25: mol_type = other DNA
aaccgggaaaactgtggaggcggat

SEQ ID NO: 66 - DNA, 41 bp, synthetic construct
  misc_feature 1..41: note = Primer
  source 1..41: mol_type = other DNA
tcctagagccagtccgcgatcgcctccgcttcgacggtcac

SEQ ID NO: 67 - DNA, 43 bp, synthetic construct
  misc_feature 1..43: note = Primer
  source 1..43: mol_type = other DNA
attcgagctcggtacccgggtcaggcggaggcgccgcgagctg

SEQ ID NO: 68 - DNA, 831 bp, synthetic construct
  misc_feature 1..831: note = Vector Construct
  source 1..831: mol_type = other DNA
tcctagagccagtccgcgatcgcctccgcttcgacggtcacggccgttttgatgtagcacgcaactacgctatcgatgttacaggccgcggcgtgttcctccagaacgcaggcgttcacacccactccatcacctccccagacctcggcatgggcgcataccgcaatgccagcattatccgcgaactgctgggcaccgaatactacccagtcgagaaatccatcgcattccaagaattcgccgtctgatgcaggaaggagatatagatatgtccaccatcggtaccttcaccatccgccctcttgacccagagaaggacgcggagttgctgcaccgctgggtgacccacccaaaggccgcattctggatgatgcaggacgcacgcctagaagacgtagagcgcgaatacatgcgcatcgctgctcacgagcaccaccacgcctacctgggcctgcacgacggagagcctgctttcctcatggaaaaatacgacccacgccacgtcgaactggtgggcctgtacgaaccagaaccaggagacgttggcatgcacttcctcgtagcgccaaccgaccgcccagttcacggcttcacccgcgccgtcatcaccgccgttatggaagaactgttcgctgatcctgcgacccgccgcgtcgtcgttgagccagacgtcggcaacaaggctgtgcacgccctcaacgaagcagttggcttcgaacccgaacgcgaaatcgacaagccagagaagcgcgcactgctttccttctgcacccgcgaacagttcgaagcagctcgcggcgcctccgcctgacccgggtaccgagctcgaat

SEQ ID NO: 69 - DNA, 8498 bp, synthetic construct
  misc_feature 1..8498: note = Vector Construct
  source 1..8498: mol_type = other DNA
aattattcacacaggaaacagaattaattaccgtcctcgacctgatcgccggccacgccgtgcaggaaggagatatagatatgaccgctcttgctgacaccaccgagccaacctacgacttcgtcggcatcggtcttggacctttcaacctgggtctggcatgtctcaccgagccagtcgacgagctagcaggtgttttcctggaatccaagccagacttcgcttggcacgcgggaatgttcctggacggcgcccacctgcagaccccattcatgtccgacctggtcaccctggctgaccctaccagcccttacagctttctgaactaccttaaggagaagggacgtctttacagcttctacatccgcgaaaacttttacccactgcgtgtggaatacgacgattactgccgttgggcagctgcacagttatcctccatccgcttcggtaccacagtcaccgaagtcacctgggatgaaaccgctgaagtgtacgtcgtcgcgaccagcaccggtaccacgtaccgcggtcgtcatctggttctgggaaccggcaccgtcccgttcgtccctgaggcatgccgcggattggaaggcgaccttttccacaacgcacagtacatgcgtcgcaaggcagaactcctcgagaagaagtcggttaccgttgttggctccggccagtccgctgctgaaatctactacgagctcctttccggtatcgacgcacacggctaccaactaaactgggtcacccgctccccccgcttcttccctctcgaatacaccaagctcaccctcgaaatgacctcccccgactacattgattactttcgcgctctgcctgaagacacccgctaccgcctggaaaagcaacagaagggcctgttcaagggcatcaattcagacctcatcgacgcaatcttcgacctcctgtaccagaagaacgtcgaatccggtggccgcggcgtccccactcgcctgctcaccaactcctccctgaccaccgcccgctaccaggacggcacctacacacttggcttccgccaagacgaacagggaaaggatttcgaaatcgctactgagggcctggtcctcgccaccggctaccactacgaacagccagccttcctagagccagtccgcgatcgcctccgcttcgacggtcacggccgttttgatgtagcacgcaactacgctatcgatgttacaggccgcggcgtgttcctccagaacgcaggcgttcacacccactccatcacctccccagacctcggcatgggcgcataccgcaatgccagcattatccgcgaactgctgggcaccgaatactacccagtcgagaaatccatcgcattccaagaattcgccgtctgatgcaggaaggagatatagatatgtccaccatcggtaccttcaccatccgccctcttgacccagagaaggacgcggagttgctgcaccgctgggtgacccacccaaaggccgcattctggatgatgcaggacgcacgcctagaagacgtagagcgcgaatacatgcgcatcgctgctcacgagcaccaccacgcctacctgggcctgcacgacggagagcctgctttcctcatggaaaaatacgacccacgccacgtcgaactggtgggcctgtacgaaccagaaccaggagacgttggcatgcacttcctcgtagcgccaaccgaccgcccagttcacggcttcacccgcgccgtcatcaccgccgttatggaagaactgttcgctgatcctgcgacccgccgcgtcgtcgttgagccagacgtcggcaacaaggctgtgcacgccctcaacgaagcagttggcttcgaacccgaacgcgaaatcgacaagccagagaagcgcgcactgctttccttctgcacccgcgaacagttcgaagcagctcgcggcgcctccgcctgacccgggtaccgagctcgaattcagcttggctgttttggcggatgagagaagattttcagcctgatacagattaaatcagaacgcagaagcggtctgataaaacagaatttgcctggcggcagtagcgcggtggtcccacctgaccccatgccgaactcagaagtgaaacgccgtagcgccgatggtagtgtggggtctccccatgcgagagtagggaactgccaggcatcaaataaaacgaaaggctcagtcgaaagactgggcctttcgttttatctgttgtttgtcggtgaacgctctcctgagtaggacaaatccgccgggagcggatttgaacgttgcgaagcaacggcccggagggtggcgggcaggacgcccgccataaactgccaggcatcaaattaagcagaaggccatcctgacggatggcctttttgcgtttctacaaactcttttgtttatttttctaaatacattcaaatatgtatccgctcatgagacaataaccctgataaatgcttcaataatattgaaaaaggaagagtatgagtattcaacatttccgtgtcgcccttattcccttttttgcggcattttgccttcctgtttttgctcacccagaaacgctggtgaaagtaaaagatgctgaagatcagttgggtgcacgagtgggttacatcgaactggatctcaacagcggtaagatccttgagagttttcgccccgaagaacgttttccaatgatgagcacttttgcttcctcgctcactgactcgctgcgctcggtcgttcggctgcggcgagcggtatcagctcactcaaaggcggtaatacggttatccacagaatcaggggataacgcaggaaagaacatgtgagcaaaaggccagcaaaaggccaggaaccgtaaaaaggccgcgttgctggcgtttttccataggctccgcccccctgacgagcatcacaaaaatcgacgctcaagtcagaggtggcgaaacccgacaggactataaagataccaggcgtttccccctggaagctccctcgtgcgctctcctgttccgaccctgccgcttaccggatacctgtccgcctttctcccttcgggaagcgtggcgctttctcaatgctcacgctgtaggtatctcagttcggtgtaggtcgttcgctccaagctgggctgtgtgcacgaaccccccgttcagcccgaccgctgcgccttatccggtaactatcgtcttgagtccaacccggtaagacacgacttatcgccactggcagcagccactggtaacaggattagcagagcgaggtatgtaggcggtgctacagagttcttgaagtggtggcctaactacggctacactagaaggacagtatttggtatctgcgctctgctgaagccagttaccttcggaaaaagagttggtagctcttgatccggcaaacaaaccaccgctggtagcggtggtttttttgtttgcaagcagcagattacgcgcagaaaaaaaggatctcaagaagatcctttgatcttttctacggggtctgacgctcagtggaacgaaaactcacgttaagggattttggtcatgagattatcaaaaaggatcttcacctagatccttttggggtgggcgaagaactccagcatgagatccccgcgctggaggatcatccagccattcggggtcgttcactggttcccctttctgatttctggcatagaagaacccccgtgaactgtgtggttccgggggttgctgatttttgcgagacttctcgcgcaattccctagcttaggtgaaaacaccatgaaacactagggaaacacccatgaaacacccattagggcagtagggcggcttcttcgtctagggcttgcatttgggcggtgatctggtctttagcgtgtgaaagtgtgtcgtaggtggcgtgctcaatgcactcgaacgtcacgtcatttaccgggtcacggtgggcaaagagaactagtgggttagacattgttttcctcgttgtcggtggtggtgagcttttctagccgctcggtaaacgcggcgatcatgaactcttggaggttttcaccgttctgcatgcctgcgcgcttcatgtcctcacgtagtgccaaaggaacgcgtgcggtgaccacgacgggcttagcctttgcctgcgcttctagtgcttcgatggtggcttgtgcctgcgcttgctgcgcctgtagtgcctgttgagcttcttgtagttgctgttctagctgtgccttggttgccatgctttaagactctagtagctttcctgcgatatgtcatgcgcatgcgtagcaaacattgtcctgcaactcattcattatgtgcagtgctcctgttactagtcgtacatactcatatttacctagtctgcatgcagtgcatgcacatgcagtcatgtcgtgctaatgtgtaaaacatgtacatgcagattgctgggggtgcagggggcggagccaccctgtccatgcggggtgtggggcttgccccgccggtacagacagtgagcaccggggcacctagtcgcggataccccccctaggtatcggacacgtaaccctcccatgtcgatgcaaatctttaacattgagtacgggtaagctggcacgcatagccaagctaggcggccaccaaacaccactaaaaattaatagtccctagacaagacaaacccccgtgcgagctaccaactcatatgcacgggggccacataacccgaaggggtttcaattgacaaccatagcactagctaagacaacgggcacaacacccgcacaaactcgcactgcgcaaccccgcacaacatcgggtctaggtaacactgagtaacactgaaatagaagtgaacacctctaaggaaccgcaggtcaatgagggttctaaggtcactcgcgctagggcgtggcgtaggcaaaacgtcatgtacaagatcaccaatagtaaggctctggcggggtgccataggtggcgcagggacgaagctgttgcggtgtcctggtcgtctaacggtgcttcgcagtttgagggtctgcaaaactctcactctcgctgggggtcacctctggctgaattggaagtcatgggcgaacgccgcattgagctggctattgctactaagaatcacttggcggcgggtggcgcgctcatgatgtttgtgggcactgttcgacacaaccgctcacagtcatttgcgcaggttgaagcgggtattaagactgcgtactcttcgatggtgaaaacatctcagtggaagaaagaacgtgcacggtacggggtggagcacacctatagtgactatgaggtcacagactcttgggcgaacggttggcacttgcaccgcaacatgctgttgttcttggatcgtccactgtctgacgatgaactcaaggcgtttgaggattccatgttttcccgctggtctgctggtgtggttaaggccggtatggacgcgccactgcgtgagcacggggtcaaacttgatcaggtgtctacctggggtggagacgctgcgaaaatggcaacctacctcgctaagggcatgtctcaggaactgactggctccgctactaaaaccgcgtctaaggggtcgtacacgccgtttcagatgttggatatgttggccgatcaaagcgacgccggcgaggatatggacgctgttttggtggctcggtggcgtgagtatgaggttggttctaaaaacctgcgttcgtcctggtcacgtggggctaagcgtgctttgggcattgattacatagacgctgatgtacgtcgtgaaatggaagaagaactgtacaagctcgccggtctggaagcaccggaacgggtcgaatcaacccgcgttgctgttgctttggtgaagcccgatgattggaaactgattcagtctgatttcgcggttaggcagtacgttctcgattgcgtggataaggctaaggacgtggccgctgcgcaacgtgtcgctaatgaggtgctggcaagtctgggtgtggattccaccccgtgcatgatcgttatggatgatgtggacttggacgcggttctgcctactcatggggacgctactaagcgtgatctgaatgcggcggtgttcgcgggtaatgagcagactattcttcgcacccactaaaagcggcataaaccccgttcgatattttgtgcgatgaatttatggtcaatgtcgcgggggcaaactatgatgggtcttgttgttggcgtcccggaaaacgattccgaagcccaacctttcatagaaggcggcggtggaatcgaaatctcgtgatggcaggttgggcgtcgcttggtcggtcatttcgaagggcaccaataactgccttaaaaaaattacgccccgccctgccactcatcgcagtactgttgtaattcattaagcattctgccgacatggaagccatcacagacggcatgatgaacctgaatcgccagcggcatcagcaccttgtcgccttgcgtataatatttgcccatggtgaaaacgggggcgaagaagttgtccatattggccacgtttaaatcaaaactggtgaaactcacccagggattggctgagacgaaaaacatattctcaataaaccctttagggaaataggccaggttttcaccgtaacacgccacatcttgcgaatatatgtgtagaaactgccggaaatcgtcgtggtattcactccagagcgatgaaaacgtttcagtttgctcatggaaaacggtgtaacaagggtgaacactatcccatatcaccagctcaccgtctttcattgccatacggaactccggatgagcattcatcaggcgggcaagaatgtgaataaaggccggataaaacttgtgcttatttttctttacggtctttaaaaaggccgtaatatccagctgaacggtctggttataggtacattgagcaactgactgaaatgcctcaaaatgttctttacgatgccattgggatatatcaacggtggtatatccagtgatttttttctccattttagcttccttagctcctgaaaatctcgtcgaagctcggcggatttgtcctactcaagctgatccgacaaaatccacacattatcccaggtgtccggatcggtcaaatacgctgccagctcatagaccgtatccaaagcatccggggctgatccccggcgccagggtggtttttcttttcaccagtgagacgggcaacagctgattgcccttcaccgcctggccctgagagagttgcagcaagcggtccacgtggtttgccccagcaggcgaaaatcctgtttgatggtggttaacggcgggatataacatgagctgtcttcggtatcgtcgtatcccactaccgagatatccgcaccaacgcgcagcccggactcggtaatggcgcgcattgcgcccagcgccatctgatcgttggcaaccagcatcgcagtgggaacgatgccctcattcagcatttgcatggtttgttgaaaaccggacatggcactccagtcgccttcccgttccgctatcggctgaatttgattgcgagtgagatatttatgccagccagccagacgcagacgcgccgagacagaacttaatgggcccgctaacagcgcgatttgctggtgacccaatgcgaccagatgctccacgcccagtcgcgtaccgtcttcatgggagaaaataatactgttgatgggtgtctggtcagagacatcaagaaataacgccggaacattagtgcaggcagcttccacagcaatggcatcctggtcatccagcggatagttaatgatcagcccactgacgcgttgcgcgagaagattgtgcaccgccgctttacaggcttcgacgccgcttcgttctaccatcgacaccaccacgctggcacccagttgatcggcgcgagatttaatcgccgcgacaatttgcgacggcgcgtgcagggccagactggaggtggcaacgccaatcagcaacgactgtttgcccgccagttgttgtgccacgcggttgggaatgtaattcagctccgccatcgccgcttccactttttcccgcgttttcgcagaaacgtggctggcctggttcaccacgcgggaaacggtctgataagagacaccggcatactctgcgacatcgtataacgttactggtttcacattcaccaccctgaattgactctcttccgggcgctatcatgccataccgcgaaaggttttgcaccattcgatggtgtcaacgtaaatgccgcttcgccttcgcgcgcgaattgcaagctgatccgggcttatcgactgcacggtgcaccaatgcttctggcgtcaggcagccatcggaagctgtggtatggctgtgcaggtcgtaaatcactgcataattcgtgtcgctcaaggcgcactcccgttctggataatgttttttgcgccgacatcataacggttctggcaaatattctgaaatgagctgttgacaattaatcatcggctcgtataatgtgtggaattgtgagcggataacaatttcacacaggaaacagaatt